(19) United States
(12) Patent Application Publication
(10) Pub. No.: US 2025/0072012 A1
(43) Pub. Date: Feb. 27, 2025

(54) SEMICONDUCTOR DEVICE

(71) Applicant: ROHM CO., LTD., Kyoto (JP)

(72) Inventors: Masanobu TSUJI, Kyoto (JP); Yoshizo OSUMI, Kyoto (JP)

(21) Appl. No.: 18/790,083

(22) Filed: Jul. 31, 2024

(30) Foreign Application Priority Data
Aug. 23, 2023 (JP) 2023-135891

(51) Int. Cl. H01F 27/28; H01L 23/00; H01L 23/31; H01L 23/495

(52) U.S. Cl. CPC H01L 28/10; H01F 27/2804; H01L 23/3107; H01L 23/49575; H01L 24/32; H01L 24/48; H01L 24/73; H01L 2224/32245; H01L 2224/48137; H01L 2224/48245; H01L 2224/73265; H01L 2924/1206

(57) ABSTRACT

A semiconductor device includes: a first chip including a first semiconductor substrate, a first circuit, and a first element insulating layer formed over the first semiconductor substrate; a second chip spaced apart from the first chip in a first direction and including a second semiconductor substrate, a second circuit, and a second element insulating layer formed over the second semiconductor substrate; a sub-mount chip separate from the first and second chips; and a transformer chip disposed over the sub-mount chip and including a transformer through which the first and second circuits transmit signals or power, wherein the transformer chip includes a third semiconductor substrate and a third element insulating layer formed over the third semiconductor substrate, wherein the transformer is embedded in the third element insulating layer, and wherein the sub-mount chip includes a fourth semiconductor substrate and an insulating layer formed over the fourth semiconductor substrate.

### CROSS-REFERENCE TO RELATED APPLICATION

This application is based upon and claims the benefit of priority from Japanese Patent Application No. 2023-135891, filed on Aug. 23, 2023, the entire contents of which are incorporated herein by reference.

### TECHNICAL FIELD

The present disclosure relates to a semiconductor device.

### BACKGROUND

The related art discloses a transformer chip including a semiconductor substrate, an insulating layer stack structure formed on the substrate, and an upper coil and a lower coil formed within the insulating layer stack structure.

### BRIEF DESCRIPTION OF DRAWINGS

The accompanying drawings, which are incorporated in and constitute a part of the specification, illustrate embodiments of the present disclosure.

FIG. 1 is a schematic circuit diagram of a semiconductor device according to a first embodiment.

FIG. 2 is a schematic plan view of the semiconductor device of FIG. 1.

FIG. 3 is a schematic cross-sectional view of the semiconductor device taken along line F3-F3 in FIG. 2.

FIG. 4 is a schematic plan view of a transformer chip in the semiconductor device of FIG. 2.

FIG. 5 is a schematic cross-sectional view of the transformer chip taken along line F5-F5 in FIG. 4.

FIG. 6 is a schematic cross-sectional view of the transformer chip taken along line F6-F6 in FIG. 4.

FIG. 7 is a schematic cross-sectional view of a sub-mount chip in the semiconductor device of FIG. 3.

FIG. 8 is an enlarged schematic cross-sectional view of a first chip, a second chip, a sub-mount chip, a transformer chip, and their periphery in the semiconductor device of FIG. 3.

FIG. 9 is a schematic cross-sectional view of a transformer chip in a semiconductor device according to a second embodiment.

FIG. 10 is a schematic circuit diagram of a semiconductor device according to a third embodiment.

FIG. 11 is a schematic plan view of the semiconductor device of FIG. 10.

FIG. 12 is a schematic plan view of a transformer chip in the semiconductor device of FIG. 11.

FIG. 13 is a schematic cross-sectional view of the transformer chip and a sub-mount chip taken along line F13-F13 in FIG. 12.

FIG. 14 is a schematic cross-sectional view of the transformer chip and the sub-mount chip taken along line F14-F14 in FIG. 12.

FIG. 15 is a schematic cross-sectional view of a transformer chip in a first modification of the semiconductor device according to the first embodiment.

FIG. 16 is a schematic cross-sectional view of a transformer chip in a second modification of the semiconductor device according to the first embodiment.

FIG. 17 is an exploded perspective view of a portion of the transformer chip in the second modification of the semiconductor device according to the first embodiment.

FIG. 18 is a schematic cross-sectional view of a transformer chip in a third modification of the semiconductor device according to the first embodiment.

FIG. 19 is a schematic cross-sectional view of a transformer chip in a fourth modification of the semiconductor device according to the first embodiment.

FIG. 20 is a schematic cross-sectional view of a portion of a transformer chip in a modification of the semiconductor device according to the second embodiment.

FIG. 21 is a schematic cross-sectional view of a transformer chip in a first modification of the semiconductor device according to the third embodiment.

FIG. 22 is a schematic cross-sectional view of a transformer chip in a second modification of the semiconductor device according to the third embodiment.

FIG. 23 is an exploded perspective view of a portion of the transformer chip in the second modification of the semiconductor device according to the third embodiment.

FIG. 24 is a schematic cross-sectional view of a transformer chip in a third modification of the semiconductor device according to the third embodiment.

FIG. 25 is a schematic cross-sectional view of a transformer chip in a fourth modification of the semiconductor device according to the third embodiment.

FIG. 26 is a schematic plan view of a transformer chip in a fifth modification of the semiconductor device according to the third embodiment.

FIG. 27 is a schematic plan view of a transformer chip in the fifth modification of the semiconductor device according to the third embodiment.

FIG. 28 is a schematic cross-sectional view of a portion of a transformer chip in a modification of the semiconductor device according to the third embodiment.

FIG. 29 is a schematic cross-sectional view of a portion of the transformer chip in the modification of the semiconductor device according to the third embodiment.

FIG. 30 is a schematic cross-sectional view of a portion of a transformer chip in a modification of the semiconductor device according to the third embodiment.

FIG. 31 is a schematic cross-sectional view of a portion of the transformer chip in the modification of the semiconductor device according to the third embodiment.

FIG. 32 is a schematic cross-sectional view of a first chip, a second chip, a sub-mount chip, a transformer chip, and their periphery in a modification of the semiconductor device.

FIG. 33 is a schematic cross-sectional view of a first chip, a second chap, a sub-mount chip, a transformer chip, and their periphery in a modification of the semiconductor device.

FIG. 34 is a schematic cross-sectional view of a first chip, a sub-mount chip, a transformer chip, and their periphery in a modification of the semiconductor device.

FIG. 35 is a schematic cross-sectional view of a portion of a first chip, a portion of the second chip, a sub-mount chip, a transformer chip, and their periphery in a modification of the semiconductor device.

FIG. 36 is a schematic cross-sectional view of a first chip, a sub-mount chip, a transformer chip, and their periphery in a modification of the semiconductor device.

FIG. 37 is a schematic cross-sectional view of a first chip, a second chip, a sub-mount chip, a transformer chip, and their periphery in a modification of the semiconductor device.

FIG. 38 is a schematic cross-sectional view of a first chip, a sub-mount chip, a transformer chip, and their periphery in a modification of the semiconductor device.

FIG. 39 is a schematic circuit diagram of a modification of the semiconductor device.

FIG. 40 is a schematic cross-sectional view of a first chip, a second chip, a sub-mount chip, a transformer chip, and their periphery in the semiconductor device of FIG. 39.

FIG. 41 is a schematic circuit diagram of a modification of the semiconductor device.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, some embodiments of a semiconductor device according to the present disclosure are described with reference to the accompanying drawings. It should be noted that, for simplicity and clarity of explanation, the constituent elements shown in the drawings are not necessarily drawn to scale. Further, in order to facilitate understanding, hatching lines may be omitted in cross-sectional views. The accompanying drawings merely illustrate embodiments of the present disclosure and should not be considered as limiting the present disclosure. The terms such as “first,” “second,” and “third” in the present disclosure are used merely to distinguish between objects and are not intended to rank the objects.

The following detailed description includes devices, systems, and methods embodying exemplary embodiments of the present disclosure. This detailed description is for illustrative purposes only and is not intended to limit the embodiments of the present disclosure or the applications and uses of such embodiments.

The expression “at least one” as used in the present disclosure means “one or more” of desired options. As an example, if there are two options, the expression “at least one” as used in the present disclosure means “only one option” or “both of the two options.” As another example, if there are three or more options, the expression “at least one” as used in the present disclosure means “only one option” or “any combination of two or more options.”

The expression “the length (dimension) of A is equal to the length (dimension) of B” or “the length (dimension) of A and the length (dimension) of B are equal to each other” as used in the present disclosure also includes a relationship in which a difference between the length (dimension) of A and the length (dimension) of B is, for example, within 10% of the length (dimension) of A.

### First Embodiment

### [Schematic Configuration of Semiconductor Device]

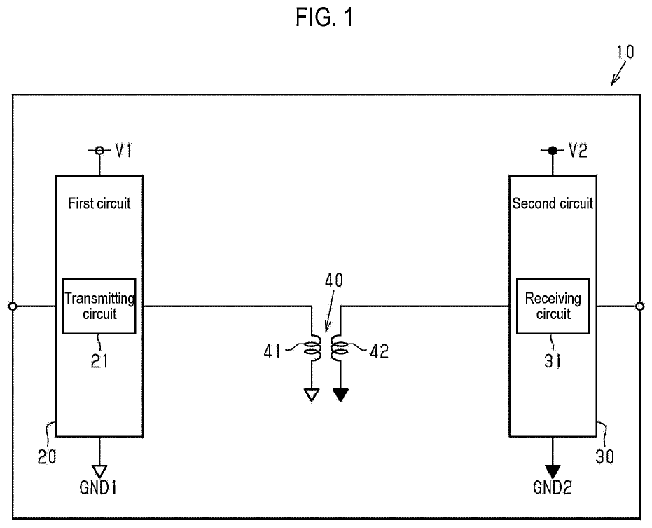

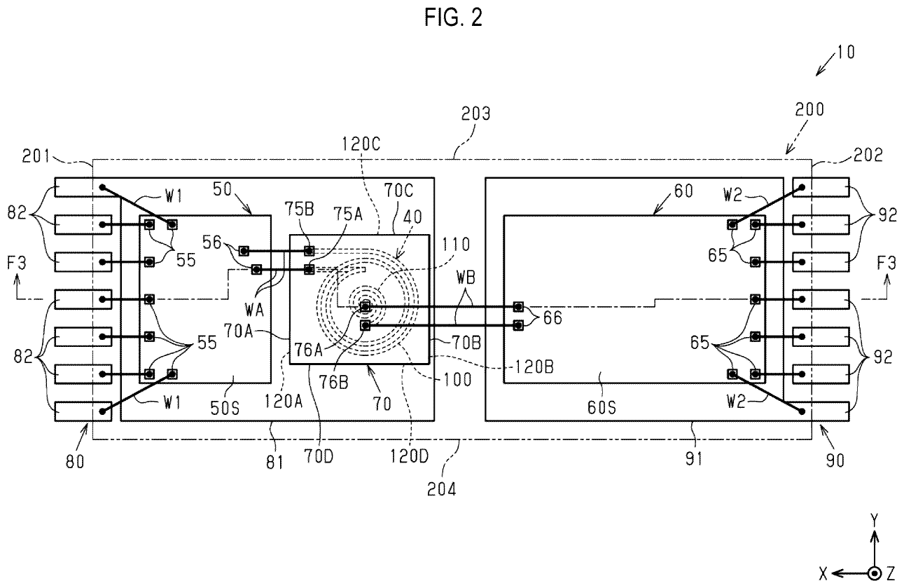

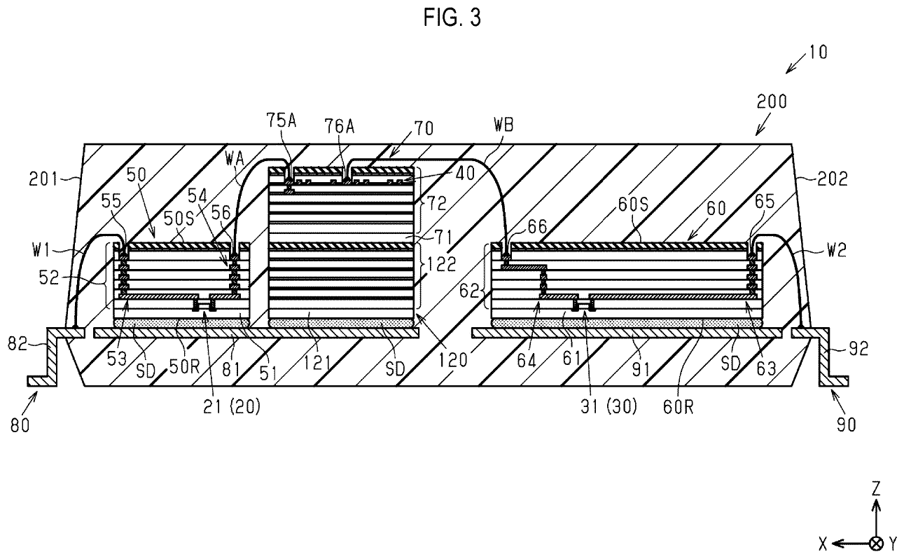

A schematic configuration of a semiconductor device 10 according to a first embodiment is described with reference to FIGS. 1 to 3. FIG. 1 shows a schematic circuit configuration of the semiconductor device 10 according to the first embodiment. FIG. 2 shows an example of a schematic internal configuration (planar structure) of the semiconductor device 10. In FIG. 2, a sealing resin 200 to be described later is shown by a two-dot chain line to show the internal configuration of the semiconductor device 10. FIG. 3 is a schematic diagram of a cross-sectional structure of the semiconductor device 10 of FIG. 2 taken along line F3-F3.

Further, FIG. 1 shows a simplified circuit configuration of the semiconductor device 10, so the number of external terminals of the semiconductor device 10 of FIG. 2 is larger than the number of external terminals of the semiconductor device 10 of FIG. 1. Herein, the number of external terminals of the semiconductor device 10 refers to the number of external electrodes that are able to connect the semiconductor device 10 to electronic components outside the semiconductor device 10.

### (Circuit Configuration of Semiconductor Device)

As shown in FIG. 1, the semiconductor device 10 includes a first circuit 20, a second circuit 30, and a transformer 40. The transformer 40 is configured to electrically insulate the first circuit 20 from the second circuit 30.

The first circuit 20 is configured to operate with a first voltage V1. In one example, the first circuit 20 includes a transmitting circuit or a receiving circuit. In the first embodiment, the first circuit 20 includes a transmitting circuit 21. The transmitting circuit 21 includes at least one transistor. The second circuit 30 is configured to operate with a second voltage V2. In one example, the second circuit 30 includes a transmitting circuit or a receiving circuit. In the first embodiment, the second circuit 30 includes a receiving circuit 31. The receiving circuit 31 includes at least one transistor. The first voltage V1 and the second voltage V2 may be the same as each other or may be different from each other. In one example, the second voltage V2 is equal to the first voltage V1. The semiconductor device 10 may be called a digital isolator. Therefore, the semiconductor device 10 may also be called a signal transmission device that transmits a signal from the first circuit 20 to the second circuit 30.

The transformer 40 includes a first coil 41 and a second coil 42. The first coil 41 is electrically connected to the transmitting circuit 21 of the first circuit 20. The second coil 42 is electrically connected to the receiving circuit 31 of the second circuit 30.

The transmitting circuit 21 of the first circuit 20 receives an input signal and pulse-drives the transformer 40. A pulse signal excited in the first coil 41 of the transformer 40 is transmitted through the second coil 42 and is input to the receiving circuit 31 of the second circuit 30. The receiving circuit 31 outputs an output signal based on the input pulse signal.

### (Internal Configuration of Semiconductor Device)

As shown in FIG. 2, the semiconductor device 10 includes a first chip 50, a second chip 60, a transformer chip 70, a first lead frame 80, a second lead frame 90, and a sealing resin 200. The sealing resin 200 is configured to seal the first chip 50, the second chip 60, and the transformer chip 70 and to partially seal the first lead frame 80 and the second lead frame 90. Further, in FIG. 2, the sealing resin 200 is shown by a two-dot chain line for the convenience of explaining the internal configuration of the semiconductor device 10.

In this way, in the semiconductor device 10, the first chip 50, the second chip 60, and the transformer chip 70 are packaged as a plurality of semiconductor chips by the sealing resin 200. Herein, the transformer chip 70 is an example of an “insulating chip.”

A package format of the semiconductor device 10 is a SO (Small Outline) type, and in the first embodiment, it is a SOP (Small Outline Package). Further, the package format of the semiconductor device 10 may be changed arbitrarily. The package format is not limited to SOP, and may be QFN (Quad For Non Lead Package), DFP (Dual Flat Package), DIP (Dual Inline Package), QFP (Quad Flat Package), SIP (Single Inline Package), or SOJ (Small Outline J-leaded Package), or various package structures similar to these.

The sealing resin 200 is made of a resin material having electrical insulation properties. This resin material includes, for example, black epoxy resin. The sealing resin 200 is formed in a rectangular plate shape with a thickness direction in a Z direction. The sealing resin 200 has four sealing side surfaces 201 to 204. More specifically, the sealing resin 200 has sealing side surfaces 201 and 202 as both end surfaces facing in an X direction and sealing side surfaces 203 and 204 as both end surfaces facing in a Y direction. The X direction and the Y direction are orthogonal to the Z direction. The X direction and the Y direction are orthogonal to each other when viewed from the Z direction. The sealing resin 200 has a rectangular shape with the X direction being a direction along a long side and the Y direction being a direction along a short side when viewed from the Z direction. Herein, the X direction corresponds to a “first direction.” In the following description, “plan view” means that the semiconductor device 10 or a component of the semiconductor device 10 is viewed from the Z direction.

Each of the first lead frame 80 and the second lead frame 90 is a conductor and is made of a material containing, for example, Cu (copper), Fe (iron), Al (aluminum), etc. Each of the lead frames 80 and 90 is provided across an inside and outside of the sealing resin 200. The first lead frame 80 and the second lead frame 90 are arranged to be spaced apart from each other in the X direction.

The first lead frame 80 includes a first die pad 81 disposed in the sealing resin 200 and a plurality of first leads 82 disposed across the inside and outside of the sealing resin 200. Each of the first leads 82 constitutes an external terminal that electrically connects to an electronic apparatus outside the semiconductor device 10.

The first chip 50 is mounted on the first die pad 81. It may be said that the first die pad 81 supports the first chip 50. In a plan view, the first die pad 81 is disposed so that its center in the X direction is closer to the sealing side surface 201 than a center of the sealing resin 200 in the X direction. In the first embodiment, the first die pad 81 is not exposed from the sealing resin 200. In one example, a shape of the first die pad 81 in a plan view is a rectangle with the X direction being a direction along a long side direction and the Y direction being a direction along a short side.

The plurality of first leads 82 are arranged to be spaced apart from each other in the Y direction. Among the plurality of first leads 82, a first lead 82 disposed at an end portion near the sealing side surface 203 in the Y direction is integrated with the first die pad 81. The remaining first leads 82 are disposed to be spaced apart from the first die pad 81 in the X direction. A portion of each of the first leads 82 protrudes from the sealing side surface 201 toward the outside of the sealing resin 200.

The second lead frame 90 includes a second die pad 91 disposed in the sealing resin 200 and a plurality of second leads 92 disposed across the inside and outside of the sealing resin 200. Each of the second leads 92 constitutes an external terminal that electrically connects to an electronic apparatus outside the semiconductor device 10.

The second chip 60 is mounted on the second die pad 91. It may be said that the second die pad 91 supports the second chip 60. In a plan view, the second die pad 91 is disposed to be closer to the sealing side surface 202 than the first die pad 81 in the X direction. That is, the first die pad 81 and the second die pad 91 are disposed to be spaced apart from each other in the X direction. Therefore, the X direction may also be said to be a disposition direction of both die pads 81 and 91. The second chip 60 is disposed to be spaced apart from the first chip 50 in the X direction. In the first embodiment, the second die pad 91 is not exposed from the sealing resin 200. In one example, a shape of the second die pad 91 in a plan view is a rectangle with the X direction being a direction along a long side and the Y direction being a direction along a short side. Also, the shape of the second die pad 91 in a plan view may be changed arbitrarily depending on the number and shape of semiconductor chips mounted on the second die pad 91.

The plurality of second leads 92 are arranged to be spaced apart from each other in the Y direction. Among the plurality of second leads 92, a second lead 92 disposed at an end portion near the sealing side surface 204 in the Y direction is integrated with the second die pad 91. The remaining second leads 92 are disposed to be spaced apart from the second die pad 91 in the X direction. A portion of each of the second leads 92 protrudes from the sealing side surface 202 toward the outside of the sealing resin 200.

In the first embodiment, the number of second leads 92 is the same as the number of first leads 82. As shown in FIG. 2, the plurality of first leads 82 and the plurality of second leads 92 are arranged in a direction (Y direction) orthogonal to the arrangement direction (X direction) of the first die pad 81 and the second die pad 91 in a plan view. The number of second leads 92 and the number of first leads 82 may be changed arbitrarily. In one example, the number of first leads 82 and the number of second leads 92 may be different from each other.

In the first embodiment, the first die pad 81 is supported by the first lead 82 integrated with the first die pad 81. The second die pad 91 is supported by the second lead 92 integrated with the second die pad 91. Therefore, each of the die pads 81 and 91 does not have a hanging lead exposed from each of the sealing side surfaces 203 and 204. Therefore, an insulation distance between the first lead frame 80 and the second lead frame 90 may be made large.

The first chip 50 mounted on the first die pad 81 includes the first circuit 20 of FIG. 1. The first chip 50 is formed in a rectangular shape having short and long sides in a plan view. In a plan view, the first chip 50 is mounted on the first die pad 81 so that the long side is aligned along the Y direction and the short side is aligned along the X direction. As shown in FIG. 3, the first chip 50 is bonded to the first die pad 81 by a conductive bonding material SD. The conductive bonding material SD is, for example, a solder paste, an Ag (silver) paste, etc.

As shown in FIGS. 2 and 3, the first chip 50 includes a plurality of first pads 55 and a plurality of first intermediate pads 56. Each of the plurality of first pads 55 and the plurality of first intermediate pads 56 is electrically connected to the first circuit 20. Further, the plurality of first pads 55 are individually connected to the plurality of first leads 82 by first wires W1. The plurality of first intermediate pads 56 are individually electrically connected to the transformer chip 70 by first intermediate wires WA.

As shown in FIG. 2, the second chip 60 mounted on the second die pad 91 includes the second circuit 30 of FIG. 1. The second chip 60 is formed in a rectangular shape having short and long sides in a plan view. In a plan view, the second chip 60 is mounted on the second die pad 91 so that a long side is aligned along the X direction and a short side is aligned along the Y direction. As shown in FIG. 3, the second chip 60 is bonded to the second die pad 91 by a conductive bonding material SD.

As shown in FIGS. 2 and 3, the second chip 60 includes a plurality of second pads 65 and a plurality of second intermediate pads 66. Each of the plurality of second pads 65 and the plurality of second intermediate pads 66 is electrically connected to the second circuit 30. Further, the plurality of second pads 65 are individually connected to the plurality of second leads 92 by second wires W2. The plurality of second intermediate pads 66 are individually electrically connected to the transformer chip 70 by second intermediate wires WB.

Each of the first pads 55, each of the first intermediate pads 56, each of the second pads 65, and each of the second intermediate pads 66 is made of a material containing one or more appropriately selected from the group of, for example, Ti (titanium), TiN (titanium nitride), Au (gold), Ag, Cu, Al (aluminum), and W (tungsten). Each of the wires W1, each of the first intermediate wires WA, each of the wires W2, and each of the second intermediate wires WB is a bonding wire formed by a wire bonding device and is made of a conductor containing, for example, Au, Al, Cu, etc.

As shown in FIGS. 2 and 3, in the first embodiment, the transformer chip 70 is disposed over the die pad 81. It may be said that both the first chip 50 and the transformer chip 70 are disposed over the first die pad 81. The transformer chip 70 is disposed between the first chip 50 and the second chip 60 in the X direction. A distance between the transformer chip 70 and the second chip 60 in the X direction is larger than a distance between the transformer chip 70 and the first chip 50 in the X direction.

The transformer chip 70 includes the transformer 40 of FIG. 1. The transformer chip 70 is formed in a rectangular shape having short sides and long sides in a plan view. In a plan view, the transformer chip 70 is disposed over the first chip 50 so that a long side is aligned along the X direction and a short side is aligned along the Y direction. As shown in FIG. 2, in the first embodiment, a dimension of the transformer chip 70 in the Y direction is smaller than both a dimension of the first chip 50 in the Y direction and a dimension of the second chip 60 in the Y direction. Also, the dimension of the transformer chip 70 in the Y direction may be changed arbitrarily. In one example, the dimension of the transformer chip 70 in the Y direction may be equal to the dimension of the first chip 50 in the Y direction. In one example, the dimension of the transformer chip 70 in the Y direction may be equal to the dimension of the second chip 60 in the Y direction. An electrical connection structure of the transformer chip 70 with the first chip 50 and the second chip 60 is described in detail later.

Further, the configuration of the semiconductor device 10 shown in FIGS. 1 to 3 is an example, and circuit configurations included in the first chip 50 and the second chip 60 may be changed as appropriate. The first circuit 20 may include a circuit other than the transmitting circuit 21. The second circuit 30 may include a circuit other than the receiving circuit 31. For example, the first circuit 20 may include an analog-digital conversion circuit. In this case, the semiconductor device 10 is configured as an insulated A/D conversion device.

Further, for example, the second circuit 30 may include a driver circuit that drives a gate of a switching element. The driver circuit may also be connected to an external terminal (for example, the second lead 92 shown in FIG. 2) of the semiconductor device 10. In this case, the semiconductor device 10 is configured as an insulated gate driver that drives the switching element. The switching element is a power semiconductor element such as a SiMOSFET (Si Metal-Oxide-Semiconductor Field-Effect Transistor), a SiCMOSFET, or an IGBT (Insulated Gate Bipolar Transistor). The driver circuit is generally a half-bridge circuit in which a low-side switching element and a high-side switching element are connected in a totem pole shape.

The semiconductor device 10 used as the insulated gate driver applies a drive voltage signal to a control terminal of the switching element. In this case, the transmitting circuit 21 of the first circuit 20 converts a control signal input from, for example, a control device, into a pulse signal. The driver circuit of the second circuit 30 outputs the drive voltage signal to the control terminal of the switching element in response to a signal received by the receiving circuit 31 through the transformer 40.

In this way, in the semiconductor device 10 used as the insulated gate driver, a power supply voltage of the first circuit 20 that receives a signal from the control device is 5 V, 3.3 V, etc. with respect to a ground potential. On the other hand, in the case of the second circuit 30 connected to the high-side switching element, a voltage (for example, 600 V or higher) equivalent to a voltage applied to a drain of the high-side switching element is applied transiently. For this reason, the semiconductor device 10 is required to have a dielectric breakdown voltage between the first circuit 20 and the second circuit 30, more specifically between the first coil 41 and the second coil 42 of the transformer 40. This dielectric breakdown voltage is, for example, 2,500 Vrms or higher and 7,500 Vrms or lower. In one example, the dielectric breakdown voltage of the semiconductor device 10 is about 5,000 Vrms. However, the specific value of the dielectric breakdown voltage of the semiconductor device 10 is not limited thereto and is arbitrary.

### (Configuration of First Chip)

An example of a configuration of the first chip 50 is described with reference to FIGS. 2 and 3. As shown in FIGS. 2 and 3, the first chip 50 having a rectangular flat plate shape includes a chip front surface 50S and a chip back surface 50R facing opposite sides to each other in the Z direction. The chip front surface 50S of the first chip 50 is, for example, a surface of the first chip 50 opposite to the first die pad 81 in the Z direction. The chip back surface 50R is a surface of the first chip 50 facing the first die pad 81. The plurality of first pads 55 and the plurality of first intermediate pads 56 are exposed from the chip front surface 50S.

As shown in FIG. 3, the first chip 50 includes a first semiconductor substrate 51 and a first element insulating layer 52 formed over the first semiconductor substrate 51. The first semiconductor substrate 51 constitutes the chip back surface 50R, and the first element insulating layer 52 constitutes the chip front surface 50S.

The first semiconductor substrate 51 (the chip back surface 50R) is bonded to the first die pad 81 by a conductive bonding material SD. The first semiconductor substrate 51 is made of a material containing, for example, Si. In the first embodiment, the first semiconductor substrate 51 is a Si substrate. Further, a wide band gap semiconductor or a compound semiconductor may be used for the first semiconductor substrate 51. The wide band gap semiconductor is a semiconductor substrate having a band gap of 2.0 eV or higher. The wide band gap semiconductor may be SiC (silicon carbide). The compound semiconductor may be a Group III-V compound semiconductor. The compound semiconductor may include at least one selected from the group of AlN (aluminum nitride), InN (indium nitride), GaN (gallium nitride), and GaAs (gallium arsenide). The first circuit 20 of FIG. 1 is formed at the first semiconductor substrate 51.

The first element insulating layer 52 includes a stack structure in which a plurality of insulating films are stacked in the Z direction. Each insulating film is made of a material containing at least one selected from the group of, for example, SiN and SiO₂. In one example, the first element insulating layer 52 includes a stack structure in which a plurality of insulating films containing SiO₂ are stacked in the Z direction. The first circuit 20, a first connection wiring 53 that connects the first circuit 20 and the first pads 55, and a second connection wiring 54 that connects the first circuit 20 and the first intermediate pads 56 are provided within the first element insulating layer 52. The first connection wiring 53 is provided in plural depending on, for example, the number of first pads 55. The second connection wiring 54 is provided in plural depending on, for example, the number of first intermediate pads 56. In this way, the first circuit 20 and the plurality of first pads 55 are individually electrically connected within the first element insulating layer 52. The first circuit 20 and the plurality of first intermediate pads 56 are individually electrically connected within the first element insulating layer 52.

### (Configuration of Second Chip)

An example of a configuration of the second chip 60 is described with reference to FIGS. 2 and 3. As shown in FIGS. 2 and 3, the second chip 60 having a rectangular flat plate shape includes a chip front surface 60S and a chip back surface 60R facing opposite sides to each other in the Z direction. The chip front surface 60S of the second chip 60 faces a same side as the chip front surface 50S of the first chip 50. The chip back surface 60R faces the second die pad 91 (see FIG. 3). The plurality of second pads 65 and the plurality of second intermediate pads 66 are exposed from the chip front surface 60S.

As shown in FIG. 3, the second chip 60 includes a second semiconductor substrate 61 and a second element insulating layer 62 formed over the second semiconductor substrate 61. The second semiconductor substrate 61 constitutes the chip back surface 60R, and the second element insulating layer 62 constitutes the chip front surface 60S.

The second semiconductor substrate 61 (the chip back surface 60R) is bonded to the second die pad 91 by a conductive bonding material SD. The second semiconductor substrate 61 is made of a material containing, for example, Si. In the first embodiment, the second semiconductor substrate 61 is a Si substrate. Also, a wide band gap semiconductor or a compound semiconductor may be used for the second semiconductor substrate 61. The second circuit 30 of FIG. 1 is formed at the second semiconductor substrate 61.

The second element insulating layer 62 includes a stack structure in which a plurality of insulating films are stacked in the Z direction. Each insulating film is made of a material containing at least one selected from the group of, for example, SiN and SiO₂. In one example, the second element insulating layer 62 includes a stack structure in which a plurality of insulating films containing SiO₂ are stacked in the Z direction. The second circuit 30, a third connection wiring 63 that connects the second circuit 30 and the second pads 65, and a fourth connection wiring 64 that connects the second circuit 30 and the second intermediate pads 66 are provided within the second element insulating layer 62. The third connection wiring 63 is provided in plural depending on, for example, the number of second pads 65. The fourth connection wiring 64 is provided in plural depending on, for example, the number of second intermediate pads 66. In this way, the second circuit 30 and the plurality of second pads 65 are individually electrically connected within the second element insulating layer 62. The second circuit 30 and the plurality of second intermediate pads 66 are individually electrically connected within the second element insulating layer 62.

### (Configuration of Transformer Chip)

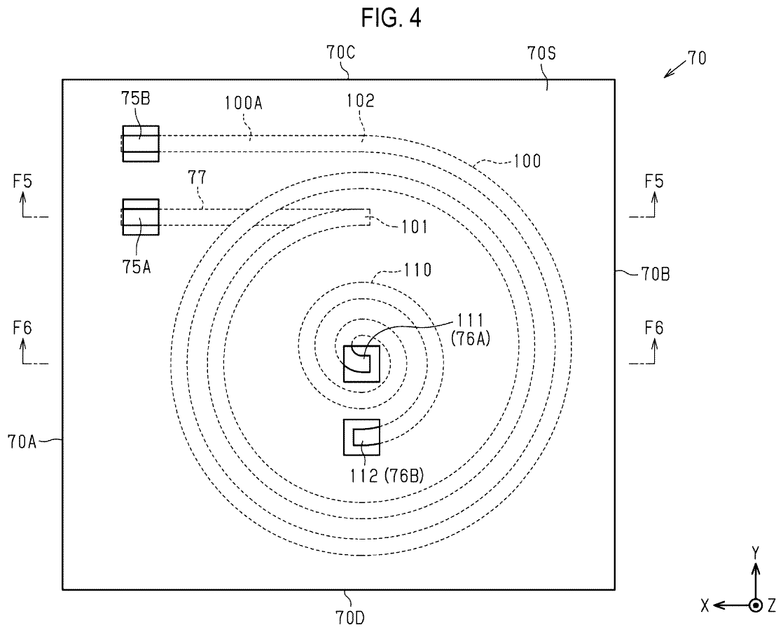

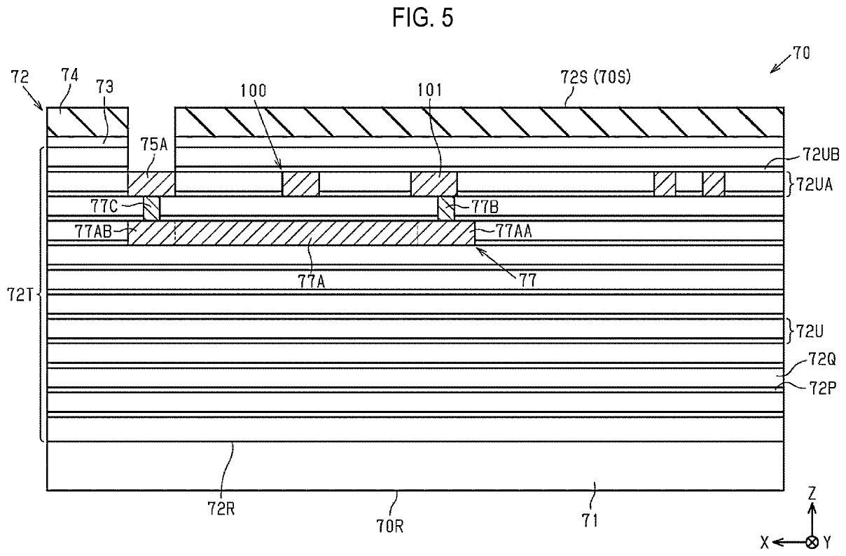

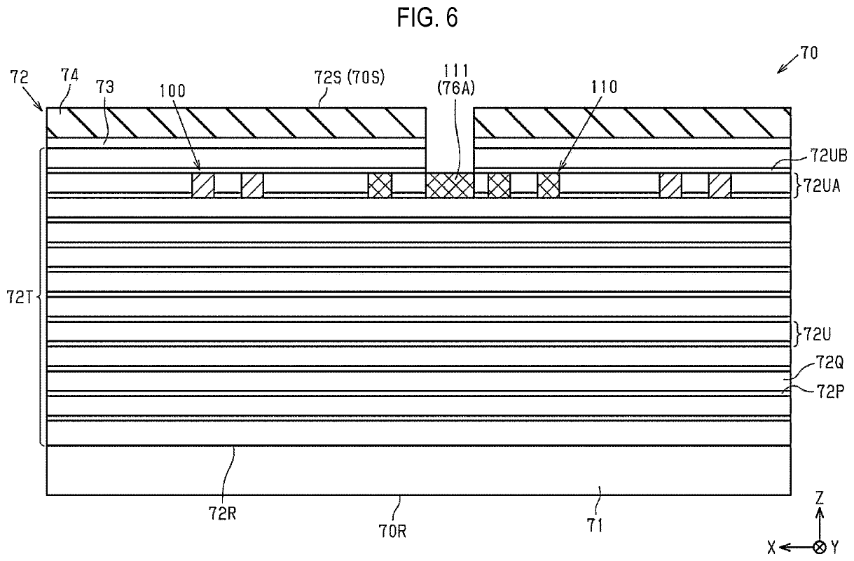

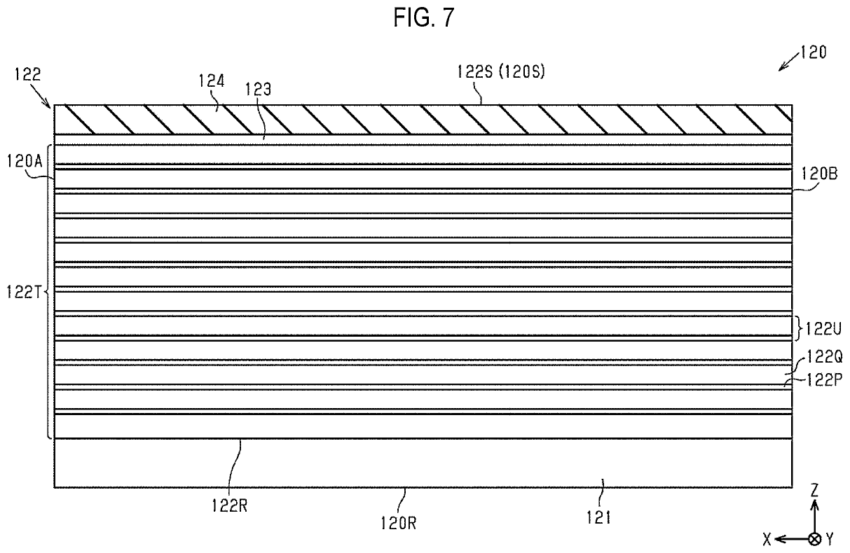

An example of the configuration of the transformer chip 70 and its periphery are described with reference to FIGS. 3 to 7. FIG. 4 shows a schematic planar structure of the transformer chip 70. FIG. 5 shows a schematic cross-sectional structure of the transformer chip 70 taken along line F5-F5 in FIG. 4. FIG. 6 shows a schematic cross-sectional structure of the transformer chip 70 taken along line F6-F6 in FIG. 4. FIG. 7 is a schematic cross-sectional structure of a sub-mount chip 120 that supports the transformer chip 70. The cross-sectional position in FIG. 7 is the same as the cross-sectional position of, for example, the transformer chip 70 in FIG. 5.

As shown in FIG. 4, the transformer chip 70 having a rectangular flat plate shape includes a chip front surface 70S and a chip back surface 70R (see FIG. 5) facing opposite sides to each other in the Z direction, and four chip side surfaces 70A to 70D connecting the chip front surface 70S and the chip back surface 70R. The chip front surface 70S of the transformer chip 70 faces a same side as the chip front surface 50S (see FIG. 3) of the first chip 50. The chip back surface 70R faces a same side as the chip back surface 50R (see FIG. 3). The chip side surfaces 70A and 70B constitute both end surfaces of the transformer chip 70 in the X direction, and the chip side surfaces 70C and 70D constitute both end surfaces of the transformer chip 70 in the Y direction. The chip side surface 70A faces the first chip 50 (see FIG. 2), and the chip side surface 70B faces the second chip 60 (see FIG. 2). The chip side surface 70C faces a same side as the sealing side surface 203 (see FIG. 2) of the sealing resin 200, and the chip side surface 70D faces a same side as the sealing side surface 204 (see FIG. 2) of the sealing resin 200.

The transformer chip 70 includes first transformer pads 75A and 75B and second transformer pads 76A and 76B exposed from the chip front surface 70S in the Z direction. The first transformer pads 75A and 75B are pads electrically connected to the plurality of first intermediate pads 56 (see FIG. 2) of the first chip 50. Specifically, the first transformer pads 75A and 75B and the plurality of first intermediate pads 56 are individually connected by the plurality of first intermediate wires WA (see FIG. 2). The first transformer pads 75A and 75B are disposed near the chip side surface 70A and the chip side surface 70C in a plan view. In the example shown in FIG. 4, the first transformer pads 75A and 75B are disposed at a same position in the X direction and spaced apart from each other in the Y direction.

The second transformer pads 76A and 76B are pads electrically connected to the plurality of second intermediate pads 66 (see FIG. 2) of the second chip 60. Specifically, the second transformer pads 76A and 76B and the plurality of second intermediate pads 66 are individually connected by the plurality of second intermediate wires WB (see FIG. 2). The second transformer pads 76A and 76B are disposed at an approximate center in the X direction and near the sealing side surface 204 (see FIG. 2) in the Y direction in a plan view. In one example, the second transformer pads 76A and 76B are disposed at a same position in the X direction and spaced apart from each other in the Y direction.

As shown in FIG. 5, the transformer chip 70 includes a third semiconductor substrate 71 and a third element insulating layer 72 formed over the third semiconductor substrate 71. Herein, the third semiconductor substrate 71 is an example of a “semiconductor substrate of insulating chip,” and the third element insulating layer 72 is an example of an “element insulating layer of insulating chip.”

The third semiconductor substrate 71 constitutes the chip back surface 70R of the transformer chip 70. The third semiconductor substrate 71 is made of a material containing, for example, Si. In the first embodiment, the third semiconductor substrate 71 is a Si substrate. Also, a wide band gap semiconductor or a compound semiconductor may be used for the third semiconductor substrate 71.

A dimension (thickness) of the third semiconductor substrate 71 in the Z direction may be the same as, for example, a dimension (thickness) of the first semiconductor substrate 51 in the Z direction. A dimension (thickness) of the third element insulating layer 72 in the Z direction may be smaller than, for example, a dimension (thickness) of the first element insulating layer 52 (see FIG. 3) in the Z direction. Therefore, a dimension of the transformer chip 70 in the Z direction may be smaller than a dimension of the first chip 50 in the Z direction.

Herein, the dimension of the third semiconductor substrate 71 in the Z direction may be changed arbitrarily. In one example, the dimension of the third semiconductor substrate 71 in the Z direction may be smaller than the dimension of the first semiconductor substrate 51 in the Z direction. Further, the dimension of the third element insulating layer 72 in the Z direction may be changed arbitrarily. In one example, the dimension of the third element insulating layer 72 in the Z direction may be equal to the dimension of the first element insulating layer 52 in the Z direction.

The third element insulating layer 72 includes a third element front surface 72S and a third element back surface 72R facing opposite sides to each other. The third element front surface 72S constitutes the chip front surface 70S of the transformer chip 70. The third element back surface 72R is in contact with the third semiconductor substrate 71.

The third element insulating layer 72 includes a plurality of first insulating films 72P and a plurality of second insulating films 72Q. In other words, the third element insulating layer 72 includes an insulating layer stack structure 72T that is a stacked body of the plurality of first insulating films 72P and the plurality of second insulating films 72Q. The insulating layer stack structure 72T is configured by alternately stacking the plurality of first insulating films 72P and the plurality of second insulating films 72Q one by one in the Z direction. Herein, if a stacked body of one first insulating film 72P and one second insulating film 72Q is defined as an insulator 72U, the insulating layer stack structure 72T may be said to be a structure in which a plurality of insulators 72U are stacked. In this way, the Z direction may also be said to be a thickness direction of the third element insulating layer 72.

The first insulating film 72P is an etching stopper film and is made of a material containing at least one selected from the group of, for example, SiN, SiC, and SiCN (nitrogen-doped silicon carbide). The first insulating film 72P may also have a function of, for example, preventing the diffusion of Cu. In other words, the first insulating film 72P may be a Cu diffusion prevention film.

The second insulating film 72Q is an interlayer insulating film and is, for example, an oxide film made of a material containing SiO₂. The second insulating film 72Q has a thickness greater than the first insulating film 72P. The first insulating film 72P has a thickness of, for example, 50 nm or more and less than 1,000 nm. The second insulating film 72Q has a thickness of, for example, 500 nm or more and 5,000 nm or less. In the first embodiment, the first insulating film 72P has a thickness of about 300 nm, and the second insulating film 72Q has a thickness of about 2,000 nm. In one example, both uppermost and lowermost insulating films of the insulating layer stack structure 72T are composed of the second insulating film 72Q. In order to facilitate understanding of the figure, a ratio of the film thickness of the first insulating film 72P to the film thickness of the second insulating film 72Q in the figure is different from an actual ratio of the film thickness of the first insulating film 72P to the film thickness of the second insulating film 72Q.

The third element insulating layer 72 further includes a protective film 73 and a passivation film 74. The protective film 73 is a film that protects the insulating layer stack structure 72T. The protective film 73 is formed over the insulating layer stack structure 72T. The protective film 73 is made of, for example, a material containing SiO₂. In one example, the protective film 73 is formed over an entire surface of the insulating layer stack structure 72T in a plan view. Also, the material constituting the protective film 73 may be changed arbitrarily. In one example, the protective film 73 may be made of a material containing SiN.

The passivation film 74 is a surface protective film of the transformer chip 70. The passivation film 74 is formed over the protective film 73. The passivation film 74 constitutes the third element front surface 72S of the third element insulating layer 72. The passivation film 74 is made of, for example, a material containing at least one selected from the group of PI (polyimide), SiN, and SiO₂. In one example, the passivation film 74 is made of a material containing SiO₂. In one example, the passivation film 74 is formed over an entire surface of the protective film 73 in a plan view. Also, the material constituting the passivation film 74 may be changed arbitrarily. The passivation film 74 may be made of a same material as the protective film 73, or may be made of a material different from the protective film 73.

As shown in FIG. 4, the transformer chip 70 includes an outer coil 100 and an inner coil 110. As shown in FIGS. 5 and 6, both the outer coil 100 and the inner coil 110 are embedded in the third element insulating layer 72. In other words, the transformer 40 is embedded in the third element insulating layer 72. The outer coil 100 corresponds to the first coil 41 of the transformer 40 in FIG. 1, and the inner coil 110 corresponds to the second coil 42 of the transformer 40. Herein, both the outer coil 100 and the inner coil 110 are examples of an “insulating element.”

In one example, the outer coil 100 and the inner coil 110 are disposed at a same position in the Z direction. It may be said that the outer coil 100 and the inner coil 110 are disposed over a same plane orthogonal to the Z direction. Specifically, the outer coil 100 and the inner coil 110 are provided to penetrate a specific insulator 72UA which is one specific insulator 72U. In the example shown in FIGS. 5 and 6, the specific insulator 72UA is an insulator 72U immediately below an uppermost insulator 72U of the insulating layer stack structure 72T. In other words, the specific insulator 72UA is a second insulator 72U from the third element front surface 72S in the insulating layer stack structure 72T. That is, in the example shown in FIGS. 5 and 6, the outer coil 100 and the inner coil 110 are disposed to be closer to the third element front surface 72S than a center of the third element insulating layer 72 in the Z direction. Also, the specific insulator 72UA in the insulating layer stack structure 72T is arbitrary. In one example, the specific insulator 72UA may be the uppermost insulator 72U of the insulating layer stack structure 72T.

In a plan view, the inner coil 110 is disposed inside the outer coil 100. The inner coil 110 is disposed so as not to overlap the outer coil 100 in a plan view. In other words, the inner coil 110 is disposed to be spaced apart from the outer coil 100 in a direction orthogonal to the Z direction. Therefore, the specific insulator 72UA is disposed between the inner coil 110 and the outer coil 100 in the direction orthogonal to the Z direction. In this way, the outer coil 100 and the inner coil 110 are electrically insulated from each other and are configured to be magnetically coupled. In the transformer 40 of the first embodiment, the outer coil 100 and the inner coil 110 are configured to be capable of being magnetically coupled along the direction orthogonal to the Z direction. Therefore, a current flows in the inner coil 110 in a direction corresponding to a direction of a magnetic flux generated by a current flowing in the outer coil 100.

As shown in FIG. 4, the outer coil 100 includes a first end 101 and a second end 102 opposite to the first end 101. The outer coil 100 is formed in a circular spiral shape in a plan view. In the spiral-shaped outer coil 100, the first end 101 is disposed inside the spiral, and the second end 102 is disposed outside the spiral. That is, the outer coil 100 is wound in a spiral shape with the first end 101 as an inner peripheral end and the second end 102 as an outer peripheral end. The outer coil 100 includes a lead wire 100A extending along the X direction from the second end 102 toward the chip side surface 70A. The lead wire 100A is disposed at a same position as the outer coil 100 in the Z direction. In one example, the lead wire 100A is formed to be integrated with the outer coil 100.

A tip of the lead wire 100A constitutes the first transformer pad 75B. In one example, the third element insulating layer 72 is provided with a second outer opening that exposes the tip of the lead wire 100A in the Z direction. The tip of the lead wire 100A exposed by the second outer opening constitutes the first transformer pad 75B.

The inner coil 110, which is disposed inside the outer coil 100, includes a first end 111 and a second end 112 opposite to the first end 111. The inner coil 110 is formed in a circular spiral shape in a plan view. In the spiral-shaped inner coil 110, the first end 111 is disposed inside the spiral, and the second end 112 is disposed outside the spiral. That is, the inner coil 110 is wound in a spiral shape with the first end 111 as an inner peripheral end and the second end 112 as an outer peripheral end.

The first end 111 constitutes the second transformer pad 76A, and the second end 112 constitutes the second transformer pad 76B. In one example, the third element insulating layer 72 is provided with a first inner opening that exposes the first end 111 in the Z direction, and a second inner opening that exposes the second end 112 in the Z direction. The first end 111 exposed by the first inner opening constitutes the second transformer pad 76A, and the second end 112 exposed by the second inner opening constitutes the second transformer pad 76B.

Both the outer coil 100 and the inner coil 110 are made of a material containing one or more appropriately selected from the group of Ti (titanium), TiN (titanium nitride), Au, Ag, Cu, Al, and W (tungsten). In one example, the outer coil 100 and the inner coil 110 may be made of a same material. In one example, the outer coil 100 and the inner coil 110 may be made of a material containing Cu.

The transformer chip 70 includes a wiring portion 77 that electrically connects the first end 101 of the outer coil 100 and the first transformer pad 75A. The wiring portion 77 is made of, for example, a material containing one or more appropriately selected from the group of Ti, TiN, Au, Ag, Cu, Al, and W.

As shown in FIG. 5, the wiring portion 77 includes a connection wiring 77A and vias 77B and 77C. The connection wiring 77A is disposed to be closer to the third semiconductor substrate 71 than the outer coil 100 is disposed in the Z direction. The connection wiring 77A extends along the X direction from the first end 101 of the outer coil 100 toward the chip side surface 70A in a plan view. The connection wiring 77A includes a first end 77AA and a second end 77AB which are both ends in the X direction. The first end 77AA of the connection wiring 77A is electrically connected to the first end 101 of the outer coil 100 by the via 77B. The second end 77AB of the connection wiring 77A is electrically connected to the first transformer pad 75A by the via 77C. The first transformer pad 75A is exposed in the Z direction by a first outer opening provided in the third element insulating layer 72.

As shown in FIG. 3, the semiconductor device 10 includes the sub-mount chip 120 provided separately from the first chip 50 and the second chip 60. The sub-mount chip 120 is disposed over the first die pad 81. The sub-mount chip 120 is bonded to the first die pad 81 by, for example, a conductive bonding material SD. The transformer chip 70 is disposed over the sub-mount chip 120. In the following description, a state in which the transformer chip 70 is disposed over the sub-mount chip 120 is referred to as a “chip disposition state.”

As shown in FIGS. 2 and 7, the sub-mount chip 120 includes a chip front surface 120S and a chip back surface 120R facing opposite sides to each other in the Z direction, and four chip side surfaces 120A to 120D connecting the chip front surface 120S and the chip back surface 120R. The chip front surface 120S of the sub-mount chip 120 faces a same side as the chip front surface 50S (see FIG. 3) of the first chip 50. The chip back surface 120R faces a same side as the chip back surface 50R (see FIG. 3). The chip back surface 120R is in contact with the conductive bonding material SD. The chip side surfaces 120A and 120B constitute both end surfaces of the sub-mount chip 120 in the X direction, and the chip side surfaces 120C and 120D constitute both end surfaces of the sub-mount chip 120 in the Y direction. The chip side surface 120A faces toward the first chip 50, and the chip side surface 120B faces toward the second chip 60. The chip side surface 120C faces a same side as the sealing side surface 203 (see FIG. 2) of the sealing resin 200, and the chip side surface 120D faces a same side as the sealing side surface 204 (see FIG. 2) of the sealing resin 200.

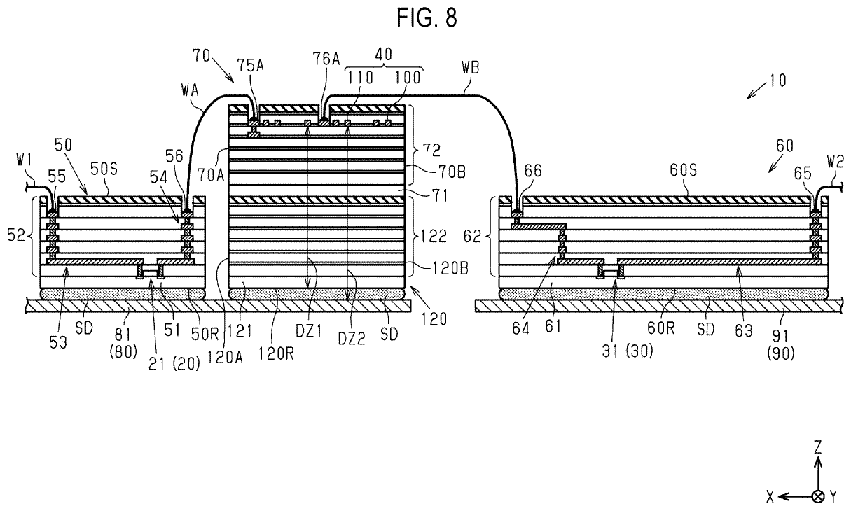

As shown in FIGS. 2 and 8, the sub-mount chip 120 has a same size as the transformer chip 70 in a plan view. In the first embodiment, in the chip disposition state, the chip side surface 120A of the sub-mount chip 120 is flush with the chip side surface 70A of the transformer chip 70, and the chip side surface 120B of the sub-mount chip 120 is flush with the chip side surface 70B of the transformer chip 70. Further, as shown in FIG. 2, in the first embodiment, in the chip disposition state, the chip side surface 120C of the sub-mount chip 120 is flush with the chip side surface 70C of the transformer chip 70, and the chip side surface 120D of the sub-mount chip 120 is flush with the chip side surface 70D of the transformer chip 70.

As shown in FIG. 7, the sub-mount chip 120 includes a fourth semiconductor substrate 121 and an insulating layer 122 formed over the fourth semiconductor substrate 121. Herein, the fourth semiconductor substrate 121 is an example of a “sub-mount semiconductor substrate.”

The fourth semiconductor substrate 121 constitutes the chip back surface 120R of the sub-mount chip 120. The fourth semiconductor substrate 121 is in contact with the conductive bonding material SD (see FIG. 8). The fourth semiconductor substrate 121 is made of a material containing, for example, Si. In the first embodiment, the fourth semiconductor substrate 121 is a Si substrate. Also, a wide band gap semiconductor or a compound semiconductor may be used for the fourth semiconductor substrate 121.

The insulating layer 122 includes an element front surface 122S and an element back surface 122R facing opposite sides to each other. The element front surface 122S constitutes the chip front surface 120S of the sub-mount chip 120. The element back surface 122R is in contact with the fourth semiconductor substrate 121.

The insulating layer 122 includes a plurality of first insulating films 122P and a plurality of second insulating films 122Q. That is, the insulating layer 122 includes an insulating layer stack structure 122T, which is a stacked body of the plurality of first insulating films 122P and the plurality of second insulating films 122Q. The insulating layer stack structure 122T is configured by alternately stacking the plurality of first insulating films 122P and the plurality of second insulating films 122Q one by one in the Z direction. Herein, if a stacked body of one first insulating film 122P and one second insulating film 122Q is defined as an insulator 122U, the insulating layer stack structure 122T may be said to be a structure in which a plurality of insulators 122U are stacked. In this way, the Z direction may also be said to be a thickness direction of the insulating layer 122.

The first insulating film 122P is an etching stopper film and is made of a material containing at least one selected from the group of, for example, SiN, SiC, and SiCN. The first insulating film 122P has a thickness of, for example, 50 nm or more and less than 1,000 nm. In the first embodiment, the first insulating film 122P has a thickness of about 300 nm.

The second insulating film 122Q is an interlayer insulating film and is, for example, an oxide film made of a material containing SiO₂. The second insulating film 122Q has a thickness greater than the first insulating film 122P. The second insulating film 122Q has a thickness of, for example, 500 nm or more and 5,000 nm or less. In the first embodiment, the second insulating film 122Q has a thickness of about 2,000 nm. In one example, both uppermost and lowermost insulating films of the insulating layer stack structure 122T are composed of the second insulating film 122Q. In order to facilitate understanding of the figure, a ratio of the film thickness of the first insulating film 122P to the film thickness of the second insulating film 122Q in the figure is different from an actual ratio of the film thickness of the first insulating film 122P to the film thickness of the second insulating film 122Q.

In one example, the film thickness of the first insulating film 122P is equal to the film thickness of the first insulating film 72P of the third element insulating layer 72 of the transformer chip 70. In one example, the film thickness of the second insulating film 122Q is equal to the film thickness of the second insulating film 72Q of the third element insulating layer 72. Further, the film thickness of the first insulating film 122P and the film thickness of the second insulating film 122Q may be changed arbitrarily.

The insulating layer 122 further includes a protective film 123 and a passivation film 124. Both the protective film 123 and the passivation film 124 are formed at a side of a surface layer of the insulating layer 122. Herein, the side of the surface layer of the insulating layer 122 refers to a portion of the insulating layer 122 that is close to the element front surface 122S and includes the element front surface 122S. Therefore, it may be said that the side of the surface layer of the insulating layer 122 is also a portion that is close to the chip front surface 120S of the sub-mount chip 120 and includes the chip front surface 120S.

The protective film 123 is a film that protects the insulating layer stack structure 122T. The protective film 123 is formed over the insulating layer stack structure 122T. The protective film 123 is formed of a material containing, for example, SiO₂. In one example, the protective film 123 is formed over an entire surface of the insulating layer stack structure 122T in a plan view. Further, the material constituting the protective film 123 may be changed arbitrarily. In one example, the protective film 123 may be made of a material containing SiN.

The passivation film 124 is a surface protective film of the sub-mount chip 120. The passivation film 124 is formed over the protective film 123. The passivation film 124 constitutes the element front surface 122S of the insulating layer 122. The passivation film 124 is made of a material containing at least one selected from the group of, for example, PI, SiN, and SiO₂. In one example, the passivation film 124 is made of a material containing SiO₂. In one example, the passivation film 124 is formed over an entire surface of the protective film 123 in a plan view. Further, the material constituting the passivation film 124 may be changed arbitrarily. The passivation film 124 may be made of a same material as the protective film 123, or may be made of a material different from the protective film 123.

As shown in FIG. 8, a dimension (thickness) of the fourth semiconductor substrate 121 in the Z direction may be equal to, for example, the dimension (thickness) of the third semiconductor substrate 71 in the Z direction. A dimension (thickness) of the insulating layer 122 in the Z direction may be larger than, for example, the dimension (thickness) of the third element insulating layer 72 in the Z direction. Therefore, a dimension (thickness) of the sub-mount chip 120 in the Z direction may be larger than the dimension (thickness) of the transformer chip 70 in the Z direction. Further, the dimension of the fourth semiconductor substrate 121 in the Z direction may be equal to, for example, the dimension (thickness) of the first semiconductor substrate 51 in the Z direction. The dimension of the insulating layer 122 in the Z direction may be equal to, for example, the dimension (thickness) of the first element insulating layer 52 in the Z direction. Therefore, the dimension of the sub-mount chip 120 in the Z direction may be equal to the dimension (thickness) of the first chip 50 in the Z direction. Similarly, the dimension of the fourth semiconductor substrate 121 in the Z direction may be equal to, for example, a dimension (thickness) of the second semiconductor substrate 61 in the Z direction. The dimension of the insulating layer 122 in the Z direction may be equal to, for example, a dimension (thickness) of the second element insulating layer 62 in the Z direction. Therefore, the dimension of the sub-mount chip 120 in the Z direction may be equal to a dimension (thickness) of the second chip 60 in the Z direction.

Herein, the dimension of the fourth semiconductor substrate 121 in the Z direction may be changed arbitrarily. In one example, the dimension of the fourth semiconductor substrate 121 in the Z direction may be smaller than the dimension of the third semiconductor substrate 71 in the Z direction. Further, the dimension of the insulating layer 122 in the Z direction may be changed arbitrarily. In one example, the dimension of the insulating layer 122 in the Z direction may be the same as the dimension of the third element insulating layer 72 in the Z direction.

In the chip disposition state, the third semiconductor substrate 71 of the transformer chip 70 is in contact with the insulating layer 122 of the sub-mount chip 120. More specifically, in the chip disposition state, the third semiconductor substrate 71 is in contact with the passivation film 124 of the insulating layer 122. In this way, in the chip disposition state, the third semiconductor substrate 71 is interposed between the third element insulating layer 72 and the sub-mount chip 120 in the Z direction. More specifically, the third semiconductor substrate 71 is interposed between the third element insulating layer 72 and the insulating layer 122 in the Z direction.

As shown in FIG. 8, the dielectric breakdown voltage of the semiconductor device 10 is determined by a distance DZ1 in the Z direction between the conductive bonding material SD between the first die pad 81 and the sub-mount chip 120 and the inner coil 110. The distance DZ1 may be defined by a distance in the Z direction between the chip back surface 120R of the sub-mount chip 120 and the inner coil 110.

Herein, the sub-mount chip 120 may be bonded to the first die pad 81 by an insulating bonding material instead of the conductive bonding material SD. In this case, the dielectric breakdown voltage of the semiconductor device 10 is determined by a distance DZ2 in the Z direction between the first die pad 81 and the inner coil 110.

### [Method of Manufacturing Semiconductor Device]

Next, an example of a method of manufacturing the semiconductor device 10 according to the first embodiment is described. In the following description, reference numerals related to the components of the semiconductor device 10 in FIGS. 1 to 8 are referenced.

The method of manufacturing the semiconductor device 10 includes a step of preparing the first chip 50, a step of preparing the second chip 60, a step of preparing the transformer chip 70, a step of preparing the sub-mount chip 120, and a step of preparing the first lead frame 80 and the second lead frame 90.

The step of preparing the first chip 50 includes a step of forming the first element insulating layer 52, the plurality of first pads 55, the plurality of first intermediate pads 56, the first connection wiring 53, and the second connection wiring 54 over the first semiconductor substrate 51 in which the first circuit 20 is formed. The plurality of first pads 55, the plurality of first intermediate pads 56, the first connection wiring 53, and the second connection wiring 54 are formed by etching and sputtering, using a metal mask, in a process of stacking the insulating films of the first element insulating layer 52.

The step of preparing the second chip 60 includes a step of forming the second element insulating layer 62, the plurality of second pads 65, the plurality of second intermediate pads 66, the third connection wiring 63, and the fourth connection wiring 64 over the second semiconductor substrate 61 in which the second circuit 30 is formed. The plurality of second pads 65, the plurality of second intermediate pads 66, the third connection wiring 63, and the fourth connection wiring 64 are formed by etching and sputtering, using a metal mask, in a process of stacking the insulating film of the second element insulating layer 62.

The step of preparing the transformer chip 70 includes a step of forming the third element insulating layer 72, the outer coil 100, the inner coil 110, the first transformer pads 75A and 75B, the second transformer pads 76A and 76B, and the wiring portion 77 over the third semiconductor substrate 71. The third element insulating layer 72 is formed by first forming the second insulating film 72Q over the third semiconductor substrate 71. Then, the first insulating film 72P and the second insulating film 72Q are alternately stacked in this order over the second insulating film 72Q. The outer coil 100, the inner coil 110, the first transformer pads 75A and 75B, the second transformer pads 76A and 76B, and the wiring portion 77 are formed by etching and sputtering, using a metal mask, in a process of stacking the first insulating film 72P and the second insulating film 72Q of the third element insulating layer 72.

The step of preparing the sub-mount chip 120 includes a step of forming the insulating layer 122 over the fourth semiconductor substrate 121. In this step, the insulating layer 122 is formed by alternately stacking the plurality of first insulating films 122P and the plurality of second insulating films 122Q one by one in the Z direction. The step of forming the insulating layer 122 is similar to, for example, the step of forming the third element insulating layer 72 of the transformer chip 70.

The method of manufacturing the semiconductor device 10 includes a step of mounting the first chip 50 and the sub-mount chip 120 on the first die pad 81 of the first lead frame 80, and a step of mounting the second chip 60 on the second die pad 91 of the second lead frame 90.

In the step of mounting the first chip 50 and the sub-mount chip 120 on the first die pad 81, first, conductive bonding materials SD are applied to two locations on the first die pad 81 that are spaced apart from each other in the X direction. Then, the first chip 50 is disposed over one conductive bonding material SD. The sub-mount chip 120 is disposed over the other conductive bonding material SD. Then, the first chip 50 and the sub-mount chip 120 are bonded to the first die pad 81 by melting and solidifying the respective conductive bonding materials SD.

Further, in the step of mounting the sub-mount chip 120, instead of the conductive bonding material SD, an insulating bonding material may be applied to the first die pad 81. Then, the sub-mount chip 120 is arranged on the insulating bonding material. Then, the sub-mount chip 120 is bonded to the first die pad 81 by melting and solidifying the insulating bonding material.

In the step of mounting the second chip 60 on the second die pad 91, first, a conductive bonding material SD is applied to the second die pad 91. Then, the second chip 60 is disposed over the conductive bonding material SD. Then, the second chip 60 is bonded to the second die pad 91 by melting and solidifying the conductive bonding material SD. Herein, the conductive bonding material SD applied to the first die pad 81 and the conductive bonding material SD applied to the second die pad 91 may be melted and solidified at the same time.

The method of manufacturing the semiconductor device 10 includes a step of forming the plurality of wires W1 and the plurality of wires W2. The plurality of wires W1 are formed using a wire bonding device to individually connect the plurality of first pads 55 of the first chip 50 to the plurality of first leads 82 of the first lead frame 80. The plurality of wires W2 are formed using a wire bonding device to individually connect the plurality of second pads 65 of the second chip 60 to the plurality of second leads 92 of the second lead frame 90.

The method of manufacturing the semiconductor device 10 includes a step of disposing the transformer chip 70 over the sub-mount chip 120. By disposing the transformer chip 70 over the sub-mount chip 120, the third semiconductor substrate 71 of the transformer chip 70 contacts the insulating layer 122 of the sub-mount chip 120.

The method of manufacturing the semiconductor device 10 includes a step of forming the plurality of first intermediate wires WA and the plurality of second intermediate wires WB. The plurality of first intermediate wires WA are formed using a wire bonding device to individually connect the first transformer pads 75A and 75B to the two first intermediate pads 56 of the first chip 50. The plurality of second intermediate wires WB are formed using a wire bonding device to individually connect the second transformer pads 76A and 76B to the two second intermediate pads 66 of the second chip 60.

The method of manufacturing the semiconductor device 10 includes a step of forming the sealing resin 200. In this step, the sealing resin 200 is formed by, for example, transfer molding. As a result, the sealing resin 200 seals the first chip 50, the second chip 60, the sub-mount chip 120, the transformer chip 70, the first die pad 81, the second die pad 91, the plurality of first wires W1, the plurality of second wires W2, the plurality of first intermediate wires WA, and the plurality of second intermediate wires WB. Through the above steps, the semiconductor device 10 is manufactured.

Additionally, in the method of manufacturing the semiconductor device 10, the order of the step of forming the plurality of first wires W1 and the plurality of second wires W2 may be changed arbitrarily. In one example, the step of forming the plurality of first wires W1 and the plurality of second wires W2 may be performed simultaneously with the step of forming the plurality of first intermediate wires WA and the plurality of second intermediate wires WB. In other words, in the chip disposition state, the plurality of first wires W1, the plurality of second wires W2, the plurality of first intermediate wires WA, and the plurality of second intermediate wires WB may be continuously formed by a wire bonding device.

### [Operation of First Embodiment]

The operation of the first embodiment is described. In the following description, a transformer chip bonded to the first die pad 81 by a conductive bonding material SD is referred to as a “transformer chip of a comparative example.” The transformer chip of the comparative example includes the outer coil 100 and the inner coil 110 provided on the third element insulating layer 72, similar to the transformer chip 70 of the first embodiment. A semiconductor device including the transformer chip of the comparative example is referred to as a “semiconductor device of a comparative example.”

A dielectric breakdown voltage of the semiconductor device of the comparative example is mainly determined by a distance between the inner coil 110 of the transformer chip of the comparative example and the conductive bonding material SD in the Z direction. In order to improve the dielectric breakdown voltage of the semiconductor device of the comparative example, it is necessary to increase the distance between the inner coil 110 and the conductive bonding material SD in the Z direction. Therefore, it would be possible to increase a thickness of the third element insulating layer 72 of the transformer chip of the comparative example, but if the thickness of the third element insulating layer 72 is increased, the third semiconductor substrate 71 becomes more likely to warp during the manufacture of the transformer chip of the comparative example. The thicker the third element insulating layer 72, the greater the warping that occurs in the third semiconductor substrate 71.

In the first embodiment, the sub-mount chip 120 is interposed between the transformer chip 70 and the first die pad 81. The sub-mount chip 120 is bonded to the first die pad 81 by, for example, a conductive bonding material SD. While the transformer chip 70 is disposed over the sub-mount chip 120, it is not bonded to the sub-mount chip 120 by the conductive bonding material SD. For this reason, the distance DZ1 in the Z direction between the inner coil 110 of the transformer chip 70 and the conductive bonding material SD in the first embodiment becomes larger by the thickness of the sub-mount chip 120, as compared to the distance in the Z direction between the inner coil 110 of the transformer chip 70 of the comparative example and the conductive bonding material SD. Further, when the sub-mount chip 120 is bonded to the first die pad 81 by, for example, an insulating bonding material, the distance DZ2 between the inner coil 110 and the first die pad 81 in the Z direction, which determines the dielectric breakdown voltage of the semiconductor device 10, becomes larger by the sum of the thickness of the sub-mount chip 120 and the thickness of the insulating bonding material, than that in the semiconductor device of the comparative example. As a result, in the first embodiment, it is possible to improve the dielectric breakdown voltage of the semiconductor device 10 without excessively increasing the thickness of the third element insulating layer 72 of the transformer chip 70.

In addition, the inner coil 110 and the outer coil 100 are disposed to face each other in the direction orthogonal to the Z direction. Therefore, by increasing the size of the transformer chip 70 in the X direction and the Y direction, a distance between the inner coil 110 and the outer coil 100 in the direction orthogonal to the Z direction may be made equal to or larger than the distance DZ1 (DZ2). In other words, the distance between the inner coil 110 and the outer coil 100 in the direction orthogonal to the Z direction may be made equal to or larger than the distance DZ1 (DZ2) without increasing the thickness of the third element insulating layer 72. Therefore, it is possible to improve the dielectric breakdown voltage of the semiconductor device 10.

Further, wiring resistance values of the outer coil 100 and the inner coil 110 affect an amount of a current flowing through the outer coil 100 and the inner coil 110, respectively, and a degree of magnetic coupling. The wiring resistance value of the outer coil 100 may be reduced by widening a wiring width of the outer coil 100 and reducing an aspect ratio of a wiring thickness to the wiring width. Similarly, the wiring resistance value of the inner coil 110 may be reduced by widening a wiring width of the inner coil 110 and reducing an aspect ratio of a wiring thickness to the wiring width.

Herein, for example, in a configuration in which two coils are disposed to face each other in the Z direction, if wiring widths of these coils are increased, a facing area between the two coils increases, which increases a capacitance value of a parasitic capacitor.

In the first embodiment, the outer coil 100 and the inner coil 110 face each other in the direction orthogonal to the Z direction. Therefore, even if the wiring width of each of the outer coil 100 and the inner coil 110 is increased, a facing area between the outer coil 100 and the inner coil 110 does not change. In other words, a capacitance value of a parasitic capacitor between the outer coil 100 and the inner coil 110 does not change. Therefore, the wiring resistance value of each coil is possible to be reduced without increasing the capacitance value of the parasitic capacitor between the coils. As a result, a current flows more easily in the outer coil 100 and the inner coil 110, such that an amount of magnetic flux generated in the transformer 40 may be increased. This is possible to improve efficiency of the magnetic coupling between the outer coil 100 and the inner coil 110, and further improve transmission characteristics.

### [Effects of First Embodiment]

The semiconductor device 10 according to the first embodiment provides the following effects.
(1-1) The semiconductor device 10 includes the first chip 50 including the first semiconductor substrate 51, the first circuit 20 formed at the first semiconductor substrate 51, and the first element insulating layer 52 formed over the first semiconductor substrate 51; the second chip 60 disposed to be spaced apart from the first chip 50 in the X direction and including the second semiconductor substrate 61, the second circuit 30 formed at the second semiconductor substrate 61, and the second element insulating layer 62 formed over the second semiconductor substrate 61; the sub-mount chip 120 provided separately from the first chip 50 and the second chip 60; and the transformer chip 70 disposed over the sub-mount chip 120 and including the transformer 40. The first circuit 20 and the second circuit 30 are configured to transmit signals or power via the transformer 40. The transformer chip 70 includes the third semiconductor substrate 71 and the third element insulating layer 72 formed over the third semiconductor substrate 71. The transformer 40 is embedded in the third element insulating layer 72. The sub-mount chip 120 includes the fourth semiconductor substrate 121 and the insulating layer 122 formed over the fourth semiconductor substrate 121.

With this configuration, as the transformer chip 70 is disposed over the sub-mount chip 120, a distance between the transformer 40 in the transformer chip 70 and a conductive member outside the transformer chip 70 may be increased in a stacking direction (Z direction) of the transformer chip 70 and the sub-mount chip 120. Therefore, it is possible to improve the dielectric breakdown voltage of the semiconductor device 10.

In addition, since the sub-mount chip 120 is composed of the fourth semiconductor substrate 121 and the insulating layer 122 formed over the fourth semiconductor substrate 121, the sub-mount chip 120 may be manufactured with the same step as the transformer chip 70. Further, since the dielectric breakdown voltage of the semiconductor device 10 is possible to be adjusted by adjusting the thickness of the insulating layer 122 of the sub-mount chip 120, semiconductor devices 10 with a plurality of types of dielectric breakdown voltages may be manufactured without changing the configuration of the transformer chip 70.
(1-2) The third element insulating layer 72 of the transformer chip 70 includes the insulating layer stack structure 72T in which the first insulating film 72P containing silicon nitride and the second insulating film 72Q containing silicon oxide are alternately stacked in plural.

With this configuration, it is possible to increase a thickness of the insulating layer stack structure 72T while suppressing the warping of the transformer chip 70. This allows the distance between the transformer 40 in the transformer chip 70 and the conductive member outside the transformer chip 70 to be further increased. Therefore, it is possible to further improve the dielectric breakdown voltage of the semiconductor device 10.
(1-3) The insulating layer 122 of the sub-mount chip 120 includes the structure in which the first insulating film 122P containing silicon nitride and the second insulating film 122Q containing silicon oxide are alternately stacked in plural.

With this configuration, it is possible to increase the thickness of the insulating layer 122 while suppressing the warping of the sub-mount chip 120. This allows the distance between the transformer 40 in the transformer chip 70 and the conductive member outside the transformer chip 70 to be further increased, thereby improving the dielectric breakdown voltage of the semiconductor device 10.
(1-4) The thickness of the sub-mount chip 120 is equal to or greater than the thickness of the transformer chip 70. With this configuration, it is possible to increase the distance between the transformer 40 in the transformer chip 70 and the conductive member outside the transformer chip 70 while suppressing the warping of the transformer chip 70. Therefore, the dielectric breakdown voltage of the semiconductor device 10 may be improved.
(1-5) The dimension of the sub-mount chip 120 in the X direction is equal to the dimension of the transformer chip 70 in the X direction. With this configuration, the transformer chip 70 may be more stably disposed over the sub-mount chip 120 than a configuration in which the dimension of the sub-mount chip 120 in the X direction is smaller than the dimension of the transformer chip 70 in the X direction. In addition, by making a position of the transformer chip 70 in the X direction the same as a position of the sub-mount chip 120 in the X direction, the position of the transformer chip 70 in the X direction relative to the sub-mount chip 120 may be easily determined.
(1-6) The thickness of the sub-mount chip 120 is equal to or greater than the thickness of the first chip 50 or the second chip 60. With this configuration, the dielectric breakdown voltage of the semiconductor device 10 may be improved.
(1-7) In the chip disposition state in which the transformer chip 70 is disposed over the sub-mount chip 120, the third semiconductor substrate 71 is interposed between the insulating layer 122 of the sub-mount chip 120 and the third element insulating layer 72 of the transformer chip 70.

With this configuration, the distance between the transformer 40 in the transformer chip 70 and the conductive member outside the transformer chip 70 may be increased in the stacking direction (Z direction) of the transformer chip 70 and the sub-mount chip 120 as compared to a configuration in which the third element insulating layer 72 is interposed between the insulating layer 122 of the sub-mount chip 120 and the third semiconductor substrate 71 of the transformer chip 70. Therefore, the dielectric breakdown voltage of the semiconductor device 10 may be improved.
(1-8) The insulating layer 122 of the sub-mount chip 120 includes the protective film 123 and the passivation film 124 as protective layers formed over the side of the surface layer of the insulating layer 122. In the chip disposition state, the third semiconductor substrate 71 is in contact with the passivation film 124.

With this configuration, it is possible to increase the thickness of the insulating layer 122 as compared to a configuration in which the protective film 123 and the passivation film 124 are omitted from the insulating layer 122. This allows the distance between the transformer 40 in the transformer chip 70 and the conductive member outside the transformer chip 70 to be increased in the stacking direction (Z direction) of the transformer chip 70 and the sub-mount chip 120. Therefore, the dielectric breakdown voltage of the semiconductor device 10 may be improved.
(1-9) The transformer 40 includes the outer coil 100 and the inner coil 110 disposed in the third element insulating layer 72. In a plan view, the inner coil 110 is disposed inside the outer coil 100 so as not to overlap the outer coil 100.

With this configuration, since the inner coil 110 and the outer coil 100 do not overlap each other in a plan view, the facing area between the outer coil 100 and the inner coil 110 does not change even if the wiring width of each of the outer coil 100 and the inner coil 110 is increased. In other words, the capacitance value of the parasitic capacitor between the outer coil 100 and the inner coil 110 does not change. Therefore, it is possible to reduce the wiring resistance value of each coil without increasing the capacitance value of the parasitic capacitor between the coils.
(1-10) Both the outer coil 100 and the inner coil 110 are disposed at a side farther from the third semiconductor substrate 71 than the center of the third element insulating layer 72 in the thickness direction (Z direction). With this configuration, it is possible to increase the distance between the transformer 40 in the transformer chip 70 and the conductive member outside the transformer chip 70 in the stacking direction (Z direction) of the transformer chip 70 and the sub-mount chip 120 as compared to a configuration in which both the outer coil 100 and the inner coil 110 are disposed to be closer to the third semiconductor substrate 71 than the center of the third element insulating layer 72 in the thickness direction (Z direction). Therefore, the dielectric breakdown voltage of the semiconductor device 10 may be improved.

In addition, it is possible to increase a distance between the outer coil 100/the inner coil 110 and the third semiconductor substrate 71 in the Z direction as compared to a configuration in which both the outer coil 100 and the inner coil 110 are disposed to be closer to the third semiconductor substrate 71 than the center of the third element insulating layer 72 in the Z direction. Therefore, the magnetic flux generated in the outer coil 100 and the inner coil 110 is less likely to pass through the third semiconductor substrate 71. This makes it possible to suppress the generation of an eddy current caused by the magnetic flux penetrating the third semiconductor substrate 71. Therefore, it is possible to suppress a decrease in the efficiency of magnetic coupling caused by the eddy current.
(1-11) The inner coil 110 and the outer coil 100 are disposed at a same position in the Z direction. With this configuration, the inner coil 110 and the outer coil 100 may be formed by using a common mask when manufacturing the transformer chip 70. Therefore, since it is possible to simplify a process of manufacturing the transformer chip 70 as compared to a configuration in which the inner coil 110 and the outer coil 100 are disposed at different positions in the Z direction, a manufacturing cost of the transformer chip 70 may be reduced.

### Second Embodiment

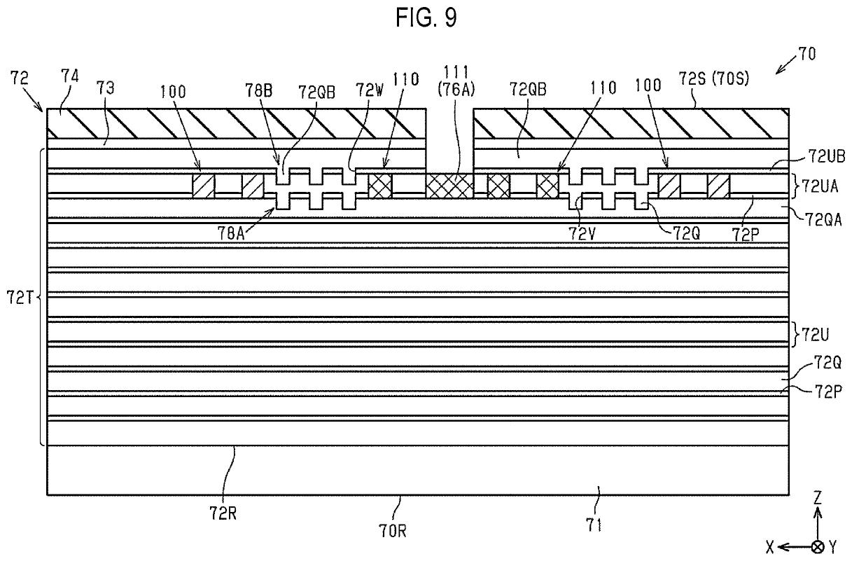

A semiconductor device 10 according to a second embodiment is described with reference to FIG. 9. The semiconductor device 10 according to the second embodiment is mainly different from the semiconductor device 10 according to the first embodiment in terms of the configuration of the third element insulating layer 72 of the transformer chip 70. In the following, differences from the first embodiment are described in detail, and the same constituent elements as those in the first embodiment are denoted by the same reference numerals and explanation thereof is omitted.

FIG. 9 shows a cross-sectional structure of a specific insulator 72UA and its periphery in the third element insulating layer 72 of the transformer chip 70. The cross-sectional position in FIG. 9 is the same as the cross-sectional position in FIG. 6 of the first embodiment.

As shown in FIG. 9, the third element insulating layer 72 of the transformer chip 70 includes a specific insulator 72UA at which the outer coil 100 and the inner coil 110 are provided, and a cover insulating film 72UB that covers the outer coil 100 and the inner coil 110 from the Z direction.

The cover insulating film 72UB includes a first insulating film 72P. The cover insulating film 72UB is in contact with a second insulating film 72Q of the specific insulator 72UA. In one example, the cover insulating film 72UB is in contact with the outer coil 100 and the inner coil 110.

The third element insulating layer 72 includes a plurality of isolation insulating films 78A and a plurality of cover side isolation insulating films 78B. Herein, the second insulating film 72Q immediately below the specific insulator 72UA is referred to as a “second insulating film 72QA,” and the second insulating film 72Q formed over the cover insulating film 72UB is referred to as a “second insulating film 72QB.”

In a plane direction orthogonal to the Z direction, a plurality of grooves 72V are formed at the first insulating film 72P of the specific insulator 72UA between the outer coil 100 and the inner coil 110. In the second embodiment, each groove 72V is a rectangular groove that penetrates the first insulating film 72P of the specific insulator 72UA in the Z direction and forms a concave shape in the second insulating film 72QA. Each groove 72V is formed in an annular shape in a plan view. In one example, the plurality of grooves 72V are formed in a concentric shape in a plan view. In one example, centers of the plurality of grooves 72V are concentric with centers of the outer coil 100 and the inner coil 110. In this way, the plurality of grooves 72V allow the first insulating films 72P of the specific insulator 72UA to be spaced apart from each other in the direction orthogonal to the Z direction between the outer coil 100 and the inner coil 110.

The second insulating film 72Q of the specific insulator 72UA is embedded in the plurality of grooves 72V. This forms the plurality of isolation insulating films 78A. That is, each isolation insulating film 78A is formed of the second insulating film 72Q containing SiO₂. In this way, between the outer coil 100 and the inner coil 110, the first insulating film 72P made of SiN is isolated by the isolation insulating film 78A made of SiO₂. That is, the first insulating film 72P between the outer coil 100 and the inner coil 110 is isolated by the second insulating film 72Q (the isolation insulating film 78A) having a smaller dielectric constant than the first insulating film 72P. The first insulating film 72P between the outer coil 100 and the inner coil 110 is provided in plural to be spaced apart from each other in a direction orthogonal to the Z direction. The isolation insulating films 78A (the second insulating film 72Q) are interposed among the plurality of first insulating films 72P. Since each groove 72V is formed in an annular shape, each isolation insulating film 78A provided in each groove 72V is formed in an annular shape in a plan view. When the plurality of grooves 72V are formed in a concentric shape in a plan view, the plurality of isolation insulating films 78A are formed in a concentric shape in a plan view. In this way, the first insulating films 72P and the second insulating films 72Q are alternately disposed between the outer coil 100 and the inner coil 110 in the direction orthogonal to the Z direction.

In the plane direction orthogonal to the Z direction, a plurality of grooves 72W are formed at the cover insulating film 72UB between the outer coil 100 and the inner coil 110. In the second embodiment, each groove 72W is a rectangular groove that penetrates the cover insulating film 72UB in the Z direction and forms a concave shape in the second insulating film 72Q of the specific insulator 72UA. Each groove 72W is formed in an annular shape in a plan view. In one example, the plurality of grooves 72W are formed in a concentric shape in a plan view. In one example, centers of the plurality of grooves 72W are concentric with the centers of the outer coil 100 and the inner coil 110. In this way, the plurality of grooves 72W allow the cover insulating films 72UB to be spaced apart from each other in the direction orthogonal to the Z direction between the outer coil 100 and the inner coil 110.

In one example, a width dimension of each groove 72W is equal to a width dimension of each groove 72V. Further, the width dimensions of the plurality of grooves 72W are equal to each other. Further, the width dimensions of the plurality of grooves 72V are equal to each other. Herein, the width dimension of each of the grooves 72V and 72W may be defined by a distance between side surfaces constituting each of the grooves 72V and 72W in the direction orthogonal to the Z direction.

The second insulating film 72QB is embedded in the plurality of grooves 72W. This forms the plurality of cover side isolation insulating films 78B. In other words, each cover side isolation insulating film 78B is formed by the second insulating film 72QB containing SiO₂. In this way, between the outer coil 100 and the inner coil 110, the cover insulating film 72UB made of SiN is isolated by the cover side isolation insulating film 78B made of SiO₂. That is, the cover insulating film 72UB between the outer coil 100 and the inner coil 110 is isolated by the second insulating film 72Q (the cover side isolation insulating film 78B) having a smaller dielectric constant than the cover insulating film 72UB. The cover insulating film 72UB between the outer coil 100 and the inner coil 110 is provided in plural to be spaced apart from each other in the direction orthogonal to the Z direction. The cover side isolation insulating films 78B (the second insulating film 72QB) are interposed among the plurality of cover insulating films 72UB. Since each groove 72W is formed in an annular shape, each cover side isolation insulating film 78B provided in each groove 72W is formed in an annular shape in a plan view. When the plurality of grooves 72W are formed in a concentric shape in a plan view, the plurality of cover side isolation insulating films 78B are formed in a concentric shape in a plan view. In this way, the cover insulating films 72UB (the first insulating films 72P) and the cover side isolation insulating films 78B (the second insulating films 72Q) are alternately disposed between the outer coil 100 and the inner coil 110 among the cover insulating film 72UB in the direction orthogonal to the Z direction.

When the width dimension of each groove 72W is equal to the width dimension of each groove 72V, a width dimension of each cover side isolation insulating film 78B is equal to a width dimension of each isolation insulating film 78A. Further, when the width dimensions of the plurality of grooves 72W are equal to each other, the width dimensions of the plurality of cover side isolation insulating films 78B are equal to each other. Further, when the width dimensions of the plurality of grooves 72V are equal to each other, the width dimensions of the plurality of isolation insulating films 78A are equal to each other. Herein, the width dimension of the isolation insulating film 78A may be defined by a distance between side surfaces of the isolation insulating film 78A that contact the side surfaces constituting the grooves 72V in the direction orthogonal to the Z direction. Also, the width dimension of the cover side isolation insulating film 78B may be defined by a distance between side surfaces of the cover side isolation insulating film 78B that contact the side surfaces constituting the groove 72W in the direction orthogonal to the Z direction.

In addition, the number of grooves 72V and 72W may be changed arbitrarily. In the second embodiment, the grooves 72V and 72W are disposed at positions overlapping each other in a plan view, but are not limited thereto. The grooves 72V and 72W may be disposed at positions different from each other in a plan view. In other words, the number of isolation insulating films 78A and the number of cover side isolation insulating films 78B may be changed arbitrarily. In the second embodiment, the isolation insulating film 78A and the cover side isolation insulating film 78B are disposed at positions overlapping each other in a plan view, but are not limited thereto. The isolation insulating film 78A and the cover side isolation insulating film 78B may be disposed at positions different from each other in a plan view.

Further, the width dimensions of the grooves 72V and 72W may be changed arbitrarily. In one example, the width dimension of the groove 72V and the width dimension of the groove 72W may be different from each other. That is, the width dimension of the isolation insulating film 78A and the width dimension of the cover side isolation insulating film 78B may be different from each other. In one example, the width dimension of at least one selected from the group of the plurality of grooves 72V may be different from the width dimensions of the remaining grooves 72V. That is, the width dimension of at least one selected from the group of the plurality of isolation insulating films 78A may be different from the width dimensions of the remaining isolation insulating films 78A. In one example, the width dimension of at least one selected from the group of the plurality of grooves 72W may be different from the width dimensions of the remaining grooves 72W. That is, the width dimension of at least one selected from the group of the plurality of cover side isolation insulating films 78B may be different from the width dimensions of the remaining cover side isolation insulating films 78B. Additionally, shapes of the grooves 72V and 72W are not limited to a rectangular concave shape and may be changed arbitrarily. In one example, the grooves 72V and 72W may be V-shaped.

### [Effects of Second Embodiment]

The semiconductor device 10 according to the second embodiment provides the following effects.
(2-1) The third element insulating layer 72 includes the insulating layer stack structure 72T in which the plurality of insulators 72U are stacked, each of which includes the first insulating film 72P containing silicon nitride and the second insulating film 72Q containing silicon oxide stacked over the first insulating film 72P. The inner coil 110 and the outer coil 100 are provided so as to penetrate the specific insulator 72UA which is one specific insulator 72U. The third element insulating layer 72 includes the cover insulating film 72UB which is constituted by the first insulating film 72P and contacts the second insulating film 72Q of the specific insulator 72UA so as to cover the inner coil 110 and the outer coil 100. A portion of the first insulating film 72P of the specific insulator 72UA between the inner coil 110 and the outer coil 100 includes the plurality of isolation insulating films 78A which are provided to be spaced apart from each other in the direction orthogonal to the Z direction. A portion of the cover insulating film 72UB between the inner coil 110 and the outer coil 100 includes the plurality of cover side isolation insulating films 78B which are provided to be spaced apart from each other in the direction orthogonal to the Z direction. Each of the plurality of isolation insulating films 78A and cover side isolation insulating films 78B is constituted by the second insulating film 72Q.

With this configuration, the plurality of isolation insulating films 78A and second insulating films 72Q are alternately disposed in the portion of the first insulating film 72P of the specific insulator 72UA between the inner coil 110 and the outer coil 100. Therefore, a distance of the interface (interface distance) between the inner coil 110 and the outer coil 100 may be increased. In other words, an insulation distance between the inner coil 110 and the outer coil 100 may be increased. Further, the plurality of cover side isolation insulating films 78B and second insulating films 72Q are alternately disposed in the portion of the cover insulating film 72UB between the inner coil 110 and the outer coil 100. Therefore, the interface distance between the inner coil 110 and the outer coil 100 may be increased. In other words, the insulation distance between the inner coil 110 and the outer coil 100 may be increased. Therefore, it is possible to improve the dielectric breakdown voltage of the semiconductor device 10 while suppressing the increase in size of the transformer chip 70.
(2-2) Each of the plurality of isolation insulating films 78A and cover side isolation insulating films 78B is formed in an annular shape. With this configuration, the second insulating films 72Q interposed among the plurality of isolation insulating films 78A are formed in an annular shape, and the second insulating films 72Q interposed among the plurality of cover side isolation insulating films 78B are formed in an annular shape. Therefore, in the portion between the inner coil 110 and the outer coil 100, the interface distance between the inner coil 110 and the outer coil 100 may be increased over an entire circumference of the inner coil 110.

### Third Embodiment

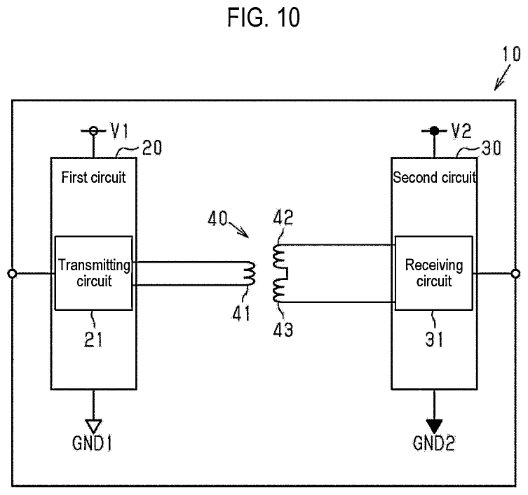

A semiconductor device 10 according to a third embodiment is described with reference to FIGS. 10 to 14. The semiconductor device 10 according to the third embodiment is mainly different from the semiconductor device 10 according to the first embodiment in terms of the configuration of the transformer chip 70. In the following, differences from the first embodiment are described in detail, and the same constituent elements as those in the first embodiment are denoted by the same reference numerals and explanation thereof is omitted.

### (Circuit Configuration of Semiconductor Device)

FIG. 10 shows a schematic circuit configuration of the semiconductor device 10 according to the third embodiment. As shown in FIG. 10, in the semiconductor device 10, the transformer 40 provided between the transmitting circuit 21 of the first circuit 20 and the receiving circuit 31 of the second circuit 30 includes first to third coils 41 to 43. The first coil 41 is electrically connected to the transmitting circuit 21, as in the first embodiment. The second coil 42 and the third coil 43 are electrically connected to each other. The second coil 42 and the third coil 43 are electrically connected to the receiving circuit 31. The first coil 41, the second coil 42, and the third coil 43 are electrically insulated from each other and are configured to be magnetically coupled.

### (Configuration of Semiconductor Device)

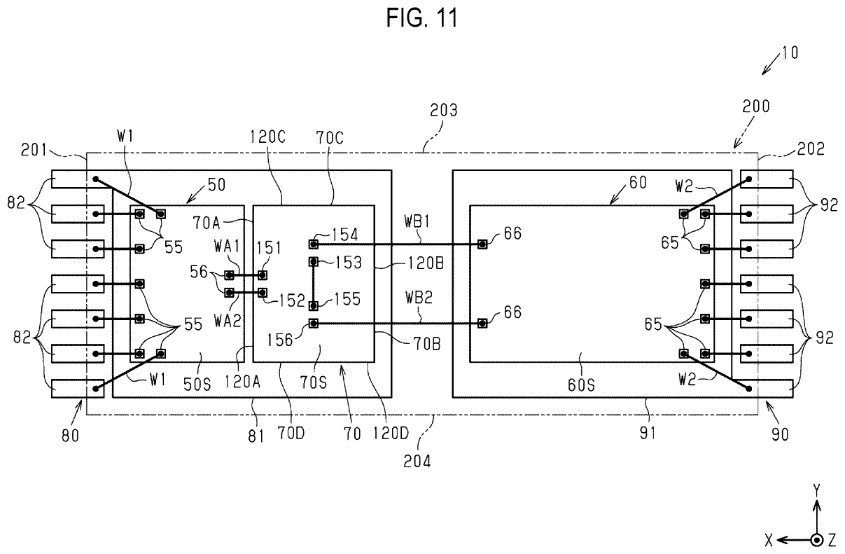

FIG. 11 shows a schematic example of a planar structure of the semiconductor device 10 according to FIG. 10. As shown in FIG. 11, the semiconductor device 10 includes a first chip 50 including the first circuit 20 shown in FIG. 10, a second chip 60 including the second circuit 30 shown in FIG. 10, and a transformer chip 70 including the first to third coils 41 to 43 shown in FIG. 10. The transformer chip 70 is disposed over the sub-mount chip 120, as in the first embodiment. Further, the semiconductor device 10 includes a first lead frame 80, a second lead frame 90, and a sealing resin 200, as in the first embodiment.

Two first intermediate pads 56 of the first chip 50 are disposed at a center of the chip front surface 50S of the first chip 50 in the Y direction, unlike the first embodiment. The first two intermediate pads 56 are disposed at a same position in the X direction and spaced apart from each other in the Y direction.

Two second intermediate pads 66 of the second chip 60 are disposed toward the chip side surfaces 60C and 60D, respectively, from a center of the chip front surface 60S of the second chip 60 in the Y direction, unlike the first embodiment. The two second intermediate pads 66 are disposed at an end portion, which is closer to the chip side surface 60A, of both end portions of the chip front surface 60S in the X direction. The two second intermediate pads 66 are disposed at a same position in the X direction and spaced apart from each other in the Y direction.

The transformer chip 70 includes first to sixth transformer pads 151 to 156. Both the first transformer pad 151 and the second transformer pad 152 are disposed to be closer to the chip side surface 70A than the third to sixth transformer pads 153 to 156 in a plan view. In one example, both the first transformer pad 151 and the second transformer pad 152 are disposed at an end portion, which is closer to the chip side surface 70A, of both end portions of the chip front surface 70S in the X direction. Both the first transformer pad 151 and the second transformer pad 152 are disposed at a center of the chip front surface 70S in the Y direction. In one example, the first transformer pad 151 and the second transformer pad 152 are disposed at a same position in the Y direction as the two first intermediate pads 56 of the first chip 50 in a plan view.

The third to sixth transformer pads 153 to 156 are disposed at a center of the chip front surface 70S in the X direction. The third to sixth transformer pads 153 to 156 are disposed at a same position in the X direction and spaced apart from each other in the Y direction. Both the third transformer pad 153 and the fourth transformer pad 154 are disposed over the chip front surface 70S so as to be closer to the chip side surface 70C in the Y direction. Both the fifth transformer pad 155 and the sixth transformer pad 156 are disposed over the chip front surface 70S so as to be closer to the chip side surface 70D in the Y direction. Electrical connection structures of the first to sixth transformer pads 151 to 156, the first chip 50, and the second chip 60 are described in detail later.

### (Internal Configuration of Transformer Chip)

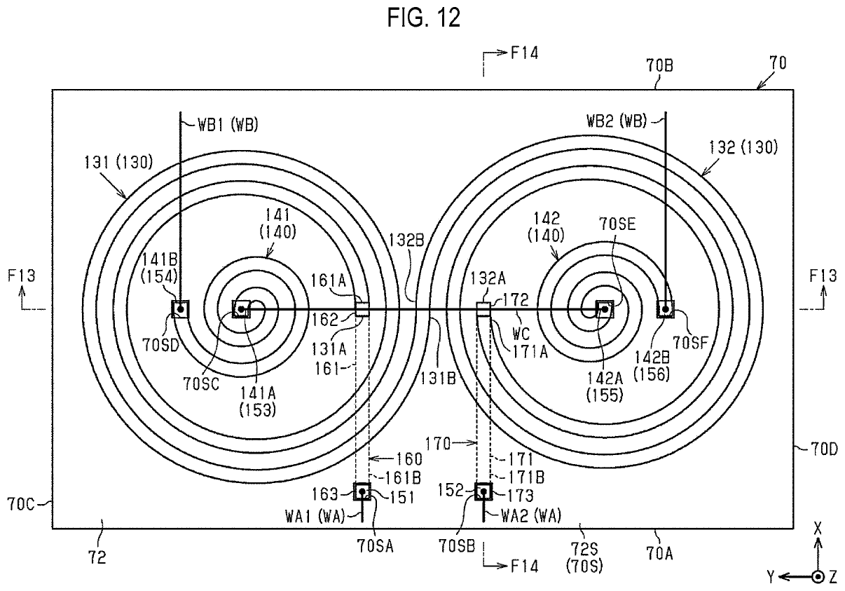

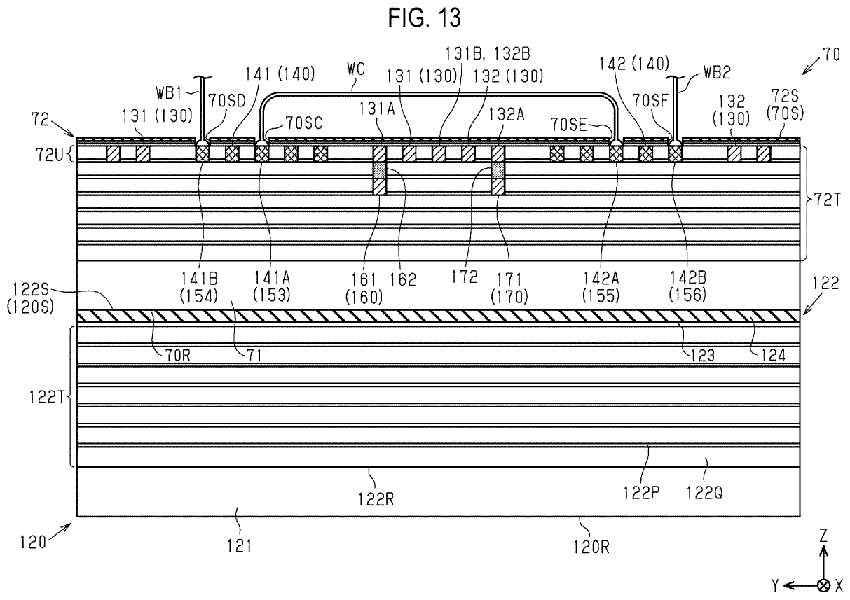

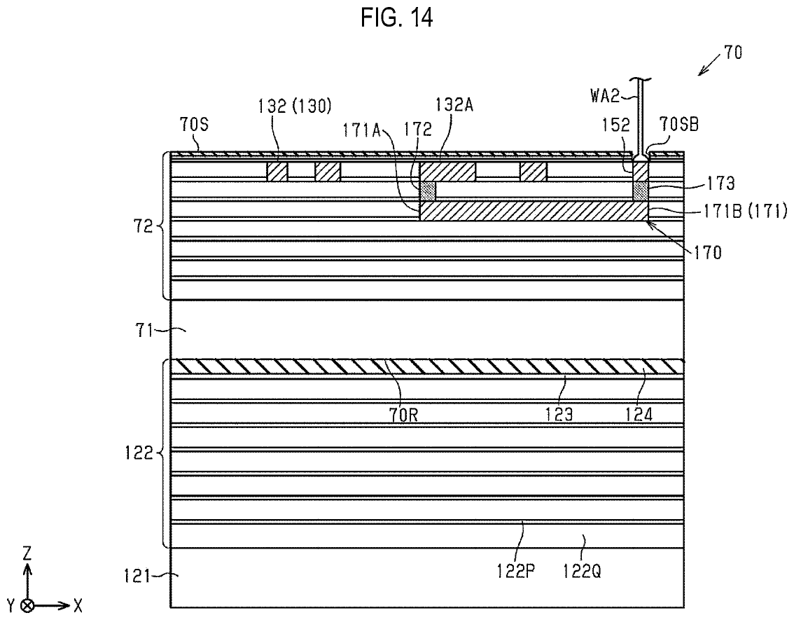

An example of an internal configuration of the transformer chip 70 is described with reference to FIGS. 12 to 14. FIG. 12 shows a schematic planar structure of the inside of the transformer chip 70. FIG. 13 shows a schematic cross-sectional structure taken along line F13-F13 in FIG. 12. FIG. 14 shows a schematic cross-sectional structure taken along line F14-F14 in FIG. 12. For the sake of convenience, an outer coil 130 and an inner coil 140, which are described below, are shown by solid lines in FIG. 12.

As shown in FIG. 12, the transformer chip 70 includes the outer coil 130 and the inner coil 140. The outer coil 130 corresponds to the first coil 41 shown in FIG. 10. The inner coil 140 includes a first inner coil 141 corresponding to the second coil 42 shown in FIG. 10 and a second inner coil 142 corresponding to the third coil 43 shown in FIG. 10. As shown in FIG. 13, each of the outer coil 130, the first inner coil 141, and the second inner coil 142 is embedded in the third element insulating layer 72. Herein, both the outer coil 130 and the inner coil 140 are examples of an “insulating element.”

As shown in FIG. 12, the outer coil 130 includes a first outer coil 131 and a second outer coil 132. The first outer coil 131 includes a first end 131A and a second end 131B opposite to the first end 131A. The second outer coil 132 includes a first end 132A and a second end 132B opposite to the first end 132A. The second end 131B of the first outer coil 131 and the second end 132B of the second outer coil 132 are electrically connected to each other.

Each of the first outer coil 131 and the second outer coil 132 is formed in a circular spiral shape in a plan view. The first outer coil 131 and the second outer coil 132 are wound so that when a current flows from a first end of one of the first outer coil 131 and the second outer coil 132 to a first end of the other outer coil, magnetic fluxes in opposite directions are generated. In one example, the first outer coil 131 and the second outer coil 132 are symmetrical in a plan view. In the third embodiment, the first outer coil 131 and the second outer coil 132 are point-symmetrical in a plan view.

In the first outer coil 131 of a spiral shape, the first end 131A is disposed inside the spiral, and the second end 131B is disposed outside the spiral. In other words, the first outer coil 131 is wound in the spiral shape with the first end 131A as an inner peripheral end and the second end 131B as an outer peripheral end. Similarly, in the second outer coil 132 of a spiral shape, the first end 132A is disposed inside the spiral, and the second end 132B is disposed outside the spiral. In other words, the second outer coil 132 is wound in the spiral shape with the first end 132A as an inner peripheral end and the second end 132B as an outer peripheral end. The first outer coil 131 and the second outer coil 132 have their respective second ends 131B and 132B, which are the outer peripheral ends, electrically connected to each other. In one example, the first outer coil 131 and the second outer coil 132 are integrated.

As shown in FIGS. 13 and 14, the first outer coil 131 and the second outer coil 132 of the outer coil 130 are disposed at a same position in the Z direction. Both the first outer coil 131 and the second outer coil 132 are disposed to be closer to the third element front surface 72S than the center of the third element insulating layer 72 in the Z direction. In the third embodiment, both the first outer coil 131 and the second outer coil 132 are provided at the uppermost insulator 72U of the insulating layer stack structure 72T of the third element insulating layer 72. The outer coil 130 is made of a material containing one or more appropriately selected from the group of Ti, TiN, Au, Ag, Cu, Al, and W. The outer coil 130 of the third embodiment is made of a material containing Cu. Also, the first outer coil 131 and the second outer coil 132 may be provided at, rather than the uppermost insulator 72U of the insulating layer stack structure 72T of the third element insulating layer 72, for example, the insulator 72U immediately below the uppermost insulator 72U.

As shown in FIG. 12, the first inner coil 141 is disposed inside the first outer coil 131. The first inner coil 141 is disposed so as not to overlap the first outer coil 131 in a plan view. The first inner coil 141 is disposed to be spaced apart from the first outer coil 131 in a plane direction orthogonal to the Z direction. In one example, a winding center of the first inner coil 141 and a winding center of the first outer coil 131 are concentric.

The second inner coil 142 is disposed inside the second outer coil 132. The second inner coil 142 is disposed so as not to overlap the second outer coil 132 in a plan view. The second inner coil 142 is disposed to be spaced apart from the second outer coil 132 in the plane direction orthogonal to the Z direction. In one example, a winding center of the second inner coil 142 and a winding center of the second outer coil 132 are concentric. The first inner coil 141 and the second inner coil 142 are disposed at a same position in the X direction and spaced apart from each other in the Y direction.

Each of the first inner coil 141 and the second inner coil 142 is formed in a circular spiral shape in a plan view. In one example, the first inner coil 141 and the second inner coil 142 are symmetrical in a plan view. In the third embodiment, the first inner coil 141 and the second inner coil 142 are point-symmetrical in a plan view.

A current flows in the first inner coil 141 in a direction corresponding to a direction of a magnetic flux generated by a current flowing in the first outer coil 131. Similarly, a current flows in the second inner coil 142 in a direction corresponding to a direction of a magnetic flux generated by a current flowing in the second outer coil 132.

The first inner coil 141 includes a first end 141A and a second end 141B opposite to the first end 141A. In the spiral first inner coil 141 of a spiral shape, the first end 141A is disposed inside the spiral, and the second end 141B is disposed outside the spiral. In other words, the first inner coil 141 is wound in the spiral shape with the first end 141A as an inner peripheral end and the second end 141B as an outer peripheral end.

The second inner coil 142 includes a first end 142A and a second end 142B opposite to the first end 142A. In the second inner coil 142 of a spiral shape, the first end 142A is disposed inside the spiral, and the second end 142B is disposed outside the spiral. In other words, the second inner coil 142 is wound in the spiral shape with the first end 142A as an inner peripheral end and the second end 142B as an outer peripheral end.

As shown in FIGS. 13 and 14, the first inner coil 141 and the second inner coil 142 are disposed at a same position in the Z direction. Both the first inner coil 141 and the second inner coil 142 are disposed to be closer to the third element front surface 72S than the center of the third element insulating layer 72 in the Z direction. In the third embodiment, both the first inner coil 141 and the second inner coil 142 are provided at the uppermost insulator 72U of the insulating layer stack structure 72T of the third element insulating layer 72. In this way, both the first inner coil 141 and the second inner coil 142 are disposed at the same position in the Z direction as both the first outer coil 131 and the second outer coil 132. The inner coil 140 is made of a material containing one or more appropriately selected from the group of Ti, TiN, Au, Ag, Cu, Al, and W. In one example, the inner coil 140 is made of a same material as the outer coil 130. The inner coil 140 of the third embodiment is made of a material containing Cu. Also, the first inner coil 141 and the second inner coil 142 may be provided at, rather than the uppermost insulator 72U of the insulating layer stack structure 72T of the third element insulating layer 72, for example, the insulator 72U immediately below the uppermost insulator 72U.

As shown in FIG. 12, the transformer chip 70 includes first to sixth openings 70SA to 70SF. The first to sixth openings 70SA to 70SF are provided at the third element insulating layer 72. The first opening 70SA is an opening that exposes the first transformer pad 151. The second opening 70SB is an opening that exposes the second transformer pad 152. The third opening 70SC is an opening that exposes the first end 141A of the first inner coil 141. The fourth opening 70SD is an opening that exposes the second end 141B of the first inner coil 141. The fifth opening 70SE is an opening that exposes the first end 142A of the second inner coil 142. The sixth opening 70SF is an opening that exposes the second end 142B of the second inner coil 142.

The first transformer pad 151 and the second transformer pad 152 are pads that are electrically connected to the outer coil 130. The first transformer pad 151 is electrically connected to the first end 131A of the first outer coil 131 of the outer coil 130. The second transformer pad 152 is electrically connected to the first end 132A of the second outer coil 132 of the outer coil 130. In one example, the first transformer pad 151 and the second transformer pad 152 are disposed at a same position as the outer coil 130 in the Z direction.

The third to sixth transformer pads 153 to 156 may be pads that are electrically connected to the inner coil 140. In the third embodiment, the third to sixth transformer pads 153 to 156 are constituted by a portion of the inner coil 140. More specifically, the third transformer pad 153 is constituted by exposing the first end 141A of the first inner coil 141 of the inner coil 140 in the Z direction from the third opening 70SC of the third element insulating layer 72. The fourth transformer pad 154 is constituted by exposing the second end 141B of the first inner coil 141 in the Z direction from the fourth opening 70SD of the third element insulating layer 72. The fifth transformer pad 155 is constituted by exposing the first end 142A of the second inner coil 142 of the inner coil 140 in the Z direction from the fifth opening 70SE of the third element insulating layer 72. The sixth transformer pad 156 is constituted by exposing the second end 142B of the second inner coil 142 in the Z direction from the sixth opening 70SF of the third element insulating layer 72.

As shown in FIGS. 12 and 14, the transformer chip 70 includes a first wiring portion 160 and a second wiring portion 170. The first wiring portion 160 is a wiring that electrically connects the first end 131A of the first outer coil 131 and the first transformer pad 151. The second wiring portion 170 is a wiring that electrically connects the first end 132A of the second outer coil 132 and the second transformer pad 152. The first wiring portion 160 and the second wiring portion 170 are made of a material containing one or more appropriately selected from the group of Ti, TiN, Au, Ag, Cu, Al, and W.

As shown in FIGS. 12 and 13, the first wiring portion 160 includes a connection wiring 161 and vias 162 and 163. The connection wiring 161 extends in the X direction. The connection wiring 161 includes a first end 161A and a second end 161B as both ends in the X direction. The connection wiring 161 extends from the first end 131A of the first outer coil 131 to the first transformer pad 151 in a plan view. The connection wiring 161 is disposed to be closer to the third semiconductor substrate 71 than the first outer coil 131 is disposed in the Z direction. The first end 161A of the connection wiring 161 is disposed at a position overlapping with the first end 131A of the first outer coil 131 in a plan view. The first end 161A is electrically connected to the first end 131A of the first outer coil 131 by the via 162. The second end 161B of the connection wiring 161 is disposed at a position overlapping with the first transformer pad 151 in a plan view. The second end 161B is electrically connected to the first transformer pad 151 by the via 163.

As shown in FIGS. 12 and 14, the second wiring portion 170 includes a connection wiring 171 and vias 172 and 173. The connection wiring 171 and the vias 172 and 173 are disposed in the same manner as the connection wiring 161 and the vias 162 and 163 of the first wiring portion 160. The connection wiring 171 includes a first end 171A and a second end 171B in the same manner as the connection wiring 161. The first end 171A of the connection wiring 171 is electrically connected to the first end 132A of the second outer coil 132 by the via 172, and the second end 171B of the connection wiring 171 is electrically connected to the second transformer pad 152 by the via 173.

As shown in FIGS. 11 and 12, the first transformer pad 151 and the second transformer pad 152 are individually connected to the two first intermediate pads 56 of the first chip 50 by two first intermediate wires WA. The two first intermediate wires WA are provided outside the transformer chip 70. In the following description, for the sake of convenience, the two first intermediate wires WA are referred to as a “first intermediate wire WA1” and a “first intermediate wire WA2,” respectively.

Since one of the two first intermediate pads 56 is electrically connected to the transmitting circuit 21, the first transformer pad 151, for example, constituted by the first end 131A of the first outer coil 131 of the outer coil 130, is electrically connected to the transmitting circuit 21 (see FIG. 10) by the first intermediate wire WA1. Therefore, it may be said that the first outer coil 131 is electrically connected to the first chip 50 by the first intermediate wire WA1. The other of the two first intermediate pads 56 is connected to the ground GND1 (see FIG. 10). Therefore, the second transformer pad 152, for example, constituted by the first end 132A of the second outer coil 132 of the outer coil 130, is electrically connected to the ground GND1 by the first intermediate wire WA2. Therefore, it may be said that the second outer coil 132 is electrically connected to the first chip 50 by the first intermediate wire WA2. Herein, the first intermediate wire WA1 is an example of a “first chip connecting wire,” and the first intermediate wire WA2 is an example of a “second chip connecting wire.”

The first end 141A of the first inner coil 141 and the first end 142A of the second inner coil 142 of the inner coil 140 are electrically connected by a wire WC. As a result, when a current generated in the first inner coil 141 flows through the wire WC to the second inner coil 142, a direction of the current and a direction of a current generated in the second inner coil 142 become the same. Herein, the wire WC is an example of a “coil connecting wire.”

The fourth transformer pad 154 and the sixth transformer pad 156 are individually connected to the two second intermediate pads 66 of the second chip 60 by two second intermediate wires WB. The two second intermediate wires WB are provided outside the transformer chip 70. In the following description, for the sake of convenience, the two second intermediate wires WB are referred to as a “second intermediate wire WB1” and a “second intermediate wire WB2,” respectively.

Since one of the two second intermediate pads 66 is electrically connected to the receiving circuit 31, the fourth transformer pad 154, for example, constituted by the second end 141B of the first inner coil 141, is electrically connected to the receiving circuit 31 (see FIG. 10) by the second intermediate wire WB1. Therefore, it may be said that the first inner coil 141 is electrically connected to the second chip 60 by the second intermediate wire WB1. The other of the two second intermediate pads 66 is connected to the ground GND2 (see FIG. 10). Therefore, the sixth transformer pad 156, for example, constituted by the second end 142B of the second inner coil 142, is electrically connected to the ground GND2. Therefore, it may be said that the second inner coil 142 is electrically connected to the second chip 60 by the second intermediate wire WB2. Herein, the second intermediate wire WB1 is an example of a “third chip connecting wire,” and the second intermediate wire WB2 is an example of a “fourth chip connecting wire.”

### [Effects of Third Embodiment]

The semiconductor device 10 according to the third embodiment provides the following effects.
(3-1) The outer coil 130 includes the first outer coil 131 and the second outer coil 132 including the first ends 131A and 132A and the second ends 131B and 132B, respectively. The second end 131B of the first outer coil 131 and the second end 132B of the second outer coil 132 are connected to each other. The first outer coil 131 and the second outer coil 132 are configured so that when a current flows from a first end of one of the first outer coil 131 and the second outer coil 132 to a first end of the other outer coil, magnetic fluxes in opposite directions are generated. The inner coil 140 includes the first inner coil 141 and the second inner coil 142 including the first ends 141A and 142A and the second ends 141B and 142B, respectively. In a plan view, the first inner coil 141 is disposed inside the first outer coil 131 so as not to overlap with the first outer coil 131, and the second inner coil 142 is disposed inside the second outer coil 132 so as not to overlap the second outer coil 132.

With this configuration, the magnetic flux generated by the outer coil 130 may be suppressed from spreading. This allows an increased amount of magnetic flux to cross the inner coil 140. Therefore, it is possible to improve the efficiency of magnetic coupling between the outer coil 130 and the inner coil 140. As a result, it is possible to improve transfer characteristics between the outer coil 130 and the inner coil 140.
(3-2) The first inner coil 141 and the second inner coil 142 are connected by the wire WC provided outside the transformer chip 70. With this configuration, the configuration of the transformer chip 70 may be simplified as compared to a configuration in which the first inner coil 141 and the second inner coil 142 are electrically connected by a wiring provided inside the transformer chip 70. In other words, since a layer for providing the wiring in the third element insulating layer 72 is not required, a dedicated mask for providing the wiring is not required when manufacturing the third element insulating layer 72. Therefore, since a process of manufacturing the transformer chip 70 may be simplified, the manufacturing cost of the transformer chip 70 may be reduced.
(3-3) The first outer coil 131 is electrically connected to the first chip 50 by the first intermediate wire WA1 provided outside the transformer chip 70. The second outer coil 132 is electrically connected to the first chip 50 by the first intermediate wire WA2 provided outside the transformer chip 70.

With this configuration, a connection structure between the first outer coil 131 and the first chip 50 may be simplified, for example, as compared to a configuration in which the first outer coil 131 and the first chip 50 are connected by a wiring provided in the transformer chip 70. Further, a connection structure between the second outer coil 132 and the first chip 50 may be simplified, for example, as compared to a configuration in which the second outer coil 132 and the first chip 50 are connected by a wiring provided in the transformer chip 70. In addition, since there is no need to determine the disposition position of transformer chip 70 relative to the first chip 50 with high precision, the semiconductor device 10 may be easily manufactured.
(3-4) Each of the first outer coil 131, the second outer coil 132, the first inner coil 141, and the second inner coil 142 is disposed near the third element front surface 72S of the third element insulating layer 72 in the Z direction.

With this configuration, as compared to a configuration in which two coils are disposed opposite to each other in the Z direction, a distance between each of the first outer coil 131, the second outer coil 132, the first inner coil 141, and the second inner coil 142, and the third semiconductor substrate 71 in the Z direction may be increased. Therefore, the magnetic flux generated in the first outer coil 131, the second outer coil 132, the first inner coil 141, and the second inner coil 142 is less likely to pass through the third semiconductor substrate 71. This makes it possible to suppress the generation of an eddy current caused by the magnetic flux penetrating the third semiconductor substrate 71. Therefore, it is possible to suppress a decrease in efficiency of magnetic coupling caused by the eddy current.
(3-5) The first outer coil 131, the second outer coil 132, the first inner coil 141, and the second inner coil 142 are disposed at a same position in the Z direction. With this configuration, when manufacturing the transformer chip 70, the first outer coil 131, the second outer coil 132, the first inner coil 141, and the second inner coil 142 may be formed using a common mask. Therefore, as compared to a configuration in which the first outer coil 131, the second outer coil 132, the first inner coil 141, and the second inner coil 142 are disposed at different positions in the Z direction, a process of manufacturing the transformer chip 70 may be simplified, thus reducing the manufacturing cost of the transformer chip 70.

### <Modifications>

The above-described embodiments may be modified as follows. The following modifications may be combined with each other unless technically contradictory.

### [Combination of Embodiments]

The first and second embodiments may be implemented in combination with each other.
The second and third embodiments may be implemented in combination with each other.

### [Modifications of First Embodiment]

### (Modifications of Transformer Chip)

In the first embodiment, the configuration of the transformer chip 70 may be modified as desired. The transformer chip 70 may be modified, for example, as first to fifth modifications.

### (First Modification)

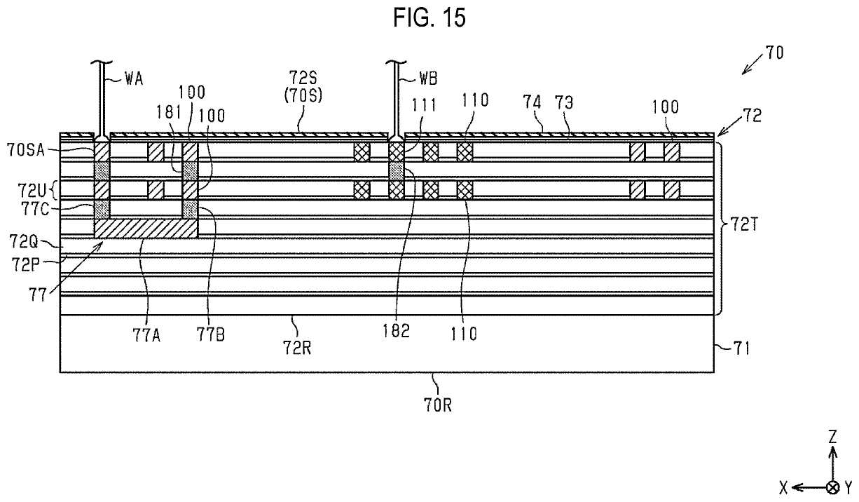

As shown in FIG. 15, the transformer chip 70 of the first modification includes two outer coils 100 disposed in the third element insulating layer 72 to be spaced apart from each other in the Z direction, and a via 181 connecting the two outer coils 100. The two outer coils 100 are connected in parallel by the via 181. The two outer coils 100 are disposed at a position overlapping each other in a plan view. The wiring portion 77 is disposed to be closer to the third semiconductor substrate 71 than the two outer coils 100 are disposed.

With this configuration, the wiring resistance value of the outer coils 100 may be reduced by connecting the two outer coils 100 in parallel. The number of outer coils 100 may be three or more.

Further, the transformer chip 70 of the first modification includes two inner coils 110 disposed in the third element insulating layer 72 to be spaced apart from each other in the Z direction, and a via 182 connecting the two inner coils 110. The two inner coils 110 are connected in parallel by the via 182. The two inner coils 110 are disposed at a position overlapping each other in a plan view. With this configuration, the wiring resistance value of the inner coils 110 may be reduced by connecting the two inner coils 110 in parallel. The number of inner coils 110 may be three or more.

### (Second Modification)

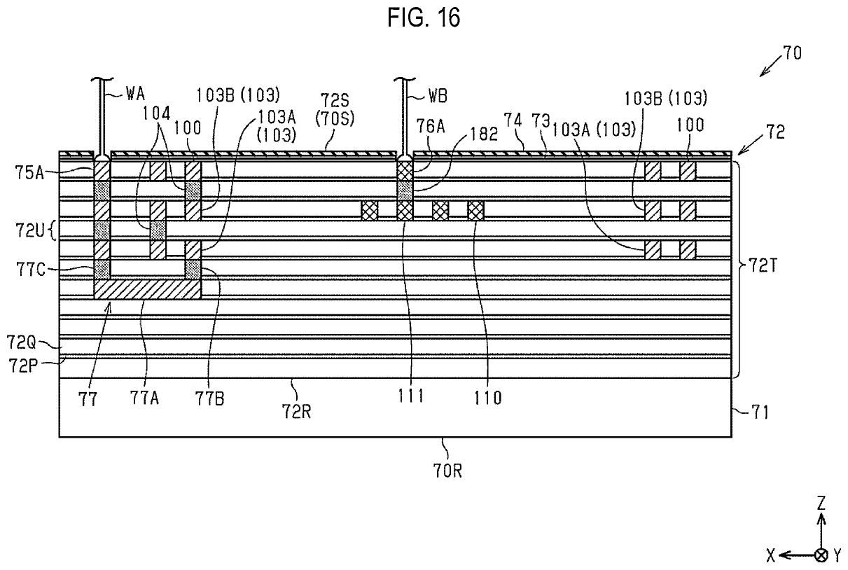

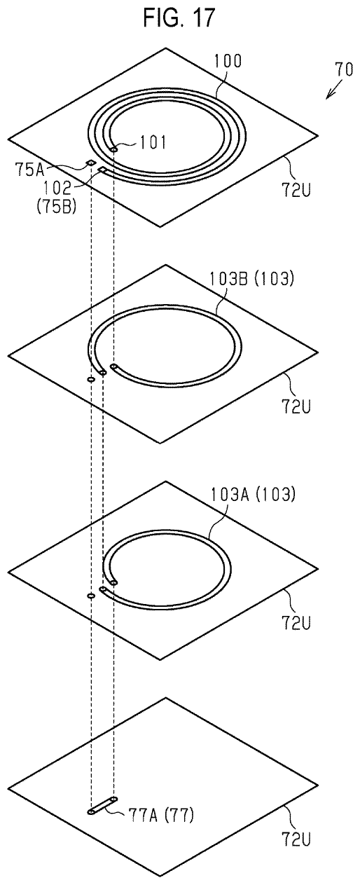

As shown in FIGS. 16 and 17, the transformer chip 70 of the second modification includes an outer coil 100, an outer coil 103 connected to the outer coil 100, and a via 104 connecting these outer coils 100 and 103. The outer coil 103 is disposed so as to overlap with the outer coil 100 in a plan view. The outer coil 103 includes coil portions 103A and 103B disposed to be spaced apart from each other in the Z direction. The coil portions 103A and 103B are connected in series between the outer coil 100 and the wiring portion 77 by the via 104. More specifically, the coil portion 103B is disposed to be closer to the outer coil 100 than the coil portion 103A is disposed in the Z direction. The coil portion 103B is connected in series with the outer coil 100. The coil portion 103B is electrically connected to the first end 101 of the outer coil 100 by the via 104. The coil portion 103A is connected in series with the coil portion 103B. The coil portion 103A is electrically connected to the wiring portion 77. That is, the coil portion 103A is electrically connected to the first transformer pad 75A. On the other hand, the second end 102 of the outer coil 100 constitutes the first transformer pad 75B.

In the transformer chip 70 of the second modification, the outer coil 103 is connected between the wiring portion 77 and the outer coil 100. Therefore, the number of turns of the outer coil consisting of the outer coil 100 and the outer coil 103 may be increased. This increases the amount of magnetic flux generated by the outer coil.

Further, the coil portions 103A and 103B of the outer coil 103 may be connected in parallel. Further, the outer coil 100 may be provided in plural as in the first modification shown in FIG. 15. In this case, the plurality of outer coils 100 may be connected in parallel. In this way, by connecting the outer coil 100 and the outer coil 103 in parallel, the number of turns may be increased and an increase in the wiring resistance value may be suppressed.

As shown in FIG. 16, in the transformer chip 70 of the second modification, the inner coil 110 is disposed at a same position as the coil portion 103B of the outer coil 103 in the Z direction. Further, the configuration of the inner coil 110 may be changed arbitrarily. The position of the inner coil 110 in the Z direction may also be changed arbitrarily. In one example, the inner coil 110 may be disposed at a same position as the outer coil 100 in the Z direction. In one example, the inner coil 110 may be disposed at a same position as the coil portion 103A of the outer coil 103 in the Z direction.

The first end 111 of the inner coil 110 is electrically connected to the second transformer pad 76A by the via 182. The second transformer pad 76A is disposed to be closer to the chip front surface 70S than the inner coil 110 is disposed in the Z direction. In one example, the second transformer pad 76A is disposed at a same position as the outer coil 100.

### (Third Modification)

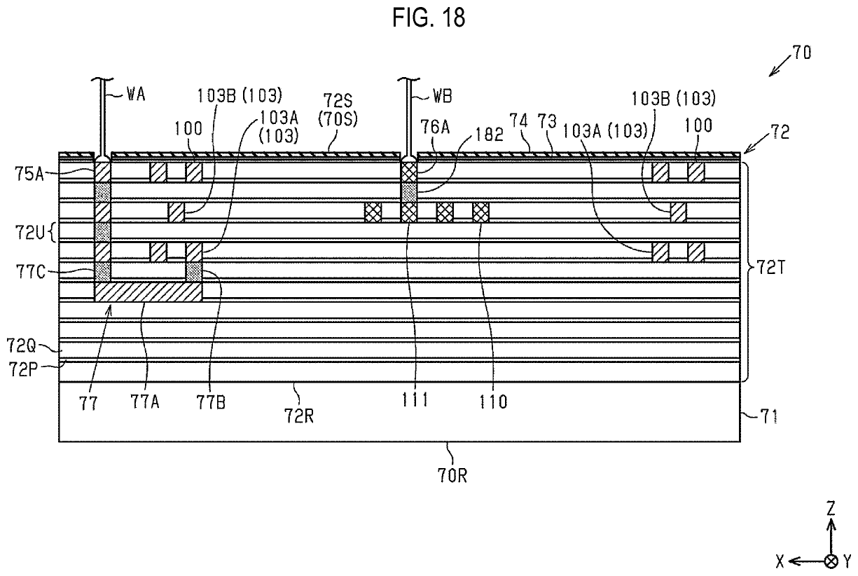

As shown in FIG. 18, the transformer chip 70 of the third modification is disposed so that the coil portion 103B of the outer coil 103 does not overlap with both the outer coil 100 and the coil portion 103A in a plan view, unlike the transformer chip 70 of the second modification shown in FIG. 16. By disposing the outer coil 100 and the coil portions 103A and 103B in this way, a facing area between the outer coil 100/the coil portion 103A and the coil portion 103B in the Z direction is reduced. Therefore, a capacitance of a parasitic capacitor caused by this facing area may be reduced.

### (Fourth Modification)

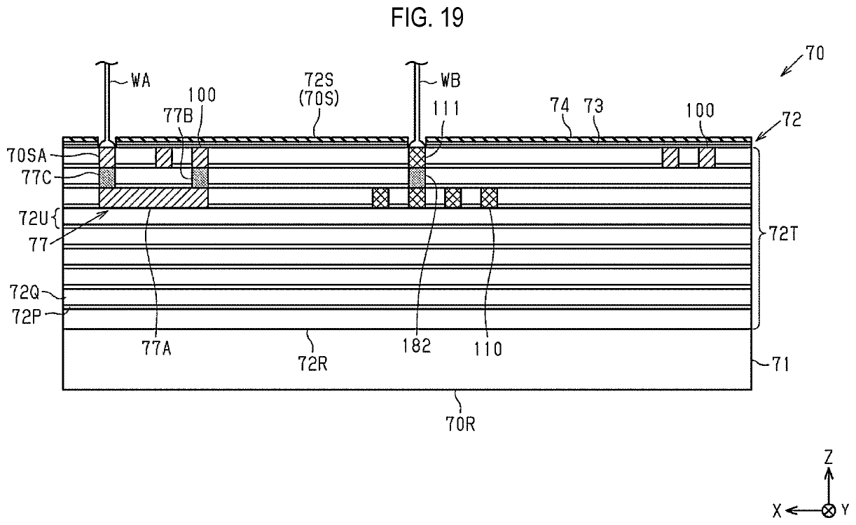

As shown in FIG. 19, in the transformer chip 70 of the fourth modification, the inner coil 110 may be disposed at a position different from the outer coil 100 in the Z direction. In the example shown in FIG. 19, the inner coil 110 is disposed to be closer to the third semiconductor substrate 71 than the outer coil 100 is disposed in the Z direction. With this configuration, a facing area between the outer coil 100 and the inner coil 110 in the direction orthogonal to the Z direction is reduced. Therefore, a capacitance of a parasitic capacitor caused by this facing area may be reduced.

Further, in the transformer chip 70 of the fourth modification, the outer coil 100 may be disposed to be closer to the third semiconductor substrate 71 than the inner coil 110 is disposed in the Z direction. In this case, the inner coil 110 is disposed, for example, on the uppermost insulator 72U of the insulating layer stack structure 72T of the third element insulating layer 72. The inner coil 110 may also be disposed, for example, on the insulator 72U immediately below the uppermost insulator 72U of the insulating layer stack structure 72T.

### (Fifth Modification)

The shapes of the outer coil 100 and the inner coil 110 in a plan view may be changed arbitrarily. In one example, the outer coil 100 and the inner coil 110 may be formed in a square shape in a plan view. In one example, the outer coil 100 and the inner coil 110 may be formed in a square shape with corners rounded in an arc shape in a plan view. In one example, the outer coil 100 and the inner coil 110 may be formed in an elliptical shape in a plan view.

### [Modifications of Second Embodiment]

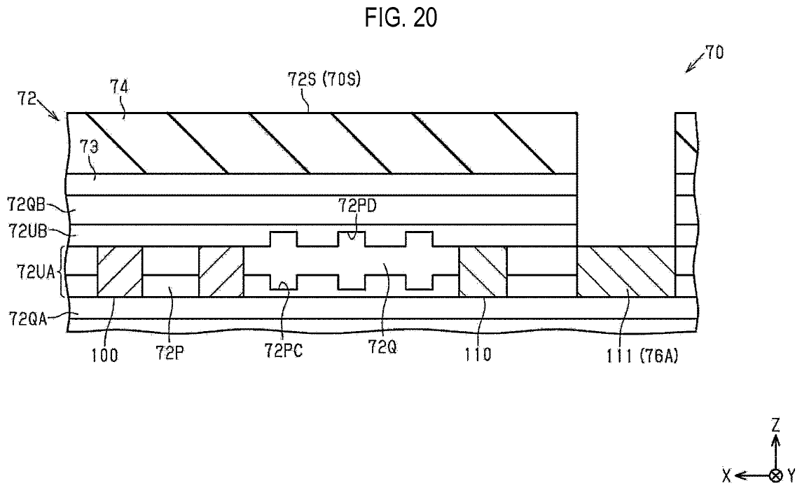

In the second embodiment, the configuration of the third element insulating layer 72 of the transformer chip 70 may be changed arbitrarily. In one example, as shown in FIG. 20, the first insulating film 72P of the specific insulator 72UA includes a plurality of concave portions 72PC that open toward the cover insulating film 72UB. The plurality of concave portions 72PC are disposed to be spaced apart from each other in a direction orthogonal to the Z direction. In one example, each concave portion 72PC is formed in an annular shape in a plan view. In one example, the plurality of concave portions 72PC are formed in a concentric shape in a plan view. In one example, centers of the plurality of concave portions 72PC are concentric with, for example, the center of the outer coil 100 and the center of the inner coil 110. The second insulating film 72Q of the specific insulator 72UA is embedded in the plurality of concave portions 72PC. The cover insulating film 72UB includes a plurality of cover side concave portions 72PD that open toward the first insulating film 72P of the specific insulator 72UA. The plurality of cover side concave portions 72PD are disposed to be spaced apart from each other in a plane direction orthogonal to the Z direction. In one example, the plurality of cover side concave portions 72PD are formed in a concentric shape in a plan view. Centers of the plurality of cover side concave portions 72PD are concentric with, for example, the center of the outer coil 100 and the center of the inner coil 110. The second insulating film 72Q of the specific insulator 72UA is embedded in the plurality of cover side concave portions 72PD. With this configuration, the same effects as those of (2-1) and (2-2) in the second embodiment may be obtained.
In the second embodiment, the number of isolation insulating films 78A and the number of cover side isolation insulating films 78B may be changed arbitrarily. In one example, the number of isolation insulating films 78A may be one. In one example, the number of cover side isolation insulating films 78B may be one. In another example, the number of isolation insulating films 78A may be different from the number of cover side isolation insulating films 78B.
In the second embodiment, the plurality of isolation insulating films 78A may be disposed at positions different from the positions of the plurality of cover side isolation insulating films 78B. That is, in a plan view, the plurality of isolation insulating films 78A may be disposed at positions where they do not overlap with the plurality of cover side isolation insulating films 78B. Further, in one example, in a plan view, the plurality of isolation insulating films 78A may be disposed at positions partially overlapping the plurality of cover side isolation insulating films 78B.
In the second embodiment, the isolation insulating film 78A only needs to penetrate the first insulating film 72P of the specific insulator 72UA in the Z direction, and the concave shape of the second insulating film 72Q may be omitted.
In the second embodiment, the cover side isolation insulating film 78B only needs to penetrate the cover insulating film 72UB in the Z direction, and the concave shape of the second insulating film 72Q of the specific insulator 72UA may be omitted.

### [Modifications of Third Embodiment]

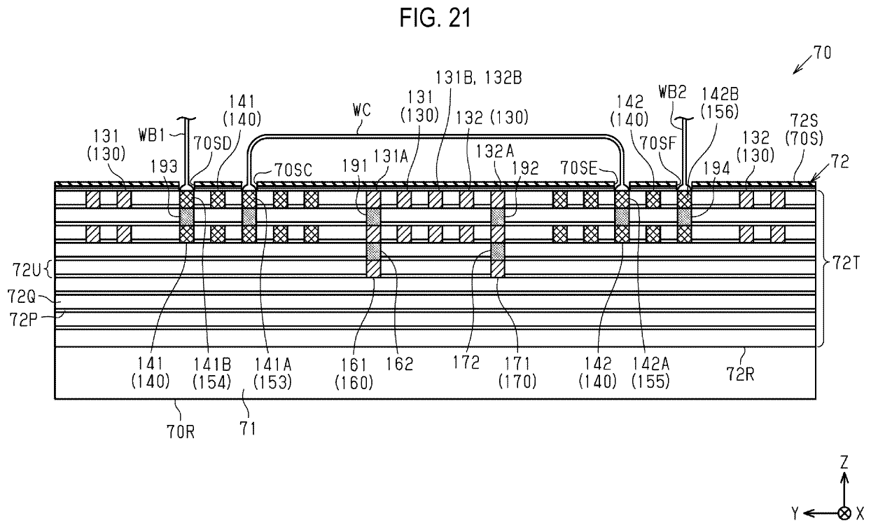

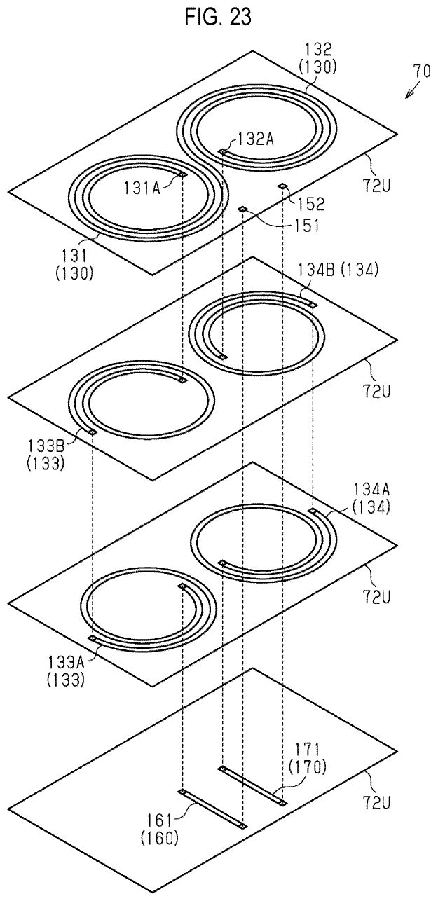

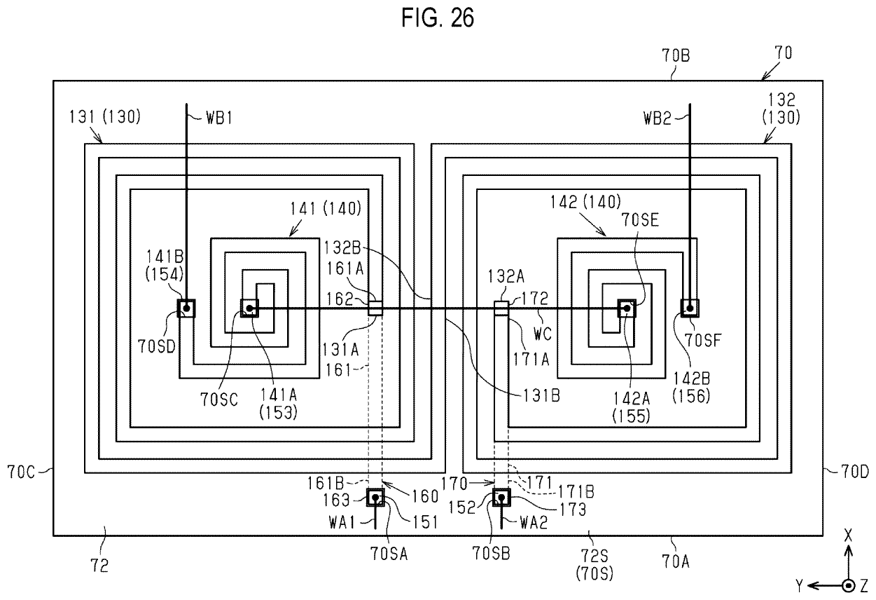

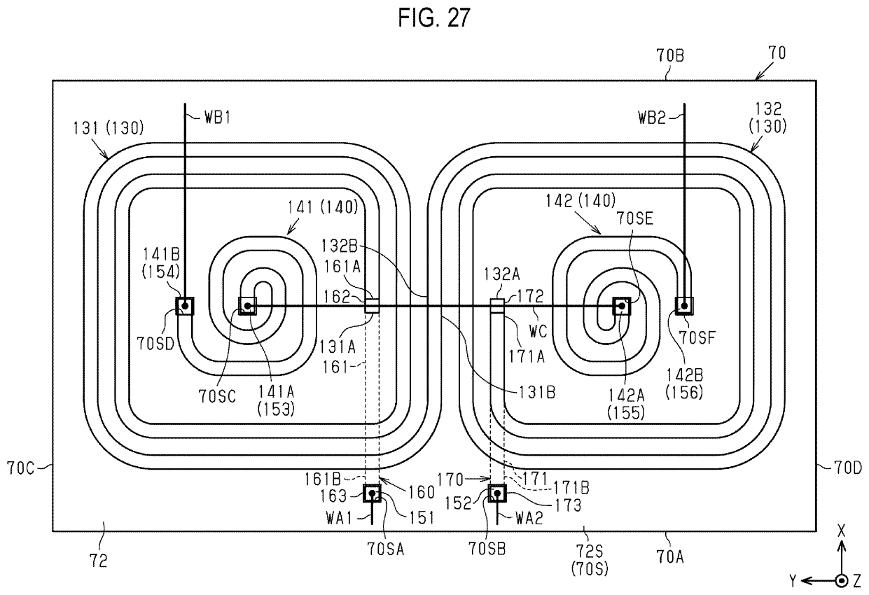

In the third embodiment, the configuration of the transformer chip 70 may be changed arbitrarily. The transformer chip 70 may be changed, for example, as in first to fifth modifications shown in FIGS. 21 to 27. FIGS. 21, 22, 24, and 25 show schematic cross-sectional structures of the transformer chip 70. Cross-sectional positions in FIGS. 21, 22, 24, and 25 are the same as the cross-sectional position of line F13-F13 in FIG. 12 of the third embodiment. FIG. 23 shows an exploded perspective structure of a portion of the transformer chip 70. FIGS. 26 and 27 show schematic planar structures of the transformer chip 70. For the sake of convenience, the outer coil 130 and the inner coil 140 are indicated by solid lines in FIGS. 26 and 27.

### (First Modification)

As shown in FIG. 21, the transformer chip 70 of the first modification includes two outer coils 130 disposed to be spaced apart from each other in the Z direction, and vias 191 and 192 connecting the two outer coils 130. Two first outer coils 131 disposed to be spaced apart from each other in the Z direction are connected in parallel by the via 191. Two second outer coils 132 disposed to be spaced apart from each other in the Z direction are connected in parallel by the via 192. With this configuration, as the two first outer coils 131 are connected in parallel and the two second outer coils 132 are connected in parallel, a wiring resistance value of the outer coil 130 may be reduced. Further, three or more outer coils 130 may be provided to be spaced apart from each other in the Z direction.

The inner coil 140 includes two inner coils 140 disposed to be spaced apart from each other in the Z direction, and vias 193 and 194 connecting the two inner coils 140. First inner coils 141 disposed to be spaced apart from each other in the Z direction are connected in parallel by the via 193. Second inner coils 142 disposed to be spaced apart from each other in the Z direction are connected in parallel by the via 194. With this configuration, as the two first inner coils 141 are connected in parallel and the two second inner coils 142 are connected in parallel, a wiring resistance value of the inner coil 140 may be reduced. Further, three or more inner coils 140 may be provided to be spaced apart from each other in the Z direction.

### (Second Modification)

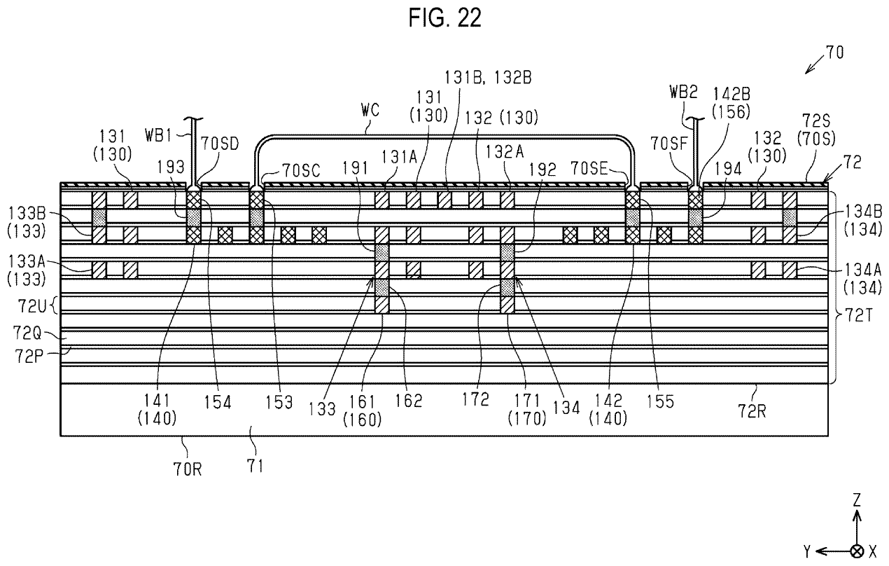

As shown in FIGS. 22 and 23, in the transformer chip 70 of the second modification, the outer coil 130 includes a first outer coil 131 and a second outer coil 132, a third outer coil 133 connected to the first outer coil 131, and a fourth outer coil 134 connected to the second outer coil 132.

The third outer coil 133 is disposed so as to overlap with the first outer coil 131 in a plan view. The third outer coil 133 includes coil portions 133A and 133B disposed to be spaced apart from each other in the Z direction. The coil portions 133A and 133B are connected in series between the first end 131A of the first outer coil 131 and the first wiring portion 160.

The fourth outer coil 134 is disposed so as to overlap with the second outer coil 132 in a plan view. The fourth outer coil 134 includes coil portions 134A and 134B disposed to be spaced apart from each other in the Z direction. The coil portions 134A and 134B are connected in series between the first end 132A of the second outer coil 132 and the second wiring portion 170.

In the transformer chip 70 of the second modification, the third outer coil 133 and the first outer coil 131 are connected in series between the first wiring portion 160 and the second outer coil 132. Further, the second outer coil 132 and the fourth outer coil 134 are connected in series between the first outer coil 131 and the second wiring portion 170. Therefore, the number of turns of the outer coil 130 disposed outside each of the first inner coil 141 and the second inner coil 142 may be increased. Therefore, an amount of magnetic flux generated by the outer coil 130 may be increased.

Further, the third outer coils 133 (the coil portions 133A and 133B) disposed to be spaced apart from each other in the Z direction may be connected in parallel. Similarly, the fourth outer coils 134 (the coil portions 134A and 134B) disposed to be spaced apart from each other in the Z direction may be connected in parallel. In this way, by connecting the third outer coils 133 and the fourth outer coils 134 in parallel, the number of turns of the outer coil 130 may be increased while suppressing an increase in the wiring resistance value.

As shown in FIG. 22, in the transformer chip 70 of the second modification, the inner coil 140 is disposed at a same position in the Z direction as the coil portion 133B of the third outer coil 133 and the coil portion 134B of the fourth outer coil 134. Also, the configuration of the inner coil 140 may be changed arbitrarily. The position of the inner coil 140 in the Z direction may also be changed arbitrarily. In one example, the inner coil 140 may be disposed at a same position as the outer coil 130 in the Z direction. In one example, the inner coil 140 may be disposed at a same position as the coil portion 133A of the third outer coil 133 and the coil portion 134A of the fourth outer coil 134 in the Z direction.

### (Third Modification)

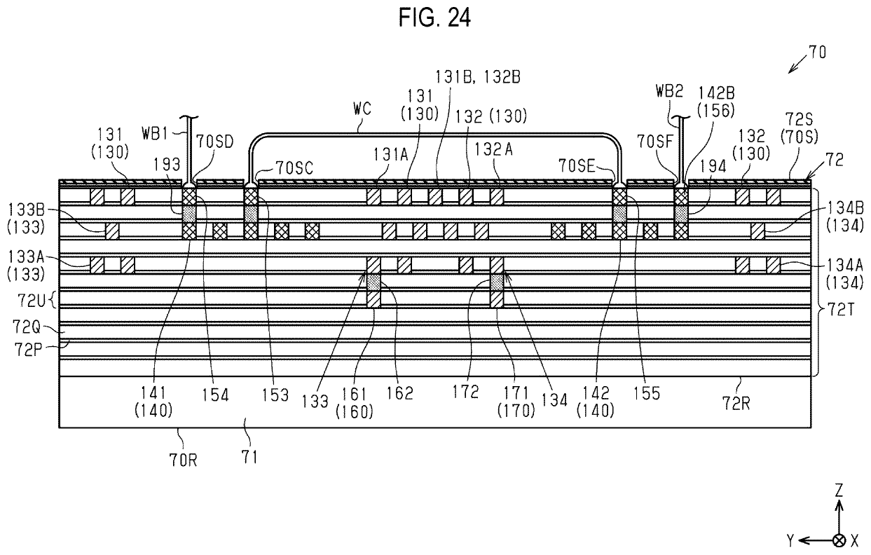

The transformer chip 70 of the third modification shown in FIG. 24 is different from the transformer chip 70 of the second modification shown in FIG. 22 in that the coil portion 133B of the third outer coil 133 is disposed so as not to overlap with the first outer coil 131, the second outer coil 132, and the coil portion 133A in a plan view. By disposing the first outer coil 131 and the third outer coil 133 in this way, a facing area between the coil portion 133B and the first outer coil 131/the second outer coil 132/the coil portion 133A in the Z direction is reduced. Therefore, a capacitance of a parasitic capacitor caused by this facing area may be reduced.

### (Fourth Modification)

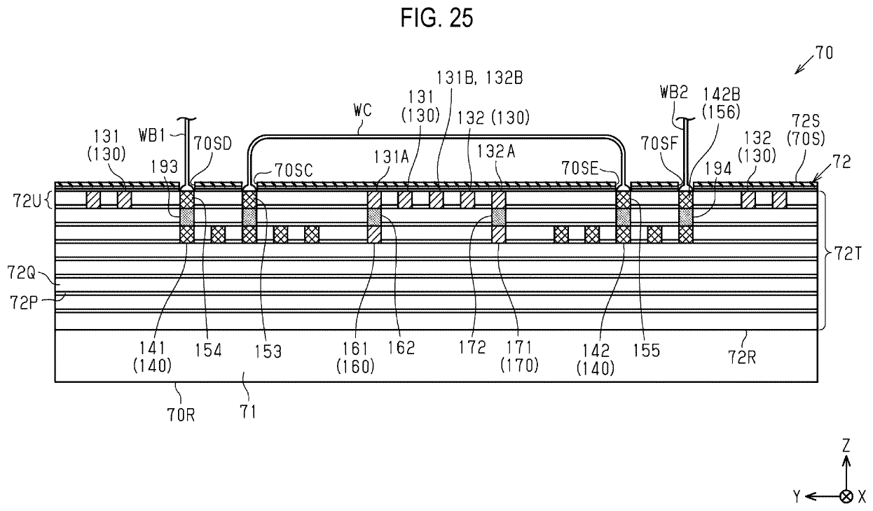

In the transformer chip 70 of the fourth modification shown in FIG. 25, the first inner coil 141 and the second inner coil 142 of the inner coil 140 are disposed at positions different from the first outer coil 131 and the second outer coil 132 of the outer coil 130 in the Z direction. In one example, the first inner coil 141 and the second inner coil 142 are disposed to be closer to the third semiconductor substrate 71 than the first outer coil 131 and the second outer coil 132 are disposed in the Z direction. With this configuration, a facing area between the inner coil 140 and the outer coil 130 in a direction orthogonal to the Z direction is reduced. Therefore, a capacitance of a parasitic capacitor caused by this facing area may be reduced.

Further, in the transformer chip 70 of the fourth modification, the outer coil 130 may be disposed to be closer to the third semiconductor substrate 71 than the inner coil 140 is disposed in the Z direction. In this case, the inner coil 140 is disposed, for example, at the uppermost insulator 72U of the insulating layer stack structure 72T of the third element insulating layer 72. The inner coil 140 may also be disposed, for example, at the insulator 72U immediately below the uppermost insulator 72U of the insulating layer stack structure 72T.

### (Fifth Modification)

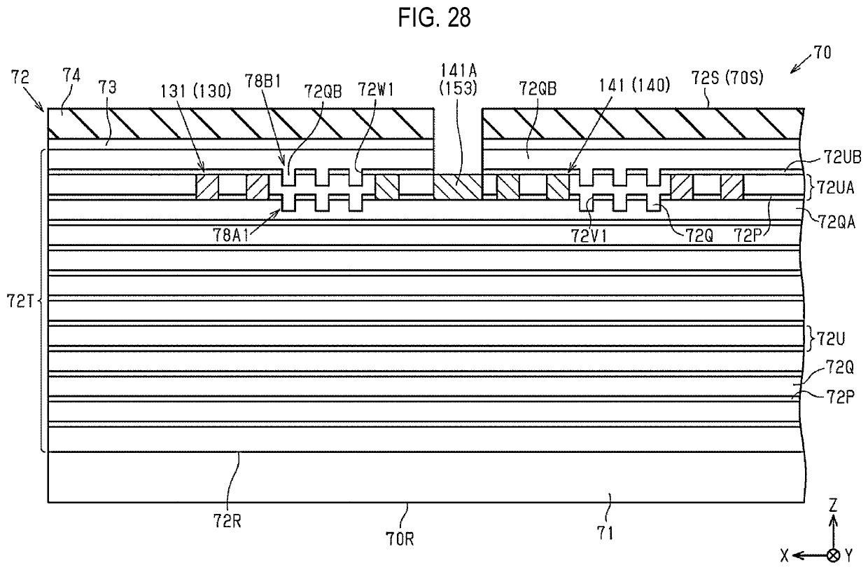

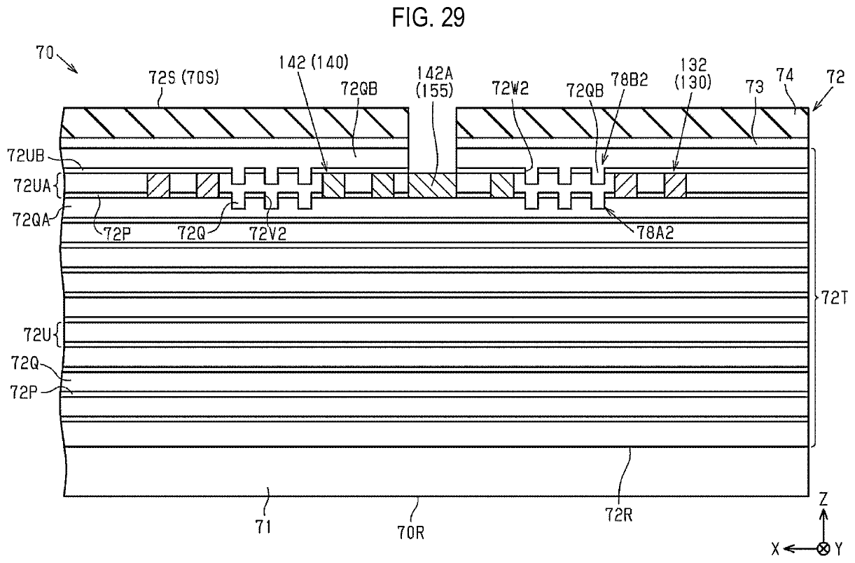

The shapes of the outer coil 130 and the inner coil 140 in a plan view may be changed arbitrarily. In one example, as shown in FIG. 26, each of the outer coil 130 and the inner coil 140 may be formed in a square shape in a plan view. Further, in one example, as shown in FIG. 27, each of the outer coil 130 and the inner coil 140 may be formed in a square shape with corners rounded in an arc shape in a plan view. Further, although not shown, each of the outer coil 130 and the inner coil 140 may be formed in an elliptical shape in a plan view.
A positional relationship in the Z direction between the first outer coil 131 and the second outer coil 132 of the outer coil 130 may be changed arbitrarily. In one example, the first outer coil 131 and the second outer coil 132 may be disposed at different positions in the Z direction. In this case, the second end 131B of the first outer coil 131 and the second end 132B of the second outer coil 132 may be formed so as to overlap each other in a plan view. Then, the second end 131B of the first outer coil 131 and the second end 132B of the second outer coil 132 may be directly electrically connected.
A positional relationship in the Z direction between the first inner coil 141 and the second inner coil 142 of the inner coil 140 may be changed arbitrarily. In one example, the first inner coil 141 and the second inner coil 142 may be disposed at different positions in the Z direction.
The first end 141A of the first inner coil 141 and the first end 142A of the second inner coil 142 of the inner coil 140 may be connected to the second chip 60. The second chip 60 may include a pad connected to the first end 141A of the first inner coil 141 and a pad connected to the first end 142A of the second inner coil 142 of the inner coil 140. The second circuit 30 of the second chip 60 may include a first receiving circuit that receives a signal transmitted by the first inner coil 141 and a second receiving circuit that receives a signal transmitted by the second inner coil 142.
A configuration in a case where the third embodiment is combined with the second embodiment is described with reference to FIGS. 28 and 29. FIG. 28 shows an enlarged cross-sectional structure of the first outer coil 131, the first inner coil 141, and their periphery. FIG. 29 shows an enlarged cross-sectional structure of the second outer coil 132, the second inner coil 142, and their periphery.

As shown in FIG. 28, a plurality of first grooves 72V1 are provided in a portion of the first insulating film 72P of the specific insulator 72UA between the first inner coil 141 and the first outer coil 131. Herein, the specific insulator 72UA is provided with the first inner coil 141, the second inner coil 142 (see FIG. 29), the first outer coil 131, and the second outer coil 132 (see FIG. 29). The plurality of first grooves 72V1 are provided to be spaced apart from each other in a direction orthogonal to the Z direction. Each first groove 72V1 is formed in an annular shape in a plan view. In one example, the plurality of first grooves 72V1 are formed in a concentric shape in a plan view. In one example, centers of the plurality of first grooves 72V 1 are concentric with the center of the first outer coil 131 and the center of the first inner coil 141. In this way, the plurality of first grooves 72V1 allow the first insulating film 72P of the specific insulator 72UA to be spaced apart from each other in the direction orthogonal to the Z direction between the first outer coil 131 and the first inner coil 141.

Each first groove 72V1 is a rectangular groove that penetrates the first insulating film 72P of the specific insulator 72UA in the Z direction and forms a concave shape in the second insulating film 72QA immediately below the specific insulator 72UA. The second insulating film 72Q of the specific insulator 72UA enters each first groove 72V1. This forms a plurality of first isolation insulating films 78A1. In this way, a portion of the first insulating film 72P of the specific insulator 72UA between the first inner coil 141 and the first outer coil 131 includes the plurality of first isolation insulating films 78A1 that are provided to be spaced apart from each other in the direction orthogonal to the Z direction. That is, the first insulating film 72P between the first outer coil 131 and the first inner coil 141 is isolated by the second insulating film 72Q (the first isolation insulating film 78A1) having a smaller dielectric constant than the first insulating film 72P. Since each first groove 72V1 is formed in an annular shape, each first isolation insulating film 78A1 provided in each first groove 72V1 is formed in an annular shape in a plan view. When the plurality of first grooves 72V1 are formed in a concentric shape in a plan view, the plurality of first isolation insulating films 78A1 are formed in a concentric shape in a plan view. In this way, the first insulating film 72P and the second insulating film 72Q are alternately disposed between the first outer coil 131 and the first inner coil 141 in the direction orthogonal to the Z direction.

As shown in FIG. 29, a plurality of second grooves 72V2 are provided in a portion of the first insulating film 72P of the specific insulator 72UA between the second inner coil 142 and the second outer coil 132. The plurality of second grooves 72V2 are provided to be spaced apart from each other in a direction orthogonal to the Z direction. Each second groove 72V2 is formed in an annular shape in a plan view. In one example, the plurality of second grooves 72V2 are formed in a concentric shape in a plan view. In one example, centers of the plurality of second grooves 72V2 are concentric with the center of the second outer coil 132 and the center of the second inner coil 142. In this way, the plurality of second grooves 72V2 allow the first insulating film 72P of the specific insulator 72UA to be spaced apart from each other in the direction orthogonal to the Z direction between the second outer coil 132 and the second inner coil 142.

Each second groove 72V2 is a rectangular groove that penetrates the first insulating film 72P of the specific insulator 72UA in the Z direction and forms a concave shape in the second insulating film 72QA immediately below the specific insulator 72UA. The second insulating film 72Q of the specific insulator 72UA enters each second groove 72V2. This forms a plurality of second isolation insulating films 78A2. In this way, a portion of the first insulating film 72P of the specific insulator 72UA between the second inner coil 142 and the second outer coil 132 includes the plurality of second isolation insulating films 78A2 that are provided to be spaced apart from each other in the direction orthogonal to the Z direction. That is, the first insulating film 72P between the second outer coil 132 and the second inner coil 142 is isolated by the second insulating film 72Q (the second isolation insulating film 78A2) having a smaller dielectric constant than the first insulating film 72P. Since each second groove 72V2 is formed in an annular shape, each second isolation insulating film 78A2 provided in each second groove 72V2 is formed in an annular shape in a plan view. When the plurality of second grooves 72V2 are formed in a concentric shape in a plan view, the plurality of second isolation insulating films 78A2 are formed in a concentric shape in a plan view. In this way, the first insulating film 72P and the second insulating film 72Q are alternately disposed between the second outer coil 132 and the second inner coil 142 in the direction orthogonal to the Z direction.

As shown in FIG. 28, a plurality of first grooves 72W1 are provided in a portion of the cover insulating film 72UB between the first inner coil 141 and the first outer coil 131, wherein the cover insulating film 72UB contacts the second insulating film 72Q of the specific insulator 72UA. The plurality of first grooves 72W1 are provided to be spaced apart from each other in a direction orthogonal to the Z direction. Each first groove 72W1 is formed in an annular shape in a plan view. In one example, the plurality of first grooves 72W1 are formed in a concentric shape in a plan view. In one example, centers of the plurality of first grooves 72W1 are concentric with the center of the first outer coil 131 and the center of the first inner coil 141. In this way, the plurality of first grooves 72W1 allow the cover insulating film 72UB to be spaced apart from each other in the direction orthogonal to the Z direction between the first outer coil 131 and the first inner coil 141.

Each first groove 72W1 is a rectangular groove that penetrates the cover insulating film 72UB in the Z direction and forms a concave shape in the second insulating film 72Q of the specific insulator 72UA. The second insulating film 72QB on the cover insulating film 72UB enters each first groove 72W1. This forms a plurality of first cover side isolation insulating films 78B1. In this way, a portion of the cover insulating film 72UB between the first inner coil 141 and the first outer coil 131 includes the plurality of first cover side isolation insulating films 78B1 that are provided to be spaced apart from each other in the direction orthogonal to the Z direction. That is, the cover insulating film 72UB between the first outer coil 131 and the first inner coil 141 is isolated by the second insulating film 72Q (the first cover side isolation insulating film 78B1) having a smaller dielectric constant than the first insulating film 72P. Since each first groove 72W1 is formed in an annular shape, each first cover side isolation insulating film 78B1 provided in each first groove 72W1 is formed in an annular shape in a plan view. When the plurality of first grooves 72W1 are formed in a concentric shape in a plan view, the plurality of first cover side isolation insulating films 78B1 are formed in a concentric shape in a plan view. In this way, the first insulating film 72P and the second insulating film 72Q are alternately disposed between the first outer coil 131 and the first inner coil 141 in the direction orthogonal to the Z direction.

As shown in FIG. 29, a plurality of second grooves 72W2 are provided in a portion of the cover insulating film 72UB between the second inner coil 142 and the second outer coil 132, wherein the cover insulating film 72UB contacts the second insulating film 72Q of the specific insulator 72UA. The plurality of second grooves 72W2 are provided to be spaced apart from each other in a direction orthogonal to the Z direction. Each second groove 72W2 is formed in an annular shape in a plan view. In one example, the plurality of second grooves 72W2 are formed in a concentric shape in a plan view. In one example, centers of the plurality of second grooves 72W2 are concentric with the center of the second outer coil 132 and the center of the second inner coil 142. In this way, the plurality of second grooves 72W2 allow the cover insulating film 72UB to be spaced apart from each other in the direction orthogonal to the Z direction between the second outer coil 132 and the second inner coil 142.

Each second groove 72W2 is a rectangular groove that penetrates the cover insulating film 72UB in the Z direction and forms a concave shape in the second insulating film 72Q of the specific insulator 72UA. The second insulating film 72QB on the cover insulating film 72UB enters each second groove 72W2. This forms a plurality of second cover side isolation insulating films 78B2. In this way, a portion of the cover insulating film 72UB between the second inner coil 142 and the second outer coil 132 includes the plurality of second cover side isolation insulating films 78B2 that are provided to be spaced apart from each other in the direction orthogonal to the Z direction. That is, the cover insulating film 72UB between the second outer coil 132 and the second inner coil 142 is isolated by the second insulating film 72Q (the second cover side isolation insulating film 78B2) having a smaller dielectric constant than the first insulating film 72P. Since each second groove 72W2 is formed in an annular shape, each second cover side isolation insulating film 78B2 provided in each second groove 72W2 is formed in an annular shape in a plan view. When the plurality of second grooves 72W2 are formed in a concentric shape in a plan view, the plurality of second cover side isolation insulating films 78B2 are formed in a concentric shape in a plan view. In this way, the first insulating film 72P and the second insulating film 72Q are alternately disposed between the second outer coil 132 and the second inner coil 142 in the direction orthogonal to the Z direction.

In one example, a width dimension of each first groove 72W1 is equal to a width dimension of each first groove 72V1. Further, the width dimensions of the plurality of first grooves 72W1 are equal to each other. Further, the width dimensions of the plurality of first grooves 72V1 are equal to each other. In one example, a width dimension of each second groove 72W2 is equal to a width dimension of each second groove 72V2. Further, the width dimensions of the plurality of second grooves 72W2 are equal to each other. Further, the width dimensions of the second grooves 72V2 are equal to each other. Herein, the width dimension of each of the first grooves 72V1 and 72W1 may be defined by a distance between side surfaces constituting each of the first grooves 72V1 and 72W1 in the direction orthogonal to the Z direction. The width dimension of each of the second grooves 72V2 and 72W2 may be defined by a distance between side surfaces constituting each of the second grooves 72V2 and 72W2 in the direction orthogonal to the Z direction.

When the width dimension of each first groove 72W1 and the width dimension of each first groove 72V1 are equal to each other, a width dimension of each first cover side isolation insulating film 78B1 is equal to a width dimension of each first isolation insulating film 78A1. Further, when the width dimensions of the plurality of first grooves 72W1 are equal to each other, the width dimensions of the plurality of first cover side isolation insulating films 78B1 are equal to each other. Further, when the width dimensions of the plurality of first grooves 72V1 are equal to each other, the width dimensions of the plurality of first isolation insulating films 78A1 are equal to each other. Herein, the width dimension of the first isolation insulating film 78A1 may be defined by a distance between side surfaces of the first isolation insulating film 78A1 that contact the side surfaces constituting the first groove 72V1 in the direction orthogonal to the Z direction. Further, the width dimension of the first cover side isolation insulating film 78B1 may be defined by a distance between side surfaces of the first cover side isolation insulating film 78B1 that contact the side surfaces constituting the first groove 72W1 in the direction orthogonal to the Z direction.

When the width dimension of each second groove 72W2 is equal to the width dimension of each second groove 72V2, a width dimension of each second cover side isolation insulating film 78B2 is equal to a width dimension of each second isolation insulating film 78A2. Further, when the width dimensions of the plurality of the second grooves 72W2 are equal to each other, the width dimensions of the plurality of second cover side isolation insulating films 78B2 are equal to each other. Further, when the width dimensions of the plurality of second grooves 72V2 are equal to each other, the width dimensions of the plurality of second isolation insulating films 78A2 are equal to each other. Herein, the width dimension of the second isolation insulating film 78A2 may be defined by a distance between side surfaces of the second isolation insulating film 78A2 that contact the side surfaces constituting the second groove 72V2 in the direction orthogonal to the Z direction. Further, the width dimension of the second cover side isolation insulating film 78B2 may be defined by a distance between side surfaces of the second cover side isolation insulating film 78B2 that contact the side surfaces constituting the second groove 72W2 in the direction orthogonal to the Z direction.

With this configuration, the plurality of first isolation insulating films 78A1 and second insulating films 72Q are alternately disposed in a portion of the first insulating film 72P of the specific insulator 72UA between the first inner coil 141 and the first outer coil 131. As a result, it is possible to increase an interface distance between the first inner coil 141 and the first outer coil 131. In other words, an insulation distance between the first inner coil 141 and the first outer coil 131 may be increased. The plurality of second isolation insulating films 78A2 and second insulating films 72Q are alternately disposed in a portion of the first insulating film 72P of the specific insulator 72UA between the second inner coil 142 and the second outer coil 132. As a result, it is possible to increase an interface distance between the second inner coil 142 and the second outer coil 132. In other words, an insulation distance between the second inner coil 142 and the second outer coil 132 may be increased.

Further, the plurality of first cover side isolation insulating films 78B1 and second insulating films 72Q are alternately disposed in a portion of the cover insulating film 72UB between the first inner coil 141 and the first outer coil 131. As a result, it is possible to increase the interface distance between the first inner coil 141 and the first outer coil 131. In other words, the insulation distance between the first inner coil 141 and the first outer coil 131 may be increased. The plurality of second cover side isolation insulating film 78B2 and second insulating film 72Q are alternately disposed in a portion of the cover insulating film 72UB between the second inner coil 142 and the second outer coil 132. As a result, it is possible to increase the interface distance between the second inner coil 142 and the second outer coil 132. In other words, the insulation distance between the second inner coil 142 and the second outer coil 132 may be increased. Therefore, it is possible to improve the dielectric breakdown voltage of the semiconductor device 10 while suppressing the increase in size of the transformer chip 70.

Further, the number of first grooves 72V1 and 72W1 may be changed arbitrarily. Further, in the modification shown in FIGS. 28 and 29, the first grooves 72V1 and 72W1 are disposed at positions overlapping each other in a plan view, but are not limited thereto. The first grooves 72V1 and 72W1 may be disposed at positions different from each other in a plan view. In other words, the number of first isolation insulating films 78A1 and the number of first cover side isolation insulating films 78B1 may be changed arbitrarily. Further, in the modification shown in FIGS. 28 and 29, the first isolation insulating film 78A1 and the first cover side isolation insulating film 78B1 are disposed at positions overlapping each other in a plan view, but are not limited thereto. The first isolation insulating film 78A1 and the first cover side isolation insulating film 78B1 may be disposed at positions different from each other in a plan view.

Further, the number of second grooves 72V2 and 72W2 may be changed arbitrarily. Further, in the modification shown in FIGS. 28 and 29, the second grooves 72V2 and 72W2 are disposed at positions overlapping each other in a plan view, but are not limited thereto. The second grooves 72V2 and 72W2 may be disposed at positions different from each other in a plan view. In other words, the number of second isolation insulating films 78A2 and the number of second cover side isolation insulating films 78B2 may be changed arbitrarily. Further, in the modification shown in FIGS. 28 and 29, the second isolation insulating film 78A2 and the second cover side isolation insulating film 78B2 are disposed at positions overlapping each other in a plan view, but are not limited thereto. The second isolation insulating film 78A2 and the second cover side isolation insulating film 78B2 may be disposed at positions different from each other in a plan view.

Further, the width dimensions of the first grooves 72V1 and 72W1 may be changed arbitrarily. In one example, the width dimension of the first groove 72V1 and the width dimension of the first groove 72W1 may be different from each other. That is, the width dimension of the first isolation insulating film 78A1 and the width dimension of the first cover side isolation insulating film 78B1 may be different from each other. In one example, the width dimension of at least one selected from the group of the plurality of first grooves 72V1 may be different from the width dimensions of the remaining first grooves 72V1. That is, the width dimension of at least one selected from the group of the plurality of first isolation insulating films 78A1 may be different from the width dimensions of the remaining first isolation insulating films 78A1. In one example, the width dimension of at least one selected from the group of the plurality of first grooves 72W1 may be different from the width dimensions of the remaining first grooves 72W1. That is, the width dimension of at least one selected from the group of the plurality of first cover side isolation insulating films 78B1 may be different from the width dimensions of the remaining first cover side isolation insulating films 78B1. Also, the shapes of the first grooves 72V1 and 72W1 are not limited to a rectangular concave shape and may be changed arbitrarily. In one example, the first grooves 72V1 and 72W1 may be V-shaped.

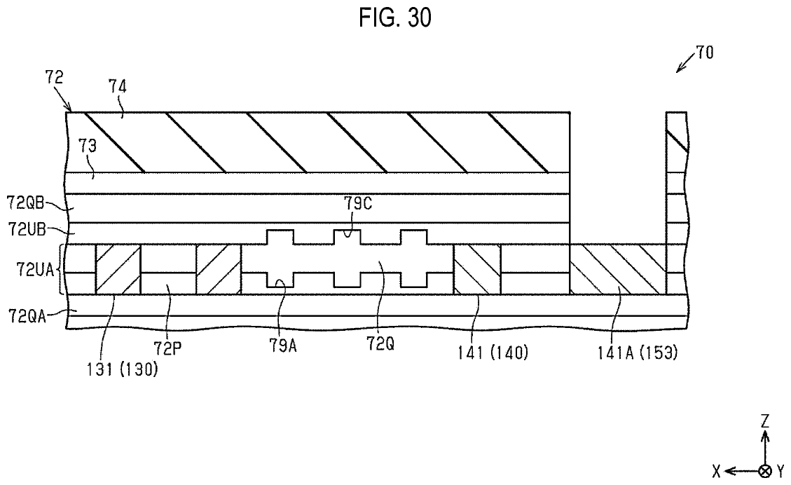

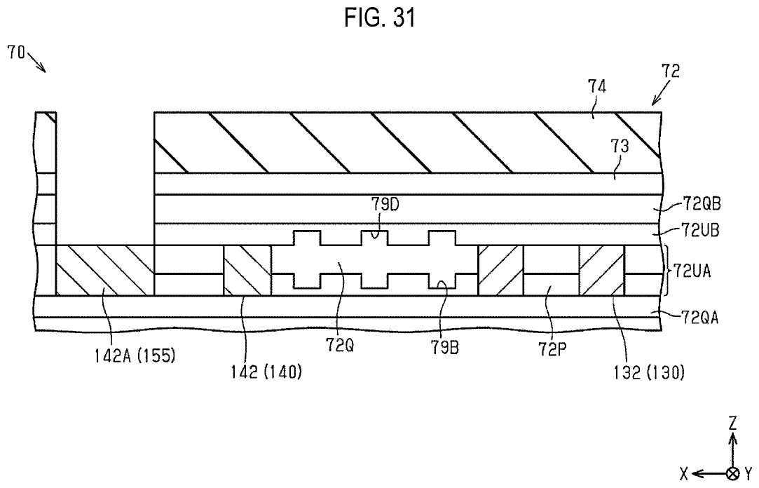

Further, the width dimensions of the second grooves 72V2 and 72W2 may be changed arbitrarily. In one example, the width dimension of the second groove 72V2 and the width dimension of the second groove 72W2 may be different from each other. That is, the width dimension of the second isolation insulating film 78A2 and the width dimension of the second cover side isolation insulating film 78B2 may be different from each other. In one example, the width dimension of at least one selected from the group of the plurality of second grooves 72V2 may be different from the width dimensions of the remaining second grooves 72V2. That is, the width dimension of at least one selected from the group of the plurality of second isolation insulating films 78A2 may be different from the width dimensions of the remaining second isolation insulating films 78A2. In one example, the width dimension of at least one selected from the group of the plurality of second grooves 72W2 may be different from the width dimensions of the remaining second grooves 72W2. That is, the width dimension of at least one selected from the group of the plurality of second cover side isolation insulating films 78B2 may be different from the width dimensions of the remaining second cover side isolation insulating films 78B2. Also, the shapes of the second grooves 72V2 and 72W2 are not limited to a rectangular concave shape and may be changed arbitrarily. In one example, the second grooves 72V2 and 72W2 may be V-shaped.
The first isolation insulating film 78A1, the second isolation insulating film 78A2, the first cover side isolation insulating film 78B1, and the second cover side isolation insulating film 78B2 in the modification shown in FIGS. 28 and 29 may be replaced with a configuration shown in FIGS. 30 and 31. FIG. 30 shows an enlarged cross-sectional structure of the first outer coil 131, the first inner coil 141, and their periphery. FIG. 31 shows an enlarged cross-sectional structure of the second outer coil 132, the second inner coil 142, and their periphery.

As shown in FIG. 30, a plurality of first concave portions 79A that open toward the cover insulating film 72UB are provided in a portion of the first insulating film 72P of the specific insulator 72UA between the first inner coil 141 and the first outer coil 131. Each first concave portion 79A is formed in an annular shape in a plan view. In one example, the plurality of first concave portions 79A are formed in a concentric shape in a plan view. In one example, centers of the plurality of first concave portions 79A are concentric with the center of the first inner coil 141 and the center of the first outer coil 131. The second insulating film 72Q of the specific insulator 72UA enters each first concave portion 79A. As shown in FIG. 31, a plurality of second concave portions 79B that open toward the cover insulating film 72UB are provided in a portion of the first insulating film 72P of the specific insulator 72UA between the second inner coil 142 and the second outer coil 132. Each second concave portion 79B is formed in an annular shape in a plan view. In one example, the plurality of second concave portions 79B are formed in a concentric circle shape in a plan view. In one example, centers of the plurality of second concave portions 79B are concentric with the center of the second inner coil 142 and the center of the second outer coil 132. The second insulating film 72Q of the specific insulator 72UA enters each second concave portion 79B.

As shown in FIG. 30, a plurality of first cover side concave portions 79C that open toward the first insulating film 72P of the specific insulator 72UA are provided in a portion of the cover insulating film 72UB between the first inner coil 141 and the first outer coil 131. Each first cover side concave portion 79C is formed in an annular shape in a plan view. In one example, the plurality of first cover side concave portions 79C are formed in a concentric shape in a plan view. In one example, centers of the plurality of first cover side concave portions 79C are concentric with the center of the first inner coil 141 and the center of the first outer coil 131. The second insulating film 72Q of the specific insulator 72UA enters each first cover side concave portion 79C. As shown in FIG. 31, a plurality of second cover side concave portions 79D that open toward the first insulating film 72P of the specific insulator 72UA are provided in a portion of the cover insulating film 72UB between the second inner coil 142 and the second outer coil 132. Each second cover side concave portion 79D is formed in an annular shape in a plan view. In one example, the plurality of second cover side concave portions 79D are formed in a concentric shape in a plan view. In one example, centers of the second cover side concave portions 79D are concentric with the center of the second inner coil 142 and the center of the second outer coil 132. The second insulating film 72Q of the specific insulator 72UA enters each second cover side concave portion 79D.

With this configuration, as in the modification shown in FIGS. 28 and 29, the plurality of first concave portions 79A and the plurality of first cover side concave portions 79C may increase the interface distance between the first inner coil 141 and the first outer coil 131. In other words, the insulation distance between the first inner coil 141 and the first outer coil 131 may be increased. Further, the plurality of second concave portions 79B and the plurality of second cover side concave portions 79D may increase the interface distance between the second inner coil 142 and the second outer coil 132. In other words, the insulation distance between the second inner coil 142 and the second outer coil 132 may be increased. Therefore, it is possible to improve the dielectric breakdown voltage of the semiconductor device 10 while suppressing the increase in size of the transformer chip 70.

[Modifications common to First to Third Embodiments]
In each embodiment, the configuration of the third element insulating layer 72 of the transformer chip 70 may be changed arbitrarily. In one example, the first insulating film 72P may be omitted from the third element insulating layer 72. That is, the insulating layer stack structure 72T of the third element insulating layer 72 may be configured by stacking a plurality of second insulating films 72Q.

### (Modifications of Sub-Mount Chip)

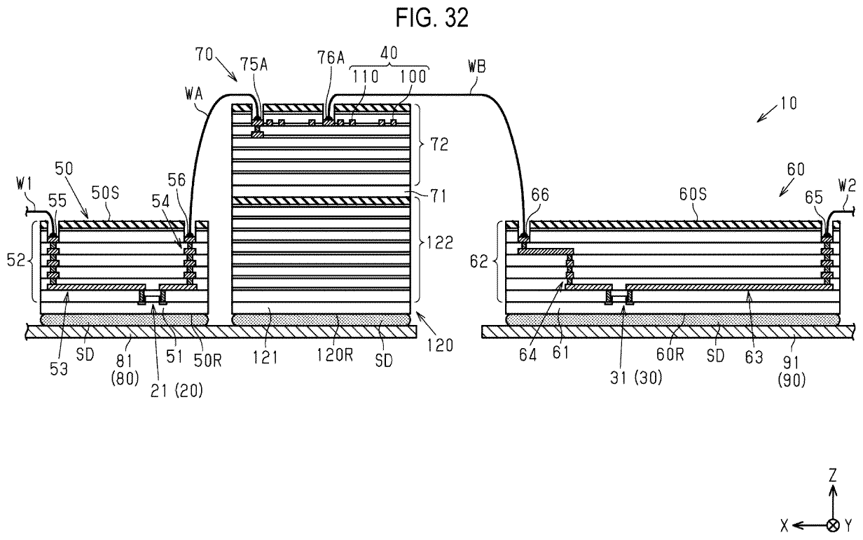

The configuration of the sub-mount chip 120 may be changed arbitrarily. The sub-mount chip 120 may be changed, for example, as in first to fifth modifications. For the sake of convenience, the sealing resin 200 (see FIG. 3) is omitted in FIGS. 32 to 34.

### (First Modification)

FIG. 32 shows a schematic cross-sectional structure of the first chip 50, the second chip 60, the transformer chip 70, the sub-mount chip 120, and their periphery in the first modification. The cross-sectional position in FIG. 32 is the same as the cross-sectional position in FIG. 8 of the first embodiment.

As shown in FIG. 32, the thickness of the sub-mount chip 120 may be greater than the thickness of the first chip 50. The thickness of the sub-mount chip 120 may be greater than the thickness of the second chip 60. In one example, the thickness of the sub-mount chip 120 is increased by increasing the thickness of the insulating layer 122. The thickness of the insulating layer 122 is greater than the thickness of the first element insulating layer 52 of the first chip 50. The thickness of the insulating layer 122 is greater than the thickness of the second element insulating layer 62 of the second chip 60. This increases the distance in the Z direction between the inner coil 110 and the conductive bonding material SD interposed between the sub-mount chip 120 and the first die pad 81, thereby improving the dielectric breakdown voltage of the semiconductor device 10.

In the first modification, the insulating layer 122 of the sub-mount chip 120 may have a configuration in which the plurality of first insulating films 122P and the plurality of second insulating films 122Q are alternately stacked one by one, as in the first embodiment. This may reduce the warping of the sub-mount chip 120. Therefore, the transformer chip 70 may be stably disposed over the sub-mount chip 120.

### (Second Modification)

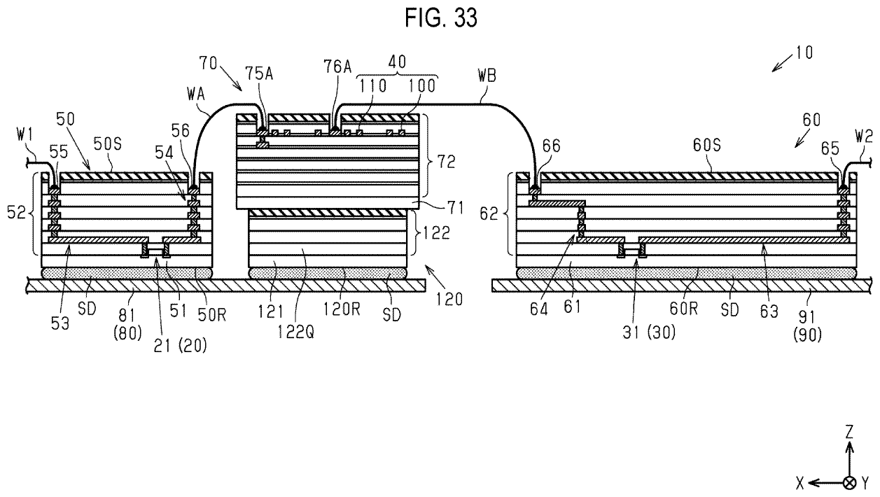

FIG. 33 shows a schematic cross-sectional structure of the first chip 50, the second chip 60, the transformer chip 70, the sub-mount chip 120, and their periphery in the second modification. The cross-sectional position in FIG. 33 is the same as the cross-sectional position in FIG. 8 of the first embodiment.

As shown in FIG. 33, the insulating layer 122 of the sub-mount chip 120 may have a configuration in which the plurality of second insulating films 122Q are stacked. In other words, the first insulating film 122P may be omitted from the insulating layer 122. With this configuration, since the first insulating film 122P, which has a higher dielectric constant than the second insulating film 122Q, is omitted, a dielectric breakdown voltage of the sub-mount chip 120 may be improved.

In the example shown in FIG. 33, the thickness of the sub-mount chip 120 is smaller than the thickness of the first chip 50. The thickness of the sub-mount chip 120 is also smaller than the thickness of the second chip 60. However, since the dielectric breakdown voltage of the sub-mount chip 120 is improved, even if the thickness of the sub-mount chip 120 is smaller than that of the sub-mount chip 120 of the first embodiment, the decrease in the dielectric breakdown voltage of the semiconductor device 10 may be suppressed. In addition, as the thickness of the sub-mount chip 120 is reduced, the semiconductor device 10 may be made thinner.

In the example shown in FIG. 33, the dimension of the sub-mount chip 120 in the X direction is smaller than the dimension of the transformer chip 70 in the X direction. Further, although not shown, the dimension of the sub-mount chip 120 in the Y direction may be smaller than the dimension of the transformer chip 70 in the Y direction. With this configuration, a cost of the sub-mount chip 120 may be reduced by miniaturizing the sub-mount chip 120.

Further, the dimension of the sub-mount chip 120 in the X direction shown in FIG. 33 may be changed arbitrarily. In one example, the dimension of the sub-mount chip 120 in the X direction may be equal to the dimension of the transformer chip 70 in the X direction. Further, the dimension of the sub-mount chip 120 in the Y direction shown in FIG. 33 may be changed arbitrarily. In one example, the dimension of the sub-mount chip 120 in the Y direction may be equal to the dimension of the transformer chip 70 in the Y direction.

### (Third Modification)

Each of the dimension in X direction and the dimension in Y direction of the sub-mount chip 120 may be changed arbitrarily. In one example, the dimension of the sub-mount chip 120 in the X direction may be larger than the dimension of the transformer chip 70 in the X direction. With this configuration, the transformer chip 70 may be stably disposed over the sub-mount chip 120. Further, in one example, the dimension of the sub-mount chip 120 in the Y direction may be larger than the dimension of the transformer chip 70 in the Y direction. With this configuration, the transformer chip 70 may be stably disposed over the sub-mount chip 120.

### (Fourth Modification)

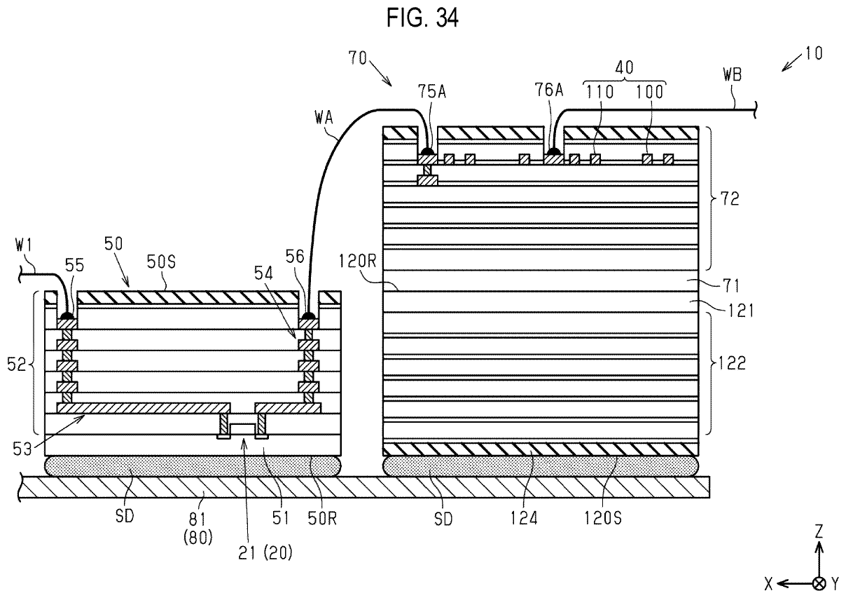

FIG. 34 shows a schematic cross-sectional structure of the first chip 50, the transformer chip 70, the sub-mount chip 120, and their periphery in the fourth modification. The cross-sectional position in FIG. 34 is the same as the cross-sectional position in FIG. 8 of the first embodiment.

As shown in FIG. 34, the sub-mount chip 120 may be disposed over the first die pad 81 such that the fourth semiconductor substrate 121 is on a side toward the transformer chip 70 with respect to the insulating layer 122. In this case, the transformer chip 70 is disposed over the fourth semiconductor substrate 121. More specifically, the third semiconductor substrate 71 of the transformer chip 70 is in contact with the fourth semiconductor substrate 121.

### (Fifth Modification)

At least one selected from the group of the protective film 123 and the passivation film 124 may be omitted from the sub-mount chip 120.

### (Modification of Positional Relationship Between Sub-Mount Chip and Transformer Chip)

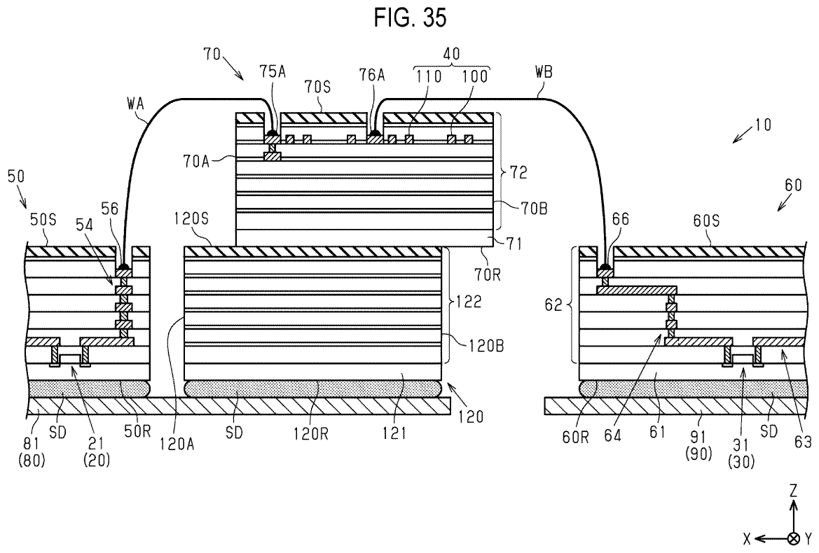

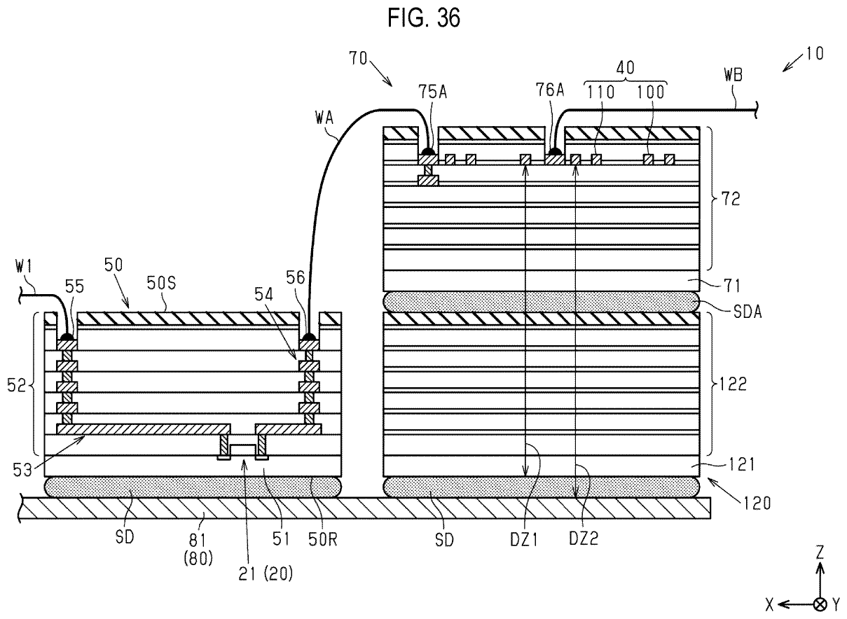

The positional relationship between the sub-mount chip 120 and the transformer chip 70 may be changed arbitrarily. This positional relationship may be changed, for example, as in first to third modifications. For the sake of convenience, the sealing resin 200 (see FIG. 3) is omitted in FIGS. 35 and 36.

### (First Modification)

FIG. 35 shows a schematic cross-sectional structure of the first chip 50, the second chip 60, the transformer chip 70, the sub-mount chip 120, and their periphery in the first modification. The cross-sectional position in FIG. 35 is the same as the cross-sectional position in FIG. 8 of the first embodiment.

As shown in FIG. 35, the transformer chip 70 may be disposed toward the second chip 60, shifted from the sub-mount chip 120. That is, in a plan view, the chip side surface 70B of the transformer chip 70 may be located to be closer to the second chip 60 than the chip side surface 120B of the sub-mount chip 120 is located. With this configuration, a length of the second intermediate wire WB may be shortened.

### (Second Modification)

FIG. 36 shows a schematic cross-sectional structure of the first chip 50, the transformer chip 70, the sub-mount chip 120, and their periphery in the second modification. The cross-sectional position in FIG. 36 is the same as the cross-sectional position in FIG. 8 of the first embodiment.

As shown in FIG. 36, the transformer chip 70 may be bonded onto the sub-mount chip 120 by an insulating bonding material SDA. That is, the insulating bonding material SDA may be interposed between the transformer chip 70 and the sub-mount chip 120 in the Z direction. With this configuration, the distance DZ1 between the conductive bonding material SD interposed between the sub-mount chip 120 and the first die pad 81 and the inner coil 110 of the transformer chip 70 in the Z direction may be increased by a thickness of the insulating bonding material SDA. Further, when an insulating bonding material is interposed between the sub-mount chip 120 and the first die pad 81, the distance DZ2 between the inner coil 110 and the first die pad 81 in the Z direction may be increased by the thickness of the insulating bonding material SDA. Therefore, the dielectric breakdown voltage of the semiconductor device 10 may be improved.

### (Third Modification)

The disposition form of the transformer chip 70 over the sub-mount chip 120 may be changed arbitrarily. In one example, the transformer chip 70 may be disposed over the sub-mount chip 120 such that the third semiconductor substrate 71 is located on an opposite side of the third element insulating layer 72 from the sub-mount chip 120. In this case, the first transformer pads 75A and 75B and the second transformer pads 76A and 76B may be provided over the third semiconductor substrate 71.

### (Modification of Transformer Chip)

The third semiconductor substrate 71 may be omitted from the transformer chip 70.
Both the inner coil 110 and the outer coil 100 may be disposed to be closer to the third semiconductor substrate 71 than the center of the third element insulating layer 72 in the Z direction.

### (Modification of Semiconductor Device)

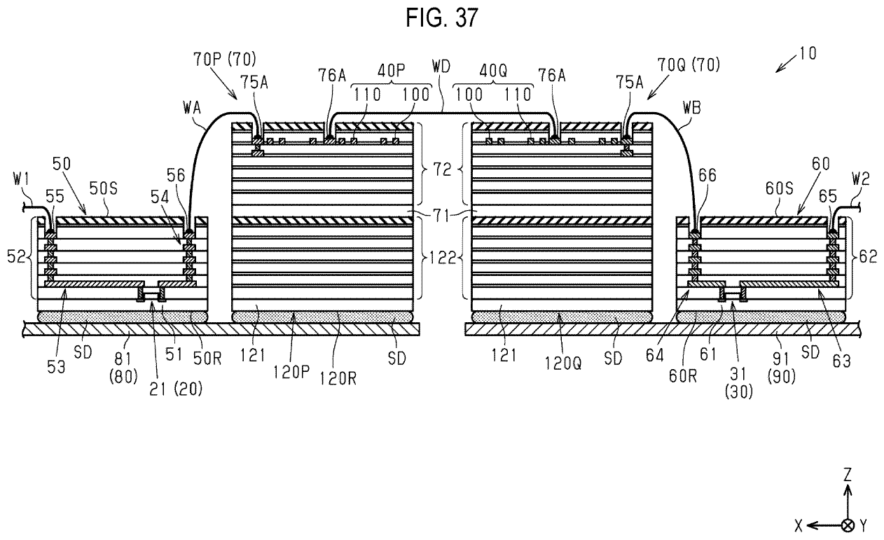

The transformer chip 70 may be disposed over the second die pad 91. In this case, the sub-mount chip 120 is bonded to the second die pad 91 by a conductive bonding material or an insulating bonding material. The transformer chip 70 is disposed over the sub-mount chip 120.
The transformer chip 70 may be provided in plural. In one example, as shown in FIG. 37, the transformer chip 70 includes a first transformer chip 70P disposed over the first die pad 81 and a second transformer chip 70Q disposed over the second die pad 91. The first transformer chip 70P includes a first transformer 40P. The second transformer chip 70Q includes a second transformer 40Q. The first transformer 40P and the second transformer 40Q have the same configuration as, for example, the transformer 40 of the first embodiment. In this case, the sub-mount chip 120 includes a first sub-mount chip 120P bonded to the first die pad 81 by a conductive bonding material or an insulating bonding material, and a second sub-mount chip 120Q bonded to the second die pad 91 by a conductive bonding material or an insulating bonding material. The first transformer chip 70P is disposed over the first sub-mount chip 120P. The second transformer chip 70Q is disposed over the second sub-mount chip 120Q.

The second transformer pads 76A and 76B of the first transformer chip 70P and the second transformer pads 76A and 76B of the second transformer chip 70Q are individually connected by wires WD. This electrically connects the inner coil 110 of the first transformer chip 70P and the inner coil 110 of the second transformer chip 70Q. The first transformer pads 75A and 75B of the second transformer chip 70Q are individually electrically connected to the second intermediate pads 66 of the second chip 60 by the second intermediate wires WB.

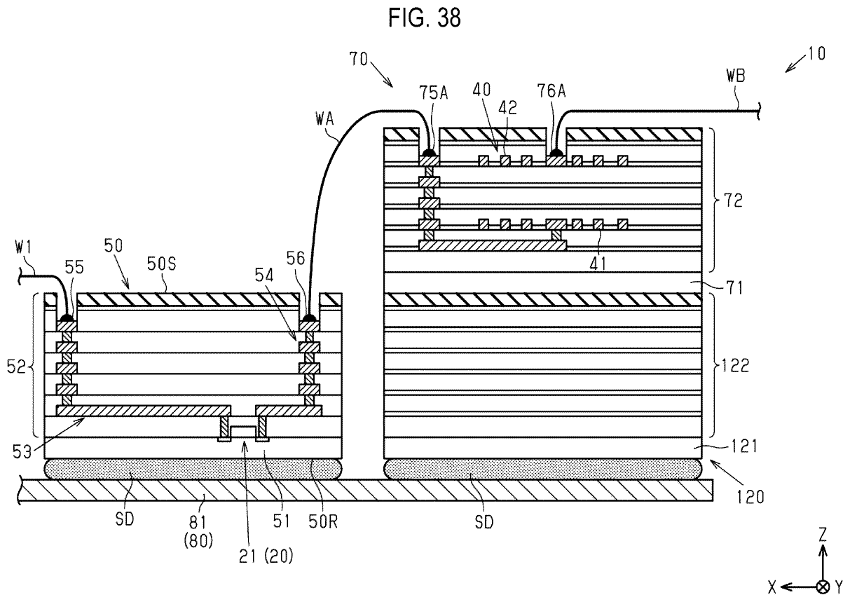

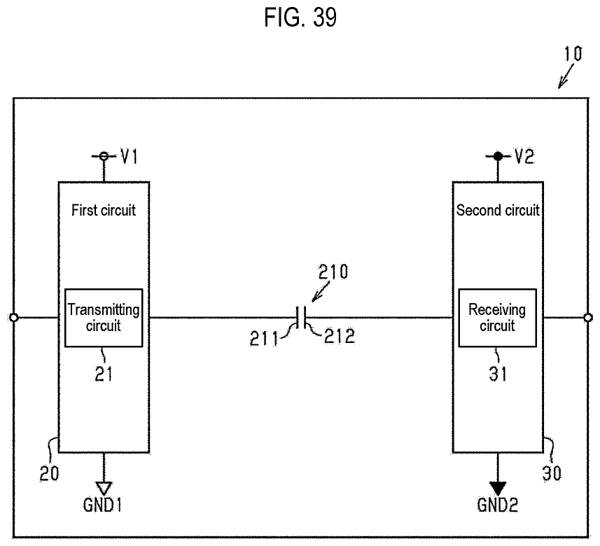

With this configuration, a double insulation structure is formed by the first transformer 40P and the second transformer 40Q, and thus the dielectric breakdown voltage of the semiconductor device 10 may be improved. Also, configurations of the first transformer 40P and the second transformer 40Q are not limited to the transformer 40 of the first embodiment, and may be the same as, for example, the transformer 40 of the third embodiment.
The configuration of the transformer 40 provided in the third element insulating layer 72 of the transformer chip 70 may be changed arbitrarily. In one example, instead of the outer coil 100 (130) and the inner coil 110 (140), the transformer chip 70 may include a first coil 41 and a second coil 42 disposed opposite to each other in the Z direction in the third element insulating layer 72 as shown in FIG. 38. The first coil 41 is disposed to be closer to the third semiconductor substrate 71 than the second coil 42 is disposed in the Z direction. In other words, the first coil 41 is disposed to be closer to the sub-mount chip 120 than the second coil 42 is disposed in the Z direction. The first coil 41 is electrically connected to the first transformer pads 75A and 75B. In other words, the first coil 41 is electrically connected to the first circuit 20 via the first intermediate wire WA. The second coil 42 is electrically connected to the second transformer pads 76A and 76B. In other words, the second coil 42 is electrically connected to the second circuit 30 via the second intermediate wire WB.
As shown in FIG. 39, the semiconductor device 10 may include a capacitor 210 instead of the transformer 40. In this case, the first circuit 20 and the second circuit 30 may be configured to transmit signals or power via the capacitor 210. In the example shown in FIG. 39, the capacitor 210 includes a first electrode plate 211 and a second electrode plate 212. The first electrode plate 211 is electrically connected to the first circuit 20. The second electrode plate 212 is electrically connected to the second circuit 30. Herein, the capacitor 210 is an example of an “insulating element.”

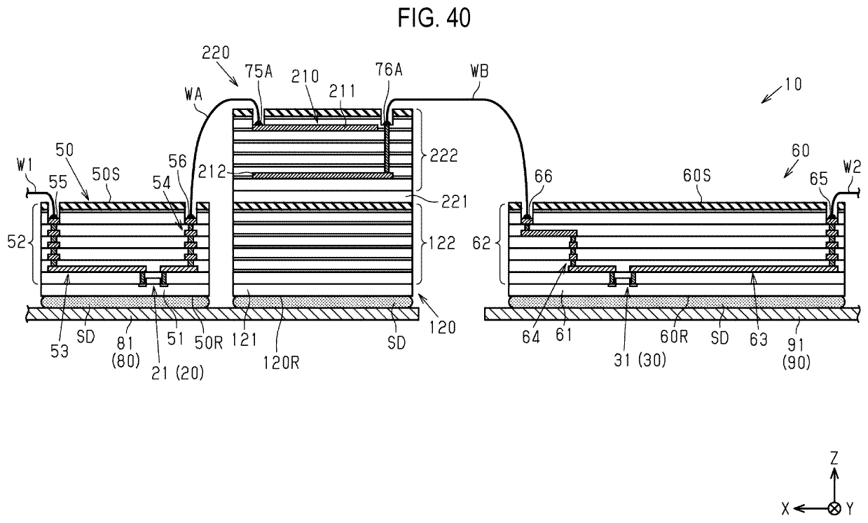

As shown in FIG. 40, the semiconductor device 10 includes a capacitor chip 220 instead of the transformer chip 70. The capacitor chip 220 is disposed over the sub-mount chip 120. The sub-mount chip 120 is bonded to the first die pad 81 by, for example, a conductive bonding material SD. Herein, the capacitor chip 220 is an example of an “insulating chip.”

The capacitor chip 220 includes a fifth semiconductor substrate 221 and a fifth element insulating layer 222 formed over the fifth semiconductor substrate 221. In one example, the fifth semiconductor substrate 221 has the same configuration as the third semiconductor substrate 71 (see FIG. 5) of the transformer chip 70. In one example, the fifth element insulating layer 222 has the same configuration as the third element insulating layer 72 (see FIG. 5) of the transformer chip 70. The first electrode plate 211 and the second electrode plate 212 of the capacitor 210 are embedded in the fifth element insulating layer 222. The first electrode plate 211 and the second electrode plate 212 are disposed opposite to each other in the Z direction.

A portion of the first electrode plate 211 constitutes the first transformer pad 75A. Therefore, the first electrode plate 211 is electrically connected to the first circuit 20 via the first intermediate wire WA. The second electrode plate 212 is electrically connected to the second transformer pad 76A. Therefore, the second electrode plate 212 is electrically connected to the second circuit 30 via the second intermediate wire WB. In the example shown in FIG. 40, the second electrode plate 212 is disposed to be closer to the fifth semiconductor substrate 221 than the first electrode plate 211 is disposed. Further, the positions of the first electrode plate 211 and the second electrode plate 212 in the Z direction may be changed arbitrarily. In one example, the first electrode plate 211 may be disposed to be closer to the fifth semiconductor substrate 221 than the second electrode plate 212 is disposed.
The semiconductor device 10 may include a plurality of first wirings and a plurality of second wirings instead of the first lead frame 80 and the second lead frame 90. In other words, the semiconductor device 10 may include a first conductive member and a second conductive member. The first conductive member supports the first chip 50 and is electrically connected to the first chip 50. The first conductive member includes a plurality of first external terminals. The second conductive member supports the second chip 60 and is electrically connected to the second chip 60. The second conductive member includes a plurality of second external terminals. The transformer chip 70 is disposed over either the first conductive member or the second conductive member.
The semiconductor device 10 is not limited to a configuration as a signal transmission device that transmits a signal via the transformer 40, and may be configured as a power transmission device that transmits power via the transformer 40.

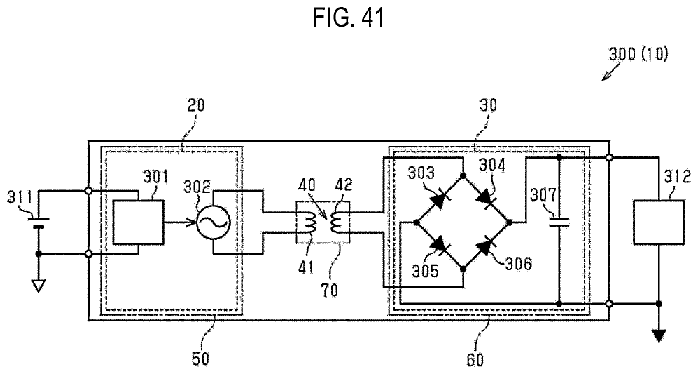

FIG. 41 shows an example of a circuit configuration of a power transmission device 300 as a modification of the semiconductor device 10. The power transmission device 300 may include a control circuit 301, an oscillator 302, a transformer 40, diodes 303 to 306, and a smoothing capacitor 307. The control circuit 301 and the oscillator 302 may be included in the first circuit 20. The first circuit 20 may include the oscillator 302 but may not include the control circuit 301. The diodes 303 to 306 and the smoothing capacitor 307 may be included in the second circuit 30. The second circuit 30 may include the diodes 303 to 306 but may not include the smoothing capacitor 307. Further, the number of diodes included in the second circuit 30 may be changed as appropriate depending on a configuration of a rectification circuit. In one example, the first chip 50 including the control circuit 301 and the oscillator 302, the transformer chip 70 including the transformer 40, and the second chip 60 including the diodes 303 to 306 and the smoothing capacitor 307 are sealed with the sealing resin 200, similar to the semiconductor device 10 according to the first embodiment.

The control circuit 301 is connected to a DC power supply 311. The oscillator 302 is controlled by the control circuit 301. The oscillator 302 outputs an AC signal. This AC signal is transmitted by the transformer 40. A DC voltage by the diodes 303 to 306 and the smoothing capacitor 307 is supplied to a load 312. In other words, the power transmission device 300 functions as a DC voltage conversion circuit (DC-DC converter) that converts a voltage of the DC power supply 311 into an operating voltage of the load 312.

The term “over” as used in the present disclosure includes the meanings of “on” and “above” unless clearly stated otherwise in the context. Therefore, for example, the expression “a first element is disposed over a second element” is intended that in some embodiments, the first element may be directly disposed on the second element in contact with the second element, while in other embodiments, the first element may be disposed above the second element without contacting the second element. That is, the term “over” does not exclude a structure in which other elements are formed between the first element and the second element.

The Z direction used in the present disclosure does not necessarily have to be a vertical direction, nor does it have to completely coincide with the vertical direction. Therefore, various structures according to the present disclosure are not limited to the Z direction “up” and “down” described herein being the vertical direction “up” and “down.” For example, the X direction may be the vertical direction, or the Y direction may be the vertical direction.

### <Supplementary Notes>

The technical ideas that may be understood from the present disclosure are described below. In addition, for the purpose of aiding understanding and not for the purpose of limitation, constituent elements described in supplementary notes are labeled with the reference numerals of the corresponding constituent elements in the above-described embodiments. The reference numerals are provided as examples to aid understanding, and the constituent elements described in supplementary notes should not be limited to the constituent elements indicated by the reference numerals.

### [Supplementary Note 1]

A semiconductor device (10) including:
a first chip (50) including a first semiconductor substrate (51), a first circuit (20) formed at the first semiconductor substrate (51), and a first element insulating layer (52) formed over the first semiconductor substrate (51);
a second chip (60) disposed to be spaced apart from the first chip (50) in a first direction (X direction) and including a second semiconductor substrate (61), a second circuit (30) formed at the second semiconductor substrate (61), and a second element insulating layer (62) formed over the second semiconductor substrate (61);
a sub-mount chip (120) provided separately from the first chip (50) and the second chip (60); and
a transformer chip (70) disposed over the sub-mount chip (120) and including a transformer (40),
wherein the first circuit (20) and the second circuit (30) are configured to transmit signals or power via the transformer (40),
wherein the transformer chip (70) includes:
   a third semiconductor substrate (71); and
   a third element insulating layer (72) formed over the third semiconductor substrate (71),
wherein the transformer (40) is embedded in the third element insulating layer (72), and
wherein the sub-mount chip (120) includes:
   a fourth semiconductor substrate (121); and
   an insulating layer (122) formed over the fourth semiconductor substrate (121).

### [Supplementary Note 2]

The semiconductor device of Supplementary Note 1, wherein the third element insulating layer (72) of the transformer chip (70) includes a structure in which a first insulating film (72P) containing silicon nitride and a second insulating film (72Q) containing silicon oxide are alternately stacked in plural.

### [Supplementary Note 3]

The semiconductor device of Supplementary Note 1 or 2, wherein the insulating layer (122) of the sub-mount chip (120) includes a structure in which a first insulating film (122P) containing silicon nitride and a second insulating film (122Q) containing silicon oxide are alternately stacked in plural.

### [Supplementary Note 4]

The semiconductor device of Supplementary Note 1 or 2, wherein the insulating layer (122) of the sub-mount chip (120) includes a structure in which an insulating film (122Q) containing silicon oxide is stacked in plural.

### [Supplementary Note 5]

The semiconductor device of any one of Supplementary Notes 1 to 4, wherein a thickness of the sub-mount chip (120) is smaller than a thickness of the transformer chip (70).

### [Supplementary Note 6]

The semiconductor device of any one of Supplementary Notes 1 to 4, wherein a thickness of the sub-mount chip (120) is equal to or greater than a thickness of the transformer chip (70).

### [Supplementary Note 7]

The semiconductor device of any one of Supplementary Notes 1 to 6, wherein a dimension of the sub-mount chip (120) in the first direction (X direction) is smaller than a dimension of the transformer chip (70) in the first direction (X direction).

### [Supplementary Note 8]

The semiconductor device of any one of Supplementary Notes 1 to 6, wherein a dimension of the sub-mount chip (120) in the first direction (X direction) is equal to a dimension of the transformer chip (70) in the first direction (X direction).

### [Supplementary Note 9]

The semiconductor device of any one of Supplementary Notes 1 to 6, wherein a dimension of the sub-mount chip (120) in the first direction (X direction) is larger than a dimension of the transformer chip (70) in the first direction (X direction).

### [Supplementary Note 10]

The semiconductor device of any one of Supplementary Notes 1 to 9, wherein a thickness of the sub-mount chip (120) is equal to or greater than a thickness of the first chip (50) or a thickness of the second chip (60).

### [Supplementary Note 11]

The semiconductor device of any one of Supplementary Notes 1 to 9, wherein a thickness of the sub-mount chip (120) is smaller than a thickness of the first chip (50) or a thickness of the second chip (60).

### [Supplementary Note 12]

The semiconductor device of any one of Supplementary Notes 1 to 11, wherein in a chip disposition state in which the transformer chip (70) is disposed over the sub-mount chip (120), the third semiconductor substrate (71) is interposed between the insulating layer (122) of the sub-mount chip (120) and the third element insulating layer (72) of the transformer chip (70).

### [Supplementary Note 13]

The semiconductor device of Supplementary Note 12, wherein the insulating layer (122) of the sub-mount chip (120) includes a protective layer (123, 124) formed at a surface layer side of the insulating layer (122), and
wherein in the chip disposition state, the third semiconductor substrate (71) is in contact with the protective layer (124).

### [Supplementary Note 14]

The semiconductor device of any one of Supplementary Notes 1 to 13, wherein the transformer (40) includes an outer coil (100) and an inner coil (110) embedded in the third element insulating layer (72), and
wherein when viewed from a thickness direction (Z direction) of the third element insulating layer (72), the inner coil (110) is disposed inside the outer coil (100) so as not to overlap with the outer coil (100).

### [Supplementary Note 15]

The semiconductor device of Supplementary Note 14, wherein both the outer coil (100) and the inner coil (110) are disposed on a side farther from the third semiconductor substrate (71) than a center of the third element insulating layer (72) in the thickness direction (Z direction).

### [Supplementary Note 16]

The semiconductor device of any one of Supplementary Notes 1 to 13, wherein the transformer (40) includes an outer coil (100) and an inner coil (110) embedded in the third element insulating layer (72),
wherein when viewed from a thickness direction (Z direction) of the third element insulating layer (72), the inner coil (110) is disposed inside the outer coil (100) so as not to overlap with the outer coil (100),
wherein the third element insulating layer (72) includes a structure in which a plurality of insulators (72U), each including a first insulating film (72P) containing silicon nitride and a second insulating film (72Q) containing silicon oxide stacked on the first insulating film (72P), are stacked,
wherein the inner coil (110) and the outer coil (100) are provided so as to penetrate a specific insulator (72UA) which is a specific one of the insulators,
wherein the third element insulating layer (72) includes a cover insulating film (72UB) composed of the first insulating film (72P) and in contact with the second insulating film (72Q) of the specific insulator (72UA) so as to cover the inner coil (110) and the outer coil (100),
wherein a portion of the first insulating film (72P) of the specific insulator (72UA) between the inner coil (110) and the outer coil (100) includes a plurality of isolation insulating films (78A) provided to be spaced apart from each other in a direction orthogonal to the thickness direction (Z direction) of the third element insulating layer (72),
wherein a portion of the cover insulating film (72UB) between the inner coil (110) and the outer coil (100) includes a plurality of cover side isolation insulating films (78B) provided to be spaced apart from each other in the direction orthogonal to the thickness direction (Z direction), and
wherein each of the plurality of isolation insulating films (78A) and the plurality of cover side isolation insulating films (78B) includes the second insulating film (72Q).

### [Supplementary Note 17]

The semiconductor device of Supplementary Note 16, wherein each of the plurality of isolation insulating films (78A) and the plurality of cover side isolation insulating films (78B) is formed in an annular shape.

### [Supplementary Note 18]

The semiconductor device of any one of Supplementary Notes 1 to 13, wherein the transformer (40) includes an outer coil (100) and an inner coil (110) embedded in the third element insulating layer (72),
wherein when viewed from a thickness direction (Z direction) of the third element insulating layer (72), the inner coil (110) is disposed inside the outer coil (100) so as not to overlap with the outer coil (100),
wherein the third element insulating layer (72) includes a structure in which a plurality of insulators (72U), each including a first insulating film (72P) containing silicon nitride and a second insulating film (72Q) containing silicon oxide stacked on the first insulating film (72P), are stacked,
wherein the inner coil (110) and the outer coil (100) are provided so as to penetrate a specific insulator (72UA) which is a specific one of the insulators,
wherein the third element insulating layer (72) includes a cover insulating film (72UB) including the first insulating film (72P) and in contact with the second insulating film (72Q) of the specific insulator (72UA) so as to cover the inner coil (110) and the outer coil (100),
wherein a portion of the first insulating film (72P) of the specific insulator (72UA) between the inner coil (110) and the outer coil (100) includes a plurality of concave portions (72PC) that are provided to be spaced apart from each other in a direction orthogonal to the thickness direction (Z direction) of the third element insulating layer (72) and open toward the cover insulating film (72UB),
wherein a portion of the cover insulating film (72UB) between the inner coil (110) and the outer coil (100) includes a plurality of cover side concave portions (72PD) that are provided to be spaced apart from each other in the direction orthogonal to the thickness direction (Z direction) and open toward the first insulating film (72P) of the specific insulator (72UA), and
wherein the second insulating film (72Q) is embedded in each of the plurality of concave portions (72PC) and the plurality of cover side concave portions (72PD).

### [Supplementary Note 19]

The semiconductor device of Supplementary Note 18, wherein each of the plurality of concave portions (72PC) and the plurality of cover side concave portions (72PD) is formed in an annular shape.

### [Supplementary Note 20]

The semiconductor device of any one of Supplementary Notes 1 to 19, further including:
a first die pad (81) that supports the first chip (50); and
a second die pad (91) that supports the second chip (60),
wherein the sub-mount chip (120) and the transformer chip (70) are disposed over the first die pad (81) or the second die pad (91) between the first chip (50) and the second chip (60) in the first direction (X direction).

### [Supplementary Note 21]

The semiconductor device of any one of Supplementary Notes 14 to 19, wherein the inner coil (110) and the outer coil (100) are disposed at a same position in the thickness direction (Z direction).

### [Supplementary Note 22]

The semiconductor device of Supplementary Note 14 or 15, wherein the outer coil (130) includes a first outer coil (131) and a second outer coil (132), each including a first end (131A, 132A) and a second end (131B, 132B),
wherein the second end (131B) of the first outer coil (131) and the second end (132B) of the second outer coil (132) are connected to each other,
wherein the first outer coil (131) and the second outer coil (132) are configured to generate magnetic fluxes in opposite directions when a current flows from the first end of one of the first outer coil (131) and the second outer coil (132) to the first end of the other of the first outer coil (131) and the second outer coil (132),
wherein the inner coil (140) includes a first inner coil (141) and a second inner coil (142), each including a first end (141A, 142A) and a second end (141B, 142B), and
wherein when viewed from the thickness direction (Z direction) of the third element insulating layer (72), the first inner coil (141) is disposed inside the first outer coil (131) so as not to overlap the first outer coil (131), and the second inner coil (142) is disposed inside the second outer coil (132) so as not to overlap with the second outer coil (132).

### [Supplementary Note 23]

The semiconductor device of Supplementary Note 22, wherein the first inner coil (141), the second inner coil (142), the first outer coil (131), and the second outer coil (132) are disposed at a same position in the thickness direction (Z direction).

### [Supplementary Note 24]

The semiconductor device of Supplementary Note 22 or 23, wherein the first inner coil (141) and the second inner coil (142) are connected by a coil connecting wire (WC) provided outside the transformer chip (70).

### [Supplementary Note 25]

The semiconductor device of any one of Supplementary Notes 22 to 24, wherein the first outer coil (131) is electrically connected to the first chip (50) by a first chip connecting wire (WA1) provided outside the transformer chip (70), and
wherein the second outer coil (132) is electrically connected to the first chip (50) by a second chip connecting wire (WA2) provided outside the transformer chip (70).

### [Supplementary Note 26]

The semiconductor device of any one of Supplementary Notes 22 to 25, wherein the first inner coil (141) is electrically connected to the second chip (60) by a third chip connecting wire (WB1) provided outside the transformer chip (70), and
wherein the second inner coil (142) is electrically connected to the second chip (60) by a fourth chip connecting wire (WB2) provided outside the transformer chip (70).

### [Supplementary Note 27]

The semiconductor device of any one of Supplementary Notes 1 to 13, wherein the transformer (40) includes an outer coil (130) and an inner coil (140) disposed in the third element insulating layer (72),
wherein the outer coil (130) includes a first outer coil (131) and a second outer coil (132), each including a first end (131A, 132A) and a second end (131B, 132B),
wherein the second end (131B) of the first outer coil (131) and the second end (132B) of the second outer coil (132) are connected to each other,
wherein the first outer coil (131) and the second outer coil (132) are configured to generate magnetic fluxes in opposite directions when a current flows from the first end of one of the first outer coil (131) and the second outer coil (132) to the first end of the other of the first outer coil (131) and the second outer coil (132),
wherein the inner coil (140) includes a first inner coil (141) and a second inner coil (142), each including a first end (141A, 142A) and a second end (141B, 142B),
wherein when viewed from the thickness direction (Z direction) of the third element insulating layer (72), the first inner coil (141) is disposed inside the first outer coil (131) so as not to overlap with the first outer coil (131), and the second inner coil (142) is disposed inside the second outer coil (132) so as not to overlap with the second outer coil (132),
wherein the third element insulating layer (72) includes a structure in which a plurality of insulators (72U), each of which includes a first insulating film (72P) containing silicon nitride and a second insulating film (72Q) containing silicon oxide stacked on the first insulating film (72P), are stacked,
wherein the first inner coil (141), the second inner coil (142), the first outer coil (131), and the second outer coil (132) are provided so as to penetrate a specific insulator (72UA) which is a specific one of the insulators,
wherein the third element insulating layer (72) includes a cover insulating film (72UB) including the first insulating film (72P) and in contact with the second insulating film (72Q) of the specific insulator (72UA) so as to cover the first inner coil (141), the second inner coil (142), the first outer coil (131), and the second outer coil (132),
wherein a portion of the first insulating film (72P) of the specific insulator (72UA) between the first inner coil (141) and the first outer coil (131) includes a plurality of first isolation insulating films (78A1) that are provided to be spaced apart from each other in a direction orthogonal to the thickness direction (Z direction),
wherein a portion of the first insulating film (72P) of the specific insulator (72UA) between the second inner coil (142) and the second outer coil (132) includes a plurality of second isolation insulating films (78A2) that are provided to be spaced apart from each other in the direction orthogonal to the thickness direction (Z direction),
wherein a portion of the cover insulating film (72UB) between the first inner coil (141) and the first outer coil (131) includes a plurality of first cover side isolation insulating films (78B1) that are provided to be spaced apart from each other in the direction orthogonal to the thickness direction (Z direction),
wherein a portion of the cover insulating film (72UB) between the second inner coil (142) and the second outer coil (132) includes a plurality of second cover side isolation insulating films (78B2) that are provided to be spaced apart from each other in the direction orthogonal to the thickness direction (Z direction), and
wherein each of the plurality of first isolation insulating films (78A1), second isolation insulating films (78A2), first cover side isolation insulating films (78B1), and second cover side isolation insulating films (78B2) includes the second insulating film (72Q).

### [Supplementary Note 28]

The semiconductor device of Supplementary Note 27, wherein each of the plurality of first isolation insulating films (78A1), second isolation insulating films (78A2), first cover side isolation insulating films (78B1), and second cover side isolation insulating films (78B2) is formed in an annular shape.

### [Supplementary Note 29]

The semiconductor device of any one of Supplementary Notes 1 to 13, wherein the transformer (40) includes an outer coil (130) and an inner coil (140) disposed in the third element insulating layer (72),
wherein the outer coil (130) includes a first outer coil (131) and a second outer coil (132), each including a first end (131A, 132A) and a second end (131B, 132B),
wherein the second end (131B) of the first outer coil (131) and the second end (132B) of the second outer coil (132) are connected to each other,
wherein the first outer coil (131) and the second outer coil (132) are configured to generate magnetic fluxes in opposite directions when a current flows from the first end of one of the first outer coil (131) and the second outer coil (132) to the first end of the other of the first outer coil (131) and the second outer coil (132),
wherein the inner coil (140) includes a first inner coil (141) and a second inner coil (142), each including a first end (141A, 142A) and a second end (141B, 142B),
wherein when viewed from the thickness direction (Z direction) of the third element insulating layer (72), the first inner coil (141) is disposed inside the first outer coil (131) so as not to overlap with the first outer coil (131), and the second inner coil (142) is disposed inside the second outer coil (132) so as not to overlap with the second outer coil (132),
wherein the third element insulating layer (72) includes a structure in which a plurality of insulators (72U), each including a first insulating film (72P) containing silicon nitride and a second insulating film (72Q) containing silicon oxide stacked on the first insulating film (72P), are stacked,
wherein the first inner coil (141), the second inner coil (142), the first outer coil (131), and the second outer coil (132) are provided so as to penetrate a specific insulator (72UA) which is a specific one of the insulators,
wherein the third element insulating layer (72) includes a cover insulating film (72UB) including the first insulating film (72P) and in contact with the second insulating film (72Q) of the specific insulator (72UA) so as to cover the first inner coil (141), the second inner coil (142), the first outer coil (131), and the second outer coil (132),
wherein a portion of the first insulating film (72P) of the specific insulator (72UA) between the first inner coil (141) and the first outer coil (131) includes a plurality of first concave portions (79A) that are provided to be spaced apart from each other in a direction orthogonal to the thickness direction (Z direction) and open toward the cover insulating film (72UB),
wherein a portion of the first insulating film (72P) of the specific insulator (72UA) between the second inner coil (142) and the second outer coil (132) includes a plurality of second concave portions (79B) that are provided to be spaced apart from each other in the direction orthogonal to the thickness direction (Z direction) and open toward the cover insulating film (72UB),
wherein a portion of the cover insulating film (72UB) between the first inner coil (141) and the first outer coil (131) includes a plurality of first cover side concave portions (79C) that are provided to be spaced apart from each other in the direction orthogonal to the thickness direction (Z direction) and open toward the first insulating film (72P) of the specific insulator (72UA),
wherein a portion of the cover insulating film (72UB) between the second inner coil (142) and the second outer coil (132) includes a plurality of second cover side concave portions (79D) that are provided to be spaced apart from each other in the direction orthogonal to the thickness direction (Z direction) and open toward the first insulating film (72P) of the specific insulator (72UA), and
wherein the second insulating film (72Q) is embedded in each of the plurality of first concave portions (79A), second concave portions (79B), first cover side concave portions (79C), and second cover side concave portions (79D).

### [Supplementary Note 30]

The semiconductor device of Supplementary Note 29, wherein each of the plurality of first concave portions (79A), second concave portions (79B), first cover side concave portions (79C), and second cover side concave portions (79D) is formed in an annular shape.

### [Supplementary Note 31]

The semiconductor device of any one of Supplementary Notes 1 to 13, wherein the transformer (40) includes a first coil (41) and a second coil (42) disposed in the third element insulating layer (72), and
wherein the first coil (41) and the second coil (42) are disposed opposite to each other in the thickness direction (Z direction) of the third element insulating layer (72).

### [Supplementary Note 32]

The semiconductor device of any one of Supplementary Notes 1 to 31, wherein an insulating bonding material (SDA) is interposed between the transformer chip (70) and the sub-mount chip (120).

### [Supplementary Note 33]

A semiconductor device (10) including:
a first chip (50) including a first semiconductor substrate (51), a first circuit (20) formed at the first semiconductor substrate (51), and a first element insulating layer (52) formed over the first semiconductor substrate (51);
a second chip (60) including a second semiconductor substrate (61), a second circuit (30) formed at the second semiconductor substrate (61), and a second element insulating layer (62) formed over the second semiconductor substrate (61) and disposed to be spaced apart from the first chip (50) in a first direction (X direction);
a first sub-mount chip (120P) and a second sub-mount chip (120Q) provided separately from the first chip (50) and the second chip (60);
a first transformer chip (70P) disposed over the first sub-mount chip (120P) and including a first transformer (40P); and
a second transformer chip (70Q) disposed over the second sub-mount chip (120Q) and including a second transformer (40Q),
wherein the first circuit (20) and the second circuit (30) are configured to transmit signals or power via the first transformer (40P) and the second transformer (40Q),
wherein each of the first transformer chip (70P) and the second transformer chip (70Q) includes:
   a third semiconductor substrate (71); and
   a third element insulating layer (72) formed over the third semiconductor substrate (71),
wherein the first transformer (40P) is embedded in the third element insulating layer (72) of the first transformer chip (70P),
wherein the second transformer (40Q) is embedded in the third element insulating layer (72) of the second transformer chip (70Q), and
wherein each of the first sub-mount chip (120P) and the second sub-mount chip (120Q) includes:
   a fourth semiconductor substrate (121); and
   an insulating layer (122) formed over the fourth semiconductor substrate (121).

### [Supplementary Note 34]

The semiconductor device of Supplementary Note 33, further including:
a first die pad (81) that supports the first chip (50); and
a second die pad (91) that supports the second chip (60),
wherein the first sub-mount chip (120P) is disposed over the first die pad (81) between the first chip (50) and the second chip (60) in the first direction (X direction),
wherein the first transformer chip (70P) is disposed over the first sub-mount chip (120P),
wherein the second sub-mount chip (120Q) is disposed over the second die pad (91) between the first chip (50) and the second chip (60) in the first direction (X direction), and
wherein the second transformer chip (70Q) is disposed over the second sub-mount chip (120Q).

### [Supplementary Note 35]

A semiconductor device (10) including:
a first chip (50) including a first semiconductor substrate (51), a first circuit (20) formed at the first semiconductor substrate (51), and a first element insulating layer (52) formed over the first semiconductor substrate (51);
a second chip (60) including a second semiconductor substrate (61), a second circuit (30) formed at the second semiconductor substrate (61), and a second element insulating layer (62) formed over the second semiconductor substrate (61) and disposed to be spaced apart from the first chip (50) in a first direction (X direction);
a sub-mount chip (120) provided separately from the first chip (50) and the second chip (60); and
a capacitor chip (220) disposed over the sub-mount chip (120) and including a capacitor (210),
wherein the first circuit (20) and the second circuit (30) are configured to transmit signals or power via the capacitor (210),
wherein the capacitor chip (220) includes:
   a fifth semiconductor substrate (221); and
   a fifth element insulating layer (222) formed over the fifth semiconductor substrate (221),
wherein the capacitor (210) is embedded in the fifth element insulating layer (222), and
wherein the sub-mount chip (120) includes:
   a fourth semiconductor substrate (121); and
   an insulating layer (122) formed over the fourth semiconductor substrate (121).

### [Supplementary Note 36]

A semiconductor device (10) including:
a first chip (50) including a first circuit (20);
a second chip (60) including a second circuit (30) and disposed to be spaced apart from the first chip (50) in a first direction (X direction);
a sub-mount chip (120) provided separately from the first chip (50) and the second chip (60); and
an insulating chip (70/220) disposed over the sub-mount chip (120) and including an insulating element (40/210),
wherein the first circuit (20) and the second circuit (30) are configured to transmit signals or power via the insulating element (40/210),
wherein the insulating chip (70/220) includes:
   a semiconductor substrate (71/221); and
   an element insulating layer (72/222) formed over the semiconductor substrate (71/221),
wherein the insulating element (40/210) is embedded in the element insulating layer (72/222), and
wherein the sub-mount chip (120) includes:
   a sub-mount semiconductor substrate (121); and
   an insulating layer (122) formed over the sub-mount semiconductor substrate (121).

The above description is merely an example. Those skilled in the art will appreciate that more possible combinations and substitutions are possible beyond the constituent elements and methods (manufacturing processes) listed for the purposes of illustrating the techniques of the present disclosure. The present disclosure is intended to cover all alternatives, modifications, and changes that fall within the scope of the present disclosure, including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a first chip including a first semiconductor substrate, a first circuit formed at the first semiconductor substrate, and a first element insulating layer formed over the first semiconductor substrate;
a second chip disposed to be spaced apart from the first chip in a first direction and including a second semiconductor substrate, a second circuit formed at the second semiconductor substrate, and a second element insulating layer formed over the second semiconductor substrate;
a sub-mount chip provided separately from the first chip and the second chip; and
a transformer chip disposed over the sub-mount chip and including a transformer,
wherein the first circuit and the second circuit are configured to transmit signals or power via the transformer,
wherein the transformer chip includes:
a third semiconductor substrate; and
a third element insulating layer formed over the third semiconductor substrate,
wherein the transformer is embedded in the third element insulating layer, and
wherein the sub-mount chip includes:
a fourth semiconductor substrate; and
an insulating layer formed over the fourth semiconductor substrate.

2. The semiconductor device of claim 1, wherein the third element insulating layer of the transformer chip includes a structure in which a first insulating film containing silicon nitride and a second insulating film containing silicon oxide are alternately stacked in plural.

3. The semiconductor device of claim 1, wherein the insulating layer of the sub-mount chip includes a structure in which a first insulating film containing silicon nitride and a second insulating film containing silicon oxide are alternately stacked in plural.

4. The semiconductor device of claim 1, wherein the insulating layer of the sub-mount chip includes a structure in which an insulating film containing silicon oxide is stacked in plural.

5. The semiconductor device of claim 1, wherein a thickness of the sub-mount chip is smaller than a thickness of the transformer chip.

6. The semiconductor device of claim 1, wherein a thickness of the sub-mount chip is equal to or greater than a thickness of the transformer chip.

7. The semiconductor device of claim 1, wherein a dimension of the sub-mount chip in the first direction is smaller than a dimension of the transformer chip in the first direction.

8. The semiconductor device of claim 1, wherein a dimension of the sub-mount chip in the first direction is equal to a dimension of the transformer chip in the first direction.

9. The semiconductor device of claim 1, wherein a dimension of the sub-mount chip in the first direction is larger than a dimension of the transformer chip in the first direction.

10. The semiconductor device of claim 1, wherein a thickness of the sub-mount chip is equal to or greater than a thickness of the first chip or a thickness of the second chip.

11. The semiconductor device of claim 1, wherein a thickness of the sub-mount chip is smaller than a thickness of the first chip or a thickness of the second chip.

12. The semiconductor device of claim 1, wherein in a chip disposition state in which the transformer chip is disposed over the sub-mount chip, the third semiconductor substrate is interposed between the insulating layer of the sub-mount chip and the third element insulating layer of the transformer chip.

13. The semiconductor device of claim 12, wherein the insulating layer of the sub-mount chip includes a protective layer formed at a surface layer side of the insulating layer, and
wherein in the chip disposition state, the third semiconductor substrate is in contact with the protective layer.

14. The semiconductor device of claim 1, wherein the transformer includes an outer coil and an inner coil embedded in the third element insulating layer, and
wherein when viewed from a thickness direction of the third element insulating layer, the inner coil is disposed inside the outer coil so as not to overlap with the outer coil.

15. The semiconductor device of claim 14, wherein both the outer coil and the inner coil are disposed on a side farther from the third semiconductor substrate than a center of the third element insulating layer in the thickness direction.

16. The semiconductor device of claim 1, wherein the transformer includes an outer coil and an inner coil embedded in the third element insulating layer,
wherein when viewed from a thickness direction of the third element insulating layer, the inner coil is disposed inside the outer coil so as not to overlap with the outer coil,
wherein the third element insulating layer includes a structure in which a plurality of insulators, each including a first insulating film containing silicon nitride and a second insulating film containing silicon oxide stacked on the first insulating film, are stacked,
wherein the inner coil and the outer coil are provided so as to penetrate a specific insulator which is a specific one of the insulators,
wherein the third element insulating layer includes a cover insulating film composed of the first insulating film and in contact with the second insulating film of the specific insulator so as to cover the inner coil and the outer coil,
wherein a portion of the first insulating film of the specific insulator between the inner coil and the outer coil includes a plurality of isolation insulating films provided to be spaced apart from each other in a direction orthogonal to the thickness direction of the third element insulating layer,
wherein a portion of the cover insulating film between the inner coil and the outer coil includes a plurality of cover side isolation insulating films provided to be spaced apart from each other in the direction orthogonal to the thickness direction, and
wherein each of the plurality of isolation insulating films and the plurality of cover side isolation insulating films includes the second insulating film.

17. The semiconductor device of claim 16, wherein each of the plurality of isolation insulating films and the plurality of cover side isolation insulating films is formed in an annular shape.

18. The semiconductor device of claim 1, wherein the transformer includes an outer coil and an inner coil embedded in the third element insulating layer,
wherein when viewed from a thickness direction of the third element insulating layer, the inner coil is disposed inside the outer coil so as not to overlap with the outer coil,
wherein the third element insulating layer includes a structure in which a plurality of insulators, each including a first insulating film containing silicon nitride and a second insulating film containing silicon oxide stacked on the first insulating film, are stacked,
wherein the inner coil and the outer coil are provided so as to penetrate a specific insulator which is a specific one of the insulators,
wherein the third element insulating layer includes a cover insulating film including the first insulating film and in contact with the second insulating film of the specific insulator so as to cover the inner coil and the outer coil,
wherein a portion of the first insulating film of the specific insulator between the inner coil and the outer coil includes a plurality of concave portions that are provided to be spaced apart from each other in a direction orthogonal to the thickness direction of the third element insulating layer and open toward the cover insulating film,
wherein a portion of the cover insulating film between the inner coil and the outer coil includes a plurality of cover side concave portions that are provided to be spaced apart from each other in the direction orthogonal to the thickness direction and open toward the first insulating film of the specific insulator, and
wherein the second insulating film is embedded in each of the plurality of concave portions and the plurality of cover side concave portions.

19. The semiconductor device of claim 18, wherein each of the plurality of concave portions and the plurality of cover side concave portions is formed in an annular shape.

20. The semiconductor device of claim 1, further comprising:
a first die pad that supports the first chip; and
a second die pad that supports the second chip,
wherein the sub-mount chip and the transformer chip are disposed over the first die pad or the second die pad, between the first chip and the second chip in the first direction.
